(19) United States
(12) Patent Application Publication
(10) Pub. No.: US 2022/0098477 A1
(43) Pub. Date: Mar. 31, 2022

(54) MONONUCLEAR IRIDIUM COMPLEXES CONTAINING THREE ORTHO-METALLATED BIDENTATE LIGANDS AND OPTICAL ORIENTATING ANISTROPHY

(71) Applicant: Merck Patent GmbH, Darmstadt (DE)

(72) Inventors: Falk MAY, Mainz (DE); Philipp STOESSEL, Frankfurt am Main (DE); Armin AUCH, Darmstadt (DE); Charlotte WALTER, Darmstadt (DE); Jochen PFISTER, Seeheim-Jugenheim (DE); Esther BREUNING, Ober-Ramstadt (DE)

(21) Appl. No.: 17/430,077

(22) PCT Filed: Feb. 10, 2020
(86) PCT No.: PCT/EP2020/053243

§ 371 Date: Aug. 11, 2021

(30) Foreign Application Priority Data
Feb. 11, 2019 (EP) 19156381.6

(51) Int. Cl. C09K 11/06; C07F 15/00; H01L 51/00

(52) U.S. Cl. CPC C09K 11/06; C07F 15/0033; H01L 51/0085; C09K 2211/185; H01L 51/5016; C09K 2211/1088; C09K 2211/1007; C09K 2211/1011; C09K 2211/1029

(57) ABSTRACT

The present invention relates to iridium complexes suitable for use in organic electroluminescent devices, especially as emitters.

The present invention relates to iridium complexes suitable as emitters for use in organic electroluminescent devices.

According to the prior art, triplet emitters used in phosphorescent organic electroluminescent devices (OLEDs) are, in particular, bis- or tris-ortho-metallated iridium complexes having aromatic ligands, where the ligands bind to the metal via a negatively charged carbon atom and an uncharged nitrogen atom or via a negatively charged carbon atom and an uncharged carbene carbon atom. Examples of such complexes are tris(phenylpyridyl)iridium(III) and derivatives thereof, and a multitude of related complexes. The complexes may be homo- or heteroleptic. Complexes of this kind are also known with polypodal ligands, as described, for example, in WO 2016/124304. Even though complexes having polypodal ligands show advantages over the complexes which otherwise have the same ligand structure except that the individual ligands therein do not have polypodal bridging, there is still need for improvement. This lies more particularly in a combination of high efficiency and simultaneously good lifetime of the compounds. Moreover, there is still need for improvement in the voltage shift. The voltage shift refers here to a shift to a higher use voltage and hence also operating voltage when the emitter concentration in the emitting layer is increased. Since, however, a certain concentration of the emitter is required for a good lifetime of the OLED, for example a concentration in the order of magnitude of 7% to 12% for green phosphorescent emitters, it is a disadvantage when the material leads to a voltage shift compared to a lower emitter concentration since the consequence of a higher voltage shift is also a higher absolute operating voltage at a given current density. Since the operating voltage has a direct influence on the power consumption of the OLED, even a slightly higher operating voltage of a material can be an exclusion criterion for this material compared to a reference material. In practice, therefore, the material of choice will typically be a material having a small voltage shift. A smaller voltage shift also generally leads to a higher lifetime of the OLED.

The external quantum efficiency of an OLED is composed of four different factors, namely the charge carrier balance of electrons and holes, the spin multiplicity, the photoluminescence quantum efficiency (PLQE) of the emitter, and the outcoupling factor which describes the proportion of internally generated photons that can be outcoupled from the OLED. The first three factors are also referred to as internal quantum efficiency. The outcoupling factor is determined essentially by the orientation of the complex. The radiation of a dipole is at its strongest at right angles to the alignment of the dipole, such that a horizontal dipole alignment, i.e. with the axis in the plane of the substrate, is desirable (see, for example, T. D. Schmidt et al., Phys. Rev. Applied 8, 037001 (2017)). If it is possible to orient the emitter completely horizontally, the efficiency can be increased by at least 50% compared to isotropic emitter arrangement. One way of improving the efficiency of an OLED is thus to orient the emitters in the layer such that the light is emitted by an optically active, i.e. emissive, ligand, preferably at right angles to OLED layer direction.

In phosphorescent iridium complexes, the transition dipole moment of iridium points toward the emissive ligand of the complex. In order to achieve oriented emission, the transition dipole moment of the emissive ligand must thus be aligned in the plane of the layer. This can be effected by extending the emissive ligand with aromatic radicals in a linear manner in the direction of the transition dipole moment and hence maximizing the van der Waals interaction of these aromatic radicals with the matrix molecules in the layer, as described, for example, in US 2017/0294597 or WO 2018/178001. However, with such metal complexes, a voltage shift toward a higher use voltage is observed in some cases when the emitter concentration in the emissive layer is increased, which can in turn also lead to a higher operating voltage and poorer lifetime.

The problem addressed by the present invention is that of providing improved metal complexes suitable as emitters for use in OLEDs. More particularly, the problem addressed by the invention is that of providing metal complexes that lead to a good or improved EQE when used as emitter in an OLED. A further problem addressed by the present invention is that of providing metal complexes which, when used as emitter in an OLED, lead to a reduction in the voltage shift and hence an improvement in the operating voltage and/or lifetime. The voltage shift refers here, as elucidated above, to a shift to a higher use voltage and hence also operating voltage when the emitter concentration in the emitting layer is increased.

It has been found that, surprisingly, mononuclear iridium complexes having three ortho-metallated bidentate ligands or sub-ligands that show oriented emission simultaneously have good efficiency and a particularly small voltage shift, if any at all, and hence a particularly good operating voltage and lifetime when the angle between the electrical dipole moment of the complex and the transition dipole moment of the complex is not more than 40°. The present invention therefore provides these complexes and organic electroluminescent devices comprising these complexes.

The invention thus provides a mononuclear iridium complex that exhibits oriented emission with an optical orientation anisotropy Θ≤0.24, containing three ortho-metallated bidentate ligands or three ortho-metallated bidentate sub-ligands, characterized in that the angle α(μ_{act},d) between the transition dipole moment μ_{act} and the electrical dipole moment d is ≤40°;

where the following compounds are excluded from the invention:

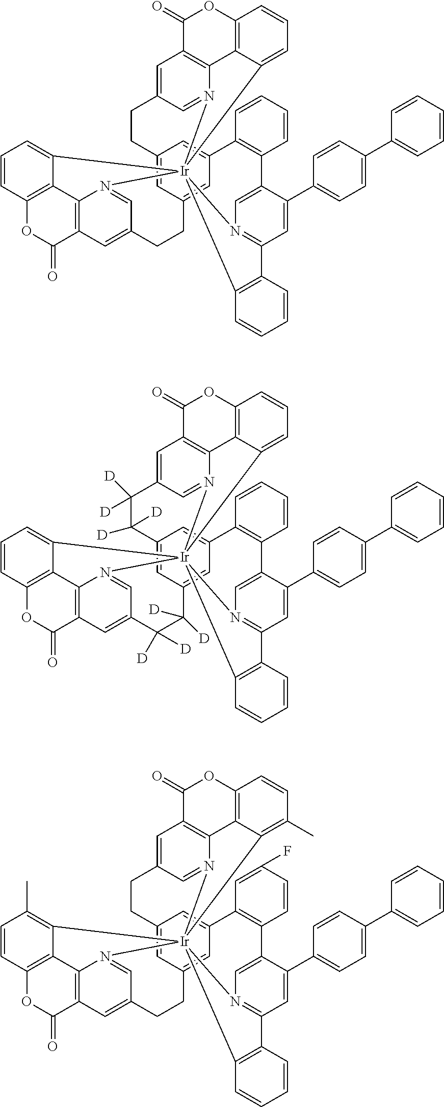

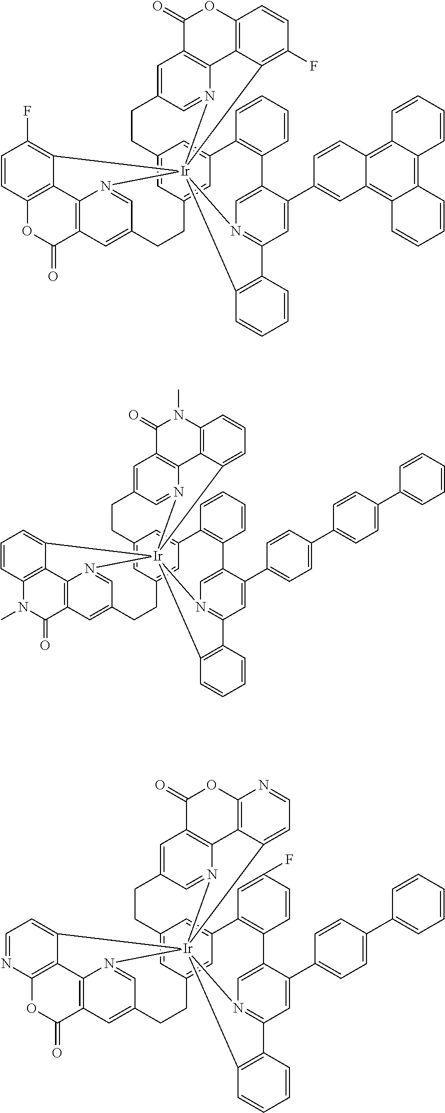

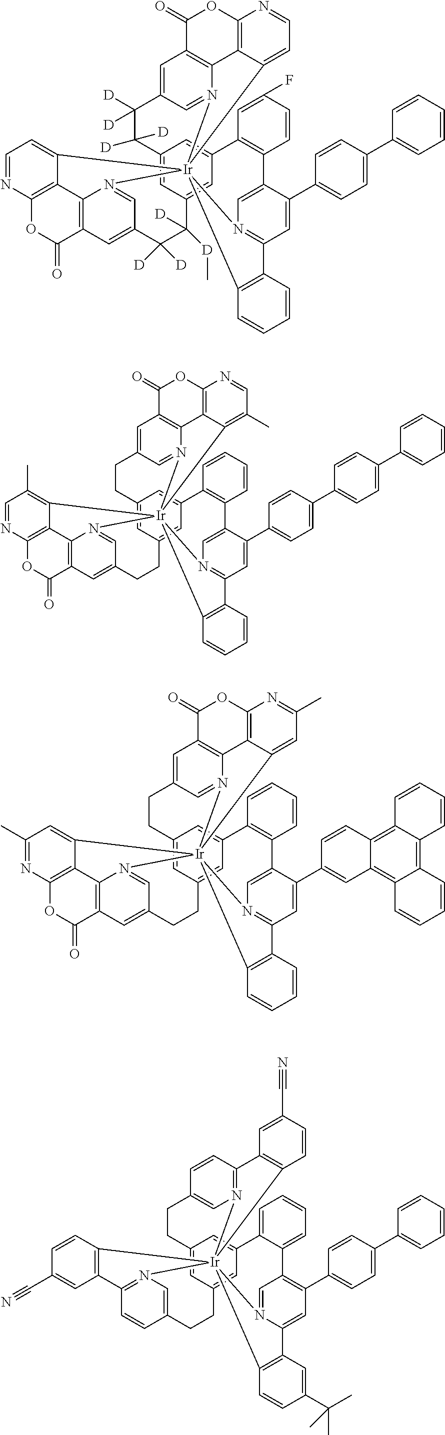

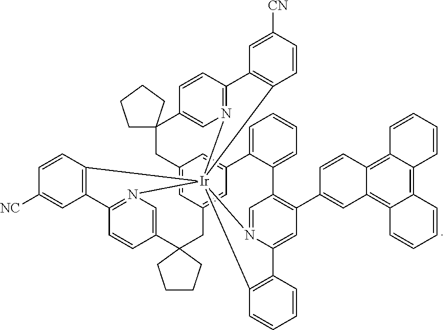

The identification of μ_{act} and d as bold and italic symbols indicates that these are vectors. In general, bold and italic symbols are used in the present application for vectors.

An ortho-metallated bidentate ligand in the context of the present invention is a ligand that binds to the iridium via two coordination sites, where at least one iridium-carbon bond is present. An ortho-metallated bidentate sub-ligand in the context of the present invention likewise binds to the iridium via two coordination sites, where at least one iridium-carbon bond is present, where this sub-ligand is covalently joined to the other two bidentate sub-ligands of the complex via a bridging group to form a polypodal ligand which is hexadentate overall. When the present application says that the ligand or a sub-ligand coordinates or binds to the iridium, this refers in the context of the present application to any kind of bond of the ligand or sub-ligand to the iridium, irrespective of the covalent component of the bond.

The orientation of a complex is possible with heteroleptic complexes in particular, since there can then be a preferred alignment of the octahedral complex. The complexes of the invention are thus preferably heteroleptic complexes, i.e. complexes containing at least two different ligands or sub-ligands. It is preferable here when the complex has two identical bidentate ligands or sub-ligands and a further bidentate ligand or sub-ligand different from the two other ligands or sub-ligands.

In order to obtain oriented emission, it is necessary that the transition dipole moment μ_{act} (where “act” stands for “active”, i.e. the optically active transition dipole moment) of the complex is arranged horizontally, i.e. very substantially parallel, to the layer plane of the OLED. For this purpose, it is preferable that exactly one of the three bidentate ligands or sub-ligands is an emissive or optically active ligand or sub-ligand, where the terms “emissive ligand” and “(optically) active ligand” and the terms “emissive sub-ligand” and “(optically) active sub-ligand” are used synonymously hereinafter. An optically active ligand or sub-ligand in the context of the present invention is understood to mean a ligand or sub-ligand responsible for the emission of the complex. This ligand or sub-ligand is referred to hereinafter as L_{act}, while the two other, optically inactive ligands or sub-ligands are referred to merely as L. The ligand Ir(L) here has a higher triplet energy E_{T1,L} than the ligand Ir(L_{act}) with E_{T1,act}. The condition for the triplet energy ΔE=E_{T1,L}−E_{T1,act}>0 achieves the effect that the emission of the complex comes predominantly from the ligand Ir(L_{act}). The emission of the complex here involves not only the metal but also the active ligand in particular in the transition, as can be inferred from the (electron and spin) densities. Reference is therefore made hereinafter to the emission or the triplet energy of the active ligand L_{act} or to the triplet energy of the ligand L.

The triplet energy of the ligands Ir(L_{act}) and Ir(L) or more generally E_{T1,i} for three ligands i=1, 2, 3 is determined by quantum-chemical calculation, as described in general in part 1.1 of the Examples. It is preferable here when the triplet energy of the ligand Ir(L) is at least 0.05 eV greater than that of the ligand Ir(L_{act}), more preferably at least 0.10 eV greater and most preferably at least 0.20 eV greater.

The person skilled in the art knows in principle which combinations of different ligands can be chosen in order to obtain a complex with exactly one optically active ligand or sub-ligand since he is aware of a multitude of complexes with different ligands and their emission energies. It is thus possible for the person skilled in the art to choose from known homoleptic complexes with known emission energy, or alternatively to calculate the emission energy of corresponding homoleptic complexes. It is then possible to assemble suitable heteroleptic complexes for which the abovementioned energy difference is between Ir(L_{act}) and Ir(L). Then, for the complex thus assembled, it is once again possible to calculate the exact energy of the optically active and inactive ligands or sub-ligands as explained in part 1.1 of the Examples, and hence to check whether the emission colour of the complex meets expectations and whether the abovementioned energy condition is satisfied.

In order to orient the complex in the layer in such a way that oriented emission at right angles to the layer plane is obtained, it is necessary that the optically active ligand or sub-ligand L_{act} is arranged very substantially parallel to the layer plane. This can be achieved in that the optically active ligand or sub-ligand is extended in the direction of the transition dipole moment with an aromatic or heteroaromatic ring system in order thus to maximize the van der Waals interaction of the optically active ligand or sub-ligand with the matrix materials of the layer. The direction of the transition dipole moment within an emitter is determined by quantum chemical calculation, as described in general terms in part 1.3 of the Examples.

The optical orientation anisotropy is defined by the following formula (see T. D. Schmidt et al., Phys. Rev. Applied 8, 037001 (2017), equation (4) in chapter III.B):

$$Θ = {\sum }_{n = 1}^{N} {( {μ}_{act , z}^{n} )}^{2} / {\sum }_{n = 1}^{N} {( {μ}_{act , x}^{n} )}^{2} + {( {μ}_{act , y}^{n} )}^{2} + {( {μ}_{act , z}^{n} )}^{2}$$

where summation is effected over all emitters n=1 . . . N and (μ_{act,z}ⁿ)² is the square of the component of the transition dipole moment μ_{act} of the active ligand of emitter n at right angles to the substrate surface (z=substrate normal), such that the numerator describes the power emitted parallel to the substrate, which is unwanted since it is unfavourable for the outcoupling of light, while the denominator is the sum of the squares of the absolute values of the transition dipole moments of the active ligands of all emitters and hence describes the total power emitted in all directions. For emitters with perfect orientation of the transition dipole moments in the plane of the substrate, i.e. with perfect optical orientation anisotropy, Θ=0, for isotropic orientation Θ=⅓=0.333, and for completely vertical orientation Θ=1. The outcoupling factor and hence the external quantum efficiency is at its highest when Θ is at a minimum.

The structure of the complex and its interaction with the substrate during the vapour deposition process results in the optical orientation anisotropy. This can be determined by the combination of quantum-chemical and molecular dynamics calculations, as described in general terms in part 2 of the Examples. Alternatively, the optical orientation anisotropy can be determined experimentally, as described in T. D. Schmidt et al., Phys. Rev. Applied 8, 037001 (2017) in chapter III.B and Figure (4) and in part 4 of the Examples. In a preferred embodiment of the invention, the optical orientation anisotropy is determined by calculation.

In a preferred embodiment of the invention, the optical orientation anisotropy Θ is ≤0.22, more preferably ≤0.20, even more preferably ≤0.18 and especially preferably ≤0.16.

The electrical dipole moment d of the complex is determined from the structure of the complex. An estimate of the electrical dipole moment of the complex can be made beforehand by the addition of the dipole moments of the individual bidentate ligands or, in the case of a polypodal complex, of the bidentate sub-ligands, where Ir must be replaced by H and the relative orientation of the three ligands in the octahedral binding situation must be taken into account. The electrical dipole moment d can be determined by quantum-chemical calculation as described in general terms in part 1.1 of the Examples.

The angle between the transition dipole moment μ_{act} and the electrical dipole moment d is fixed by the structure of the complex. In a predominant number of the known tris-ortho-metallated iridium complexes that show oriented emission, the electrical dipole moment is aligned here such that the overall result is a layer dipole moment that counteracts the injection of holes from the adjacent hole transport layer. In this case, the angle between the transition dipole moment μ_{act} and the electrical dipole moment d is distinctly greater than 40°, for example 80° for Ir(ppy)₃. If, however, the angle between the transition dipole moment μ_{act}, which must lie in the layer plane owing to favourable orientation anisotropy, and the electrical dipole moment d is <40°, the component of the electrical dipole moment at right angles to the layer plane found from the sine of the angle α is significantly reduced, and so the electrical dipole moment d barely counteracts the injection of charge. This results in a smaller voltage shift.

In a preferred embodiment of the invention, the angle α between the transition dipole moment μ_{act} and the electrical dipole moment d is ≤35°, more preferably ≤30°, even more preferably ≤25° and especially preferably ≤20°. The lower limit for the angle α is 0°. In this case, the transition dipole moments and the electrical dipole moment are aligned parallel to one another, and the electrical dipole moment no longer counteracts the injection of charge when μ_{act} lies in the plane of the substrate.

There follows a description of a method by which suitable iridium complexes can be constructed, in order that they have both the conditions for the optical orientation anisotropy Θ≤0.24 and the required angle α(μ_{act},d)≤40° between the transition dipole moment of the active ligand μ_{act} and the electrical dipole moment d of the complex. The transition dipole moment of the active ligand corresponds essentially to the transition dipole moment of the complex. The method of discovering suitable complexes with optical orientation anisotropy Θ≤0.24 and an angle α(μ_{act},d)≤40° is shown in schematic form by the flow diagram depicted in FIG. 1. Steps 1 to 7 shown in the flow diagram are described in detail hereinafter. Suitable complexes are found by aromatically extending one of the three ligands of a homoleptic starting complex and then electronically modifying the other two.

Step 1: Choose a bidentate ligand L that forms ortho-metallated complexes, and form a homoleptic Ir complex Ir(L)₃ therefrom. Calculate, as described in general terms in part 1 of the Examples, the 3D geometry of the singlet ground state and one of the three (identical) triplet states for the homoleptic complex Ir(L)₃. Calculate, on the basis of the triplet geometry, the direction of the transition dipole moment μ_{L} and the triplet energy E_{T1,L}. On the basis of the metal-to-ligand charge transfer (MLCT) character of the transition, μ_{L} usually points from iridium into the plane of the ligand. This is shown by way of example for Ir(ppy)₃ in FIG. 2, where μ_{L} points in Ir→C5 direction. FIG. 2 shows the transition dipole moment μ_{L} of one of the three ppy ligands, and the electrical dipole moment d of the singlet ground state of Ir(ppy)₃. In the homoleptic complex, the electrical dipole moment d points in the C3 axis of symmetry for reasons of symmetry.

Step 2: In order to position the transition dipole moment in the plane of the substrate as far as possible in the vapour deposition process and hence to maximize the outcoupling of light from the OLED, one of the three ligands is extended with an aromatic system in order to increase the van der Waals interaction of this ligand with the substrate which is formed mainly by the triplet matrix material, compared to the two other ligands. For extension, an aromatic system with triplet energy>E_{T1,L}, i.e. greater than the triplet energy of the homoleptic complex (see part 1.1 of the Examples), with more than 6 carbon atoms is chosen, which increases the molecular mass of the overall complex after the extension preferably to not more than 1500 g/mol, more preferably not more than 1200 g/mol, even more preferably not more than 1000 g/mol and especially preferably not more than 800 g/mol, in order to assure the evaporability of the complex. Useful aromatic systems include very substantially flat units with and without heteroatoms having strong van der Waals interaction, for example triphenylene, biphenyl, terphenyl, dibenzofuran and dibenzothiophene. Examples are shown in FIG. 3.

Whether these systems called “extension unit” hereinafter are suitable is defined by the eigenvalues of the gyration tensor calculated, which is referred to hereinafter as λₘ², m=x, y, z (see part 1.5 of the Examples). The gyration tensor describes the geometry of the emitter. The roots of the eigenvalues have the dimension of length and are sorted by size, such that λ_{z}≥λ_{y}≥λₓ, where the z direction here no longer relates to the substrate normal. If these are in a ratio of 1:1:1, the geometry of the extension unit can be regarded as a sphere, in the case of 1:0:0 as a rod, and for 1:1:0 as a disk. We will restrict ourselves to λₓ/λ_{z}≤0.25 for any λ_{y}/λ_{z} (FIG. 3), i.e. more rod-shaped, such as para-terphenyl with λₓ/λ_{z}≈0.15 and λ_{y}/λ_{z}≈0.2, or disk-shaped, such as triphenylene with λₓ/λ_{z}≈0 and λ_{y}/λ_{z}≈0.85. FIG. 3a) shows a selection of extension units based on the ratio between the roots of the eigenvalues λ_{z}≥λ_{y}≥λₓ of the gyration tensor. The extension units here are already shown with possible single bonds toward the ligand of the Ir complex (calculated as an additional CH₃ group, which does not significantly affect the result). All aromatic and heteroaromatic extension units with λₓ/λ_{z}≤0.25 are suitable, except for phenyl since it contains 6 carbon atoms. Comparatively spherical extension units with λₓ/λ_{z}≥0.25, such as triphenylamine, or nonaromatic extension units, such as cyclohexane or phenylcyclohexane, are unsuitable owing to the weaker van der Waals interaction with the substrate, as shown in FIG. 3b). FIG. 3b) shows the influence of the extension unit R on the optical orientation anisotropy Θ using the example of Ir(ppy-CN)₂(ppy-R). With increasing size of the π system and increasing number of heteroatoms, there is a rise in the van der Waals interaction of R with the triplet matrix material (biphenyl→dibenzofuran→dibenzothiophene), and the optical orientation anisotropy becomes better. The attachment point also plays a role here. Suitable R values are those that lead to Θ≤0.24.

With the aid of suitable extension units, for example for Ir(ppy-CN)₂(ppy), it is possible to reduce the optical orientation anisotropy from the virtually isotropic value Θ=0.31 (without extension) by extending the active ligand with triphenylene or para-terphenyl up to Θ=0.19 (FIG. 3b)). This corresponds to a possible increase in the absolute EQE by about 20% for the complex without extension to about 30% with triphenylene or para-terphenyl, i.e. a relative increase in the EQE by a factor of 1.5. A perfectly oriented emitter would have Θ=0, a totally disoriented one Θ=1, and an exactly isotropic one Θ=⅓.

The eigenvector for the greatest eigenvalue λ_{z}² defines the long axis of the extension unit p_{z}. If two eigenvalues are of equal size, one of the two directions can be selected as extension axis. The attachment point by which the extension unit is bonded by a single bond to a ligand of the complex Ir(L)₃ from step 1 corresponds to the atom for which the bond vector c from the centroid toward this atom forms an angle as close as possible to 0° or 180° with the long axis p_{z}, as shown for biphenyl in FIG. 4a) (see also FIG. 3, where the single bond to the attachment is shown as CH₃).

Step 3: The attachment point for the single bond of the extension unit on the ligand side is chosen such that the angle β_{Cn} formed between μ_{L} or the point reflection of the transition dipole moment in the iridium atom −μ_{L} from step 1, and p_{z} from step 2 is at a minimum (FIG. 4). FIG. 4 a) shows the definition of the long axis p_{z} and the attachment point of the extension unit. FIG. 4 b) shows how the attachment point to the ligand can be discovered via angle β_{Cn} between transition dipole moment of the ligand μ_{L} and p_{z}. For visualization, μ_{L} from step 1 is translated here to every possible attachment point (C1-C11 in FIG. 4 b)) of the ligand. In the case of Ir(ppy)₃ with biphenyl as extension unit, the carbon atom C3 is most suitable as attachment point since β_{C3} is at its smallest together with β_{C10}. A further criterion is to align as many as possible atoms of the active ligand in a linear manner in the μ_{L} or −μ_{L} direction, such that C3 with 7 atoms (Ir,N,C,C,C,C,C) is preferable over attachment point C10 since the Ir→C11 bond does not run along μ_{L} for the latter. Attachment positions with a strong steric demand such as C4 and C7 should be avoided here. The newly formed extended ligand, owing to a somewhat enlarged π electron system, has a smaller triplet energy than the two other ligands L and therefore becomes more optically active, and so we refer to it as L_{act} and the two other ligands as co-ligands L.

Step 4: Then, in the newly formed heteroleptic complex Ir(L)₂L_{act} composed of the two existing ligands L and the new extended ligand L_{act}, the 3D geometry, the electrical dipole moment in the singlet ground state d, the transition dipole moment μ_{act} and the energy of the triplet state E_{T1,act} of the active ligand are calculated, as is also the angle between μ_{act} and d, which is referred to as α(μ_{act},d).

If μ_{act} deviates significantly from the extension axis of the extension unit p_{z}, the next-best attachment point in step 3 should be chosen, since it is otherwise not guaranteed that μ_{act} will be in the plane of the substrate in the vapour deposition. A significant deviation in the context of this invention is a deviation of more than 20°. This would have happened in the case of choice of C10 rather than C3 in step 3, since μ_{act} is then pulled more in the direction of Ir→C11 for C10. In this respect, C3 is more suitable than C10 for the attachment. If μ_{act} lies further in p_{z} direction, the triplet energies E_{T1,L} in the heteroleptic complex and their transition dipole moments μ_{L} are calculated for the two co-ligands as well, since these are required later on for calculation of the optical orientation anisotropy.

FIG. 5 shows Ir(L)₂L_{act}=Ir(ppy)₂(ppy-C3-biphenyl) as an example, where μ_{act} of the extended ligand, compared to the “old” μ_{L} from Ir(ppy)₃, moves even closer to the extension axis p_{z} that was to be expected from the homoleptic Ir(ppy)₃ complex (“old” μ_{L} as a dotted line), such that β′_{C3} becomes even smaller than was to be expected from the visualization in step 3 with β_{C3}, which is better for the optical orientation. In that respect, the attachment point at C3 can be retained, while an extension at C10 would probably have been worse. In aromatically extended ppy ligands, μ_{act} constantly moves closer in Ir→N direction, such that the extension in the para position to Ir→N (C3 in FIG. 5) is often the best choice.

As shown in FIG. 5 c), owing to the loss of symmetry between the ligands, the electrical dipole moment of the overall molecule d is no longer exactly on top of the pseudo-C3 axis of symmetry, but has been shifted more in the direction of the active ligand, which reduces the angle α(μ_{act},d). The angle between μ_{act} of the active ligand and the electrical dipole moment of the overall molecule is α(μ_{act},d)=55°, i.e. is still α(μ_{act},d)>40°. Thus, Ir(ppy)₂(ppy-C3-biphenyl) is not in accordance with the invention.

Step 5: If α(μ_{act},d)≤40° is not satisfied, the introduction of electronically active groups such as CN, F, N, O, etc. in the two co-ligands can significantly alter the electrical dipole moment of the two co-ligands (with Ir notionally replaced with H) in terms either of its contribution or of its direction in the plane of the co-ligand. Thus, the electrical dipole moment of the overall molecule which results roughly from the vector addition of the three electrical dipole moments of the ligands (in each case with Ir notionally replaced by H), as a result of these electronically active groups, can be shifted away from the pseudo-C3 axis of symmetry and hence closer to μ_{act}, such that α(μ_{act},d) is distinctly reduced. A modification of the co-ligands here usually does not lead to a significant change in the transition dipole moment of the active ligand.

In the case of Ir(ppy)₂(ppy-C3-biphenyl) with a fixed active ligand (ppy-C3-biphenyl), the electrical dipole moment of the active ligand (with Ir notionally replaced by H) is close to the transition dipole moment of the active ligand, i.e. along Ir→N. Since the electrical dipole moment for the ppy co-ligand (with Ir notionally replaced by H) at first also points in a similar direction within the plane of the ligand (along Ir→N), and in terms of magnitude is only somewhat smaller than the magnitude of the electrical dipole moment of the active ligand, the electrical dipole moment of the overall Ir(ppy)₂(ppy-C3-biphenyl) complex, owing to the vector addition of the three electrical dipole moments of the ligands in the octahedral binding situation of the facial complex, is slightly removed from the pseudo-C3 axis of symmetry in the active ligand direction and therefore forms an excessively large angle with the transition dipole moment of the active ligand α(μ_{act},d)=55°. As shown in FIG. 6, therefore, the angle has been reduced compared to the homoleptic Ir(ppy)₃ because μ_{act} after the extension no longer points along Ir→C5 but in the Ir→N direction and d is shifted slightly away from the C3 axis of symmetry in the μ_{act} direction.

In order to remove the electrical dipole moment of the overall molecule even further from the pseudo-C3 axis of symmetry, ppy-based co-ligands altered electronically along the C7, C8 and/or C9 position are now suitable rather than L=ppy. They can lead to smaller angles α(μ_{act},d) via two effects, which can be illustrated by a three-dimensional vector model of the electrical dipole moments of the three ligands.

Firstly, the electrical asymmetry between the Ir-bonded N and C of the phenylpyridine can be compensated for, which minimizes the magnitude of the electrical dipole of the co-ligand and hence leads inevitably to smaller angles α(μ_{act},d) since the electrical dipole moment of the active ligand points in the same direction as the transition dipole moment of the active ligand. Secondly, the direction of the electrical dipole moment of the co-ligand can be altered so significantly that, on vector addition of the three electrical dipole moments of the ligands, the resulting total electrical dipole moment of the complex lies far away from the C3 axis of symmetry and closer to the transition dipole moment of the active ligand. This is the case when, in Ir(ppy)₂(ppy-C3-biphenyl), one cyano group is introduced into each of the two co-ligands at position C8 or better still at C7 (FIG. 6), such that the direction of the electrical co-ligand dipole changes significantly compared to ppy, and so it follows that α(μ_{act},d)=45° for C8 or better still α(μ_{act},d)=25° for C7. For instance, for Ir(ppy-C7-CN)₂(ppy-C3-biphenyl), the first of the two criteria for the invention is satisfied since α(μ_{act},d)≤40°.

FIG. 6 shows that, in the homoleptic complex Ir(ppy)₃, the electrical dipole moment d is in the C3 axis of symmetry and α(μ_{act},d)=80°. The electrical dipole moments of the three ligands all point in the same direction within the plane of the ligand (Ir→N). Extension of the active ligand breaks the symmetry, and d points somewhat more along the active ligand since the magnitude of the electrical dipole of the extended ligand grows. At the same time, there is also a change in the direction of μ_{act} compared to Ir(ppy)₃, such that α(μ_{act},d)=55°. By means of electronically active cyano groups in the two co-ligands at position C8 or C7, it is possible to remove d further from the C3 axis of symmetry since the direction of the electrical dipole moments of the co-ligands in the plane of the co-ligands is significantly altered compared to ppy, and so, ultimately, α(μ_{act},d)=25°, i.e. α≤40° for Ir(ppy-C7-CN)₂(ppy-C3-biphenyl).

Further examples of electronically modified ppy co-ligands that lead to small angles α(μ_{act},d) with the active ppy-C3-biphenyl ligand in a similar manner to that for Ir(ppy-C7-CN)₂(ppy-C3-biphenyl) are shown in FIG. 7. It is shown here in FIG. 7a) that the electronically modified ppy ligands, owing to altered electrical dipole moments (see arrows), lead to small angles α(μ_{act},d) between transition dipole moment μ_{act} and electrical dipole moment d of the overall complex Ir(L)₂L_{act} with active ppy-C3-terphenylligand. They lead either to a small magnitude of the electrical dipole of the co-ligand (the length of the vectors depicted corresponds to the magnitude), as is the case for the co-ligand 55, or to a distinct change in direction of the electrical dipole moment of the co-ligand compared to ppy, as is the case for the co-ligand 14—this is the co-ligand of Ir(ppy-C7-CN)₂(ppy-C3-biphenyl).

FIG. 7b) shows the optical orientation anisotropy Θ and the angle α(μ_{act},d) for co-ligands L from FIG. 7a) in combination with active (ppy-C3-terphenyl), once without polypodal bridging and once with polypodal bridging (identified in the nomenclature by the addition “poly” for polypodal). The homoleptic reference complex Ir(ppy)₃ has virtually isotropic optical orientation of Θ=0.31 and a very large angle α(μ_{act},d)=80° (see also FIG. 6), i.e. is optically and electrically unsuitable. Extension with a para-terphenyl group leads to better optical and electrical properties. Introduction of the polypodal cap leads to an improvement in the optical orientation at the cost of a slightly higher angle since conjugation overhead has the effect that the electrical dipole moment remains somewhat closer to the pseudo-axis of symmetry. Modification of the co-ligands with electronically active groups leads to even smaller angles α(μ_{act},d), such that both α(μ_{act},d)≤40° and Θ≤0.24 are possible and all compounds in the top-left quadrant are suitable. The introduction of a polypodal cap for bridging of the three ligands barely changes the direction of μ_{act}, but affects the optical order parameter Θ. At the bottom of FIG. 7b), α(μ_{act},d) and Θ for all-co-ligands are combined always with the same active ligand (ppy-C3-biphenyl), once with and once without a polypodal cap.

Step 6: If α(μ_{act},d)≤40° for Ir(L)₂L_{act}, it is necessary to verify, as a second criterion, that the optical orientation anisotropy Θ≤0.24 is satisfied in order to enable good outcoupling characteristics and hence high efficiency. Following the construction rules as described in step 1 to step 5, this is usually the case (for exceptions see step 7 below).

It is possible here to measure the optical orientation anisotropy Θ for a mixed film of the synthesized complex in a proportion of 10% by volume in a triplet matrix material as reference material by angle-dependent photoluminescence (see part 3 of the Examples “Measurement of emitter orientation in the vapour-deposited film”). However, Θ is preferably calculated by means of molecular dynamics simulation of the vapour deposition process based on the geometries, energies and transition dipole moments, determined by quantum-chemical means in step 4, of the three triplet states in Ir(L)₂L_{act} (see part 2 of the Examples). Moreover, the calculation has the advantage of determining the three individual optical orientation anisotropies Θ_{1=act}, Θ_{2=L}, Θ_{3=L} of the three ligands in the heteroleptic complex that generate the overall value Θ by averaging via energetics (Boltzmann distribution) and rates. The calculated Θ give a good correlation with the management (correlation coefficient R²=0.70 for 30 tested emitters).

Step 7: If, in the calculation, the optically active ligand is in the plane of the substrate when Θ_{1=act}≤0.24, but at least one of the two co-ligands has poorer optical orientation (Θ_{2=L}, Θ_{3=L}>0.24), a possible result of the averaging of the three contributions is that, overall, Θ>0.24.

In this case, increasing the triplet energy differential ΔE=E_{T1,L}−E_{T1,act} between the active ligand and the two co-ligands can achieve the effect that the emission of the two co-ligands Θ≤0.24 is suppressed. In order to achieve this, the co-ligands can be blue-shifted by introducing heteroatoms such as F, CN, N or O, or the active ligand can be red-shifted by enlarging the π system. However, since such modifications also entail a change in the angle α(μ_{act},d), it is then necessary to start again at step 4.

This is unnecessary in the case of Ir(ppy-C7-CN)₂(ppy-C3-biphenyl) from FIG. 6 since the energy differential ΔE≈0.1 eV, which corresponds to about 4k_{B}T at room temperature (with the Boltzmann constant k_{B} and the temperature T), such that the emission of the co-ligands is weaker at least by a factor of exp(4)=50 than the emission of the active ligand, and so only the active ligand has relevant emission.

In rare cases, it is found that Θ_{1=act}>0.24 even though, as explained in the construction method in steps 1 to 5, μ_{act} points along p_{z}. This means that the extension of the active ligand was not strong enough, which may, for example, be because of an excessively strong van der Waals interaction of the co-ligands with the substrate. In that case, it is then possible, for example, to extend the active ligand not with biphenyl but with terphenyl or triphenylene (see FIG. 3 b)). It is also possible for sterically demanding alkylic substituents to lead to Θ_{1=act}>0.24. In such cases, even a larger extension unit on the active ligand is unhelpful, the iteration process has to be started again at step 5, step 2 or even at step 1.

A suitable complex Ir(L)₂L_{act} has been found when both α(μ_{act},d)≤40° and Θ≤0.24 are satisfied. Because Θ≤0.24, this complex enables good light outcoupling and hence high efficiencies, but at the same time does not show any shift in voltage since the electrical dipole moments d of the complexes are then more likely to be in the plane of the substrate together with μ_{act}, such that they cannot generate a strong electrical field in transport direction.

In a preferred embodiment of the invention, the complex of the invention has a photoluminescence quantum efficiency of more than 0.85, preferably more than 0.9 and more preferably more than 0.95. The photoluminescence quantum efficiency is measured as described in general terms in the Examples at the back.

In structural terms, the iridium complexes of the invention can be represented by the formulae (1) and (2)

L_{act} in formula (1) represents the optically active ortho-metallated bidentate ligand or, in formula (2), the optically active ortho-metallated bidentate sub-ligand. L is the same or different at each instance in formula (1) and represents the optically inactive ortho-metallated bidentate ligands or, in formula (2), the optically inactive ortho-metallated bidentate sub-ligands. V in formula (2) is a bridging unit that joins the sub-ligands L_{act} and L covalently to one another to form a tripodal hexadentate ligand. Preference is given to the tripodal complexes of the formula (2).

The ligand in formula (2) is a hexadentate tripodal ligand having one bidentate sub-ligand L_{act} and two bidentate sub-ligands L. “Bidentate” means that the particular sub-ligand in the complex coordinates or binds to the iridium via two coordination sites. “Tripodal” means that the ligand has three sub-ligands bonded to the bridge V. Since the ligand has three bidentate sub-ligands, the overall result is a hexadentate ligand, i.e. a ligand which coordinates or binds to the iridium via six coordination sites. The expression “bidentate sub-ligand” in the context of this application means that L_{act} and L would each be a bidentate ligand if the bridge V were absent. However, as a result of the formal abstraction of a hydrogen atom from this bidentate ligand and the attachment to the bridge, it is no longer a separate ligand but a portion of the hexadentate ligand which thus arises, and so the term “sub-ligand” is used therefor.

The bidentate ortho-metallated ligands or sub-ligands L_{act} and L are described hereinafter. The ligands or sub-ligands L_{act} and L coordinate to the iridium via one carbon atom and one nitrogen atom or via two carbon atoms. When L_{act} or L coordinates to the iridium via two carbon atoms, one of the two carbon atoms is a carbene carbon atom. In addition, L is different from L_{act} since L_{act} is an optically active ligand or sub-ligand, while L is optically inactive. In a preferred embodiment of the invention, the two ligands or sub-ligands L are identical.

More preferably, each ligand or sub-ligand L_{act} and L has one carbon atom and one nitrogen atom as coordinating atoms.

It is further preferable when the metallacycle which is formed from the iridium and the ligand or sub-ligand L_{act} and L is a five-membered ring. This is shown schematically hereinafter:

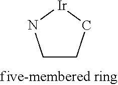

where N represents a coordinating nitrogen atom and C a coordinating carbon atom, and the carbon atoms shown represent atoms of the ligand or sub-ligand L_{act} or L.

As described above, the structure fragment Ir(L) has a higher triplet energy than the structure fragment Ir(L_{act}) with the optically active ligand or sub-ligand. This achieves the effect that the emission from the complex comes predominantly from the structure fragment Ir(L_{act}).

In a preferred embodiment of the invention, the ligands or sub-ligands L_{act} and L are a structure of the following formula (L-1) or (L-2), where L_{act} and L are different from one another and the two ligands or sub-ligands L may be the same or different, but are preferably the same,

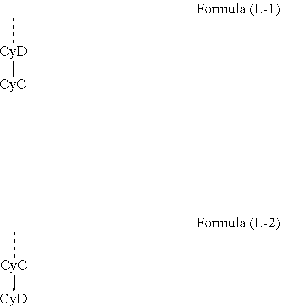

where the dotted bond represents the bond of the sub-ligand to the bridge V in formula (2) and is absent for formula (1) and where the other symbols used are as follows:
CyC is the same or different at each instance and is a substituted or unsubstituted aryl or heteroaryl group which has 5 to 14 aromatic ring atoms and coordinates in each case to the metal via a carbon atom and which is bonded to CyD via a covalent bond;
CyD is the same or different at each instance and is a substituted or unsubstituted heteroaryl group which has 5 to 14 aromatic ring atoms and coordinates to the metal via a nitrogen atom or via a carbene carbon atom and which is bonded to CyC via a covalent bond;
   at the same time, two or more of the optional substituents together may form a ring system; the optional radicals are preferably selected from the R radicals defined below.

CyD coordinates via an uncharged nitrogen atom or via a carbene carbon atom, and CyC coordinates via an anionic carbon atom.

When two or more of the substituents, especially two or more R radicals, together form a ring system, it is possible for a ring system to be formed from substituents bonded to directly adjacent carbon atoms. In addition, it is also possible that the substituents on CyC and CyD or on the two CyD groups together form a ring, as a result of which CyC and CyD may also together form a single fused aryl or heteroaryl group as bidentate ligand.

Preferably, all ligands or sub-ligands L_{act} and L have a structure of the formula (L-1), or all ligands or sub-ligands L_{act} and L have a structure of the formula (L-2). L_{act} is different from L, and the two sub-ligands L are preferably the same.

In a preferred embodiment of the present invention, CyC is an aryl or heteroaryl group having 6 to 13 aromatic ring atoms, more preferably having 6 to 10 aromatic ring atoms, most preferably having 6 aromatic ring atoms, which coordinates to the metal via a carbon atom, which may be substituted by one or more R radicals and which is bonded to CyD via a covalent bond.

Preferred embodiments of the CyC group are the structures of the following formulae (CyC-1) to (CyC-19) where the CyC group binds in each case at the position signified by # to CyD and coordinates at the position signified by * to the iridium,

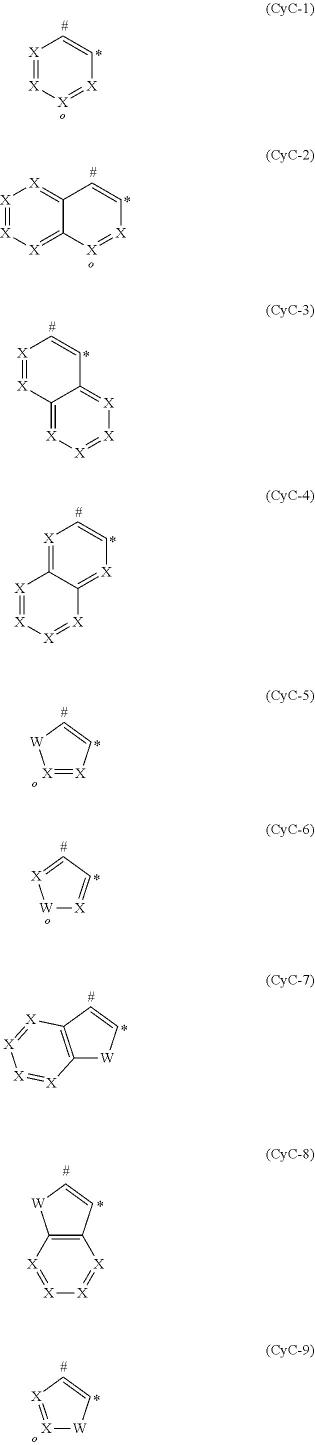

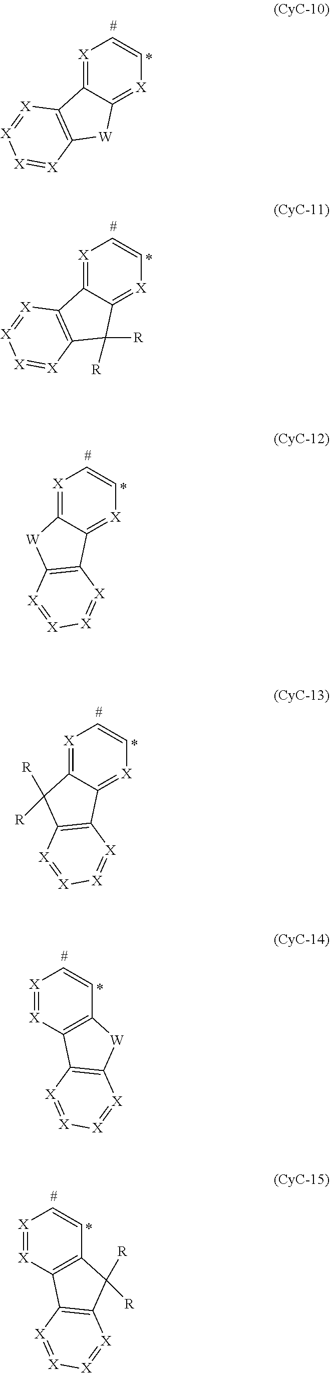

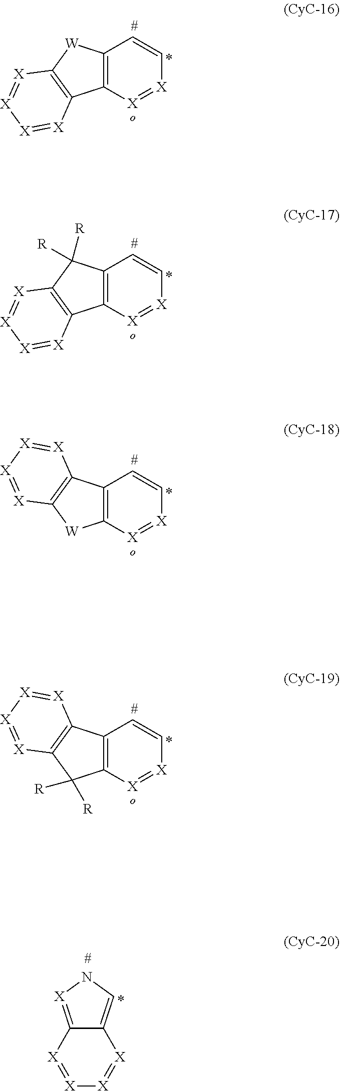

where the symbols used are as follows:
X is the same or different at each instance and is CR or N, with the proviso that at most two symbols X per ring are N;
W is the same or different at each instance and is NR, O or S;
R is the same or different at each instance and is H, D, F, Cl, Br, I, N(R¹)₂, OR¹, SR¹, CN, NO₂, COOR¹, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, especially a hydrocarbyl radical, having 1 to 20 carbon atoms, in which one or more hydrogen atoms may also be replaced by F;
   with the proviso that, when the bridge V is bonded to CyC in formula (2), one symbol X is C and the bridge V is bonded to this carbon atom. When the CyC group is bonded to the bridge V, the bond is preferably via the position marked “o” in the formulae depicted above, and so the symbol X marked “o” in that case is preferably C. The above-depicted structures which do not contain any symbol X marked “o” are preferably not bonded directly to the bridge V, since such a bond to the bridge is not advantageous for steric reasons.

When two R or R¹ radicals together form a ring system, it may be mono- or polycyclic, aliphatic, heteroaliphatic, aromatic or heteroaromatic. In this case, these radicals which together form a ring system may be adjacent, meaning that these radicals are bonded to the same carbon atom or to carbon atoms directly bonded to one another, or they may be further removed from one another. Preference is given to this kind of ring formation in radicals bonded to carbon atoms directly bonded to one another.

The wording that two or more radicals together may form a ring, in the context of the present description, should be understood to mean, inter alia, that the two radicals are joined to one another by a chemical bond with formal elimination of two hydrogen atoms. This is illustrated by the following scheme:

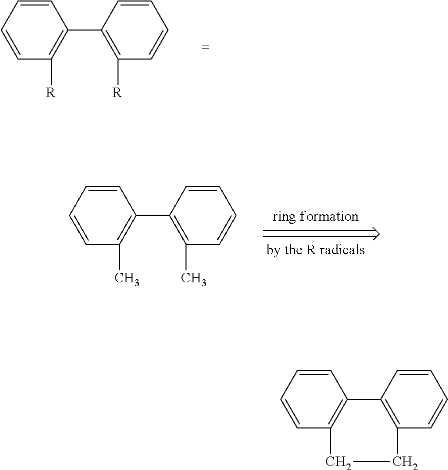

In addition, the abovementioned wording shall also be understood to mean that, if one of the two radicals is hydrogen, the second radical binds to the position to which the hydrogen atom was bonded, forming a ring. This shall be illustrated by the following scheme:

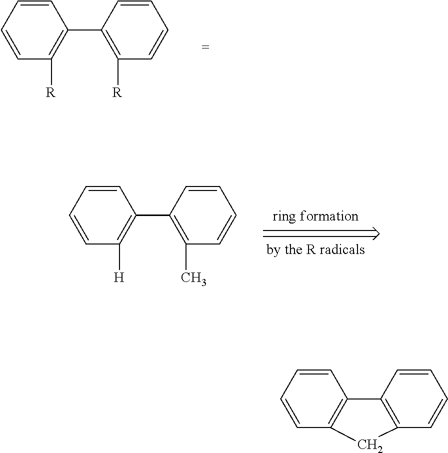

In addition, the abovementioned wording shall also be understood to mean that, if the two radicals are alkenyl groups, the radicals together form a ring, forming a fused-on aryl group. Analogously, the formation of a fused-on benzofuran group is possible in the case of an aryloxy substituent, and the formation of a fused-on indole group in the case of an arylamino substituent. This shall be illustrated by the following schemes:

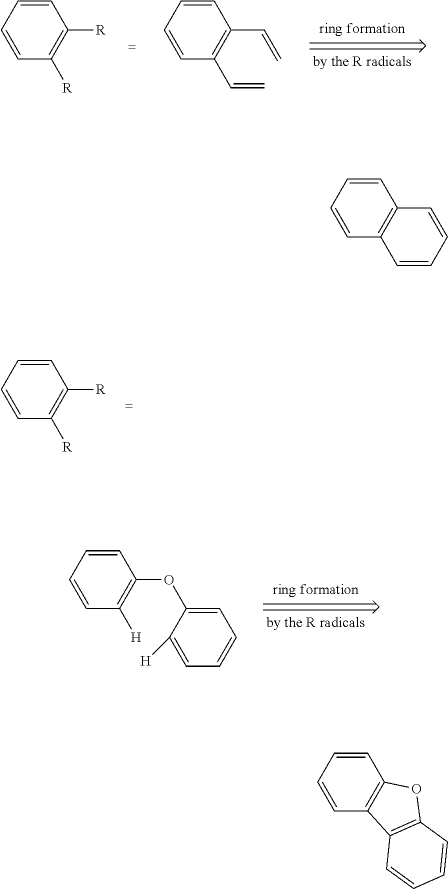

A cyclic alkyl, alkoxy or thioalkoxy group in the context of this invention is understood to mean a monocyclic, bicyclic or polycyclic group.

In the context of the present invention, a C₁- to C₂₀-alkyl group in which individual hydrogen atoms or CH₂ groups may also be replaced by the abovementioned groups is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. An OR¹ group is understood to mean, for example, methoxy, trifluoromethoxy, ethoxy, n-propoxy, i-propoxy, n-butoxy, i-butoxy, s-butoxy, t-butoxy or 2-methylbutoxy.

An aryl group in the context of this invention contains 6 to 30 carbon atoms, a heteroaryl group in the context of this invention contains 2 to 30 carbon atoms and at least one heteroatom, with the proviso that the sum total of carbon atoms and heteroatoms is at least 5. The heteroatoms are preferably selected from N, O and/or S. Here, an aryl group or heteroaryl group is understood to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic systems joined to one another by a single bond, for example biphenyl, by contrast, are not referred to as an aryl or heteroaryl group but as an aromatic ring system.

An aromatic ring system in the context of this invention contains 6 to 40 carbon atoms, preferably 6 to 30 carbon atoms, in the ring system. A heteroaromatic ring system in the context of this invention contains 2 to 40 carbon atoms, preferably 2 to 30 carbon atoms, and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for two or more aryl or heteroaryl groups to be joined by a nonaromatic unit, for example a carbon, nitrogen or oxygen atom. These shall likewise be understood to mean systems in which two or more aryl or heteroaryl groups are joined directly to one another, for example biphenyl, terphenyl, bipyridine or phenylpyridine. For example, systems such as fluorene, 9,9′-spirobifluorene, 9,9-diarylfluorene, triarylamine, diaryl ethers, stilbene, etc. shall also be regarded as aromatic ring systems in the context of this invention, and likewise systems in which two or more aryl groups are joined, for example, by a short alkyl group. Preferred aromatic or heteroaromatic ring systems are simple aryl or heteroaryl groups and groups in which two or more aryl or heteroaryl groups are joined directly to one another, for example biphenyl or bipyridine, and also fluorene or spirobifluorene.

An aromatic or heteroaromatic ring system which has 5-40 aromatic ring atoms and may also be substituted in each case by the abovementioned R² radicals or a hydrocarbyl radical and which may be joined to the aromatic or heteroaromatic system via any desired positions is understood to mean especially groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or groups derived from a combination of these systems.

Preferably, a total of not more than two symbols X in CyC are N, more preferably not more than one symbol X in CyC is N, and most preferably all symbols X are CR, with the proviso that, when the bridge V in formula (2) is bonded to CyC, one symbol X is C and the bridge V is bonded to this carbon atom.

Particularly preferred CyC groups are the groups of the following formulae (CyC-1a) to (CyC-20a):

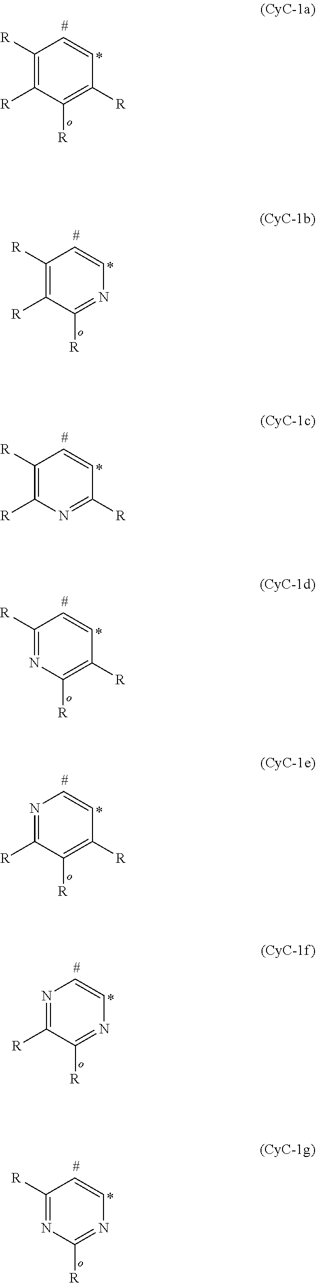

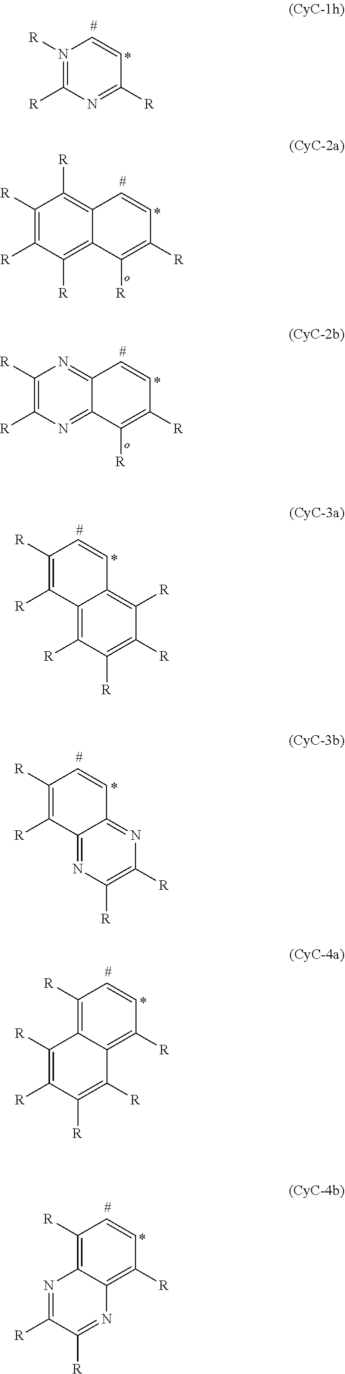

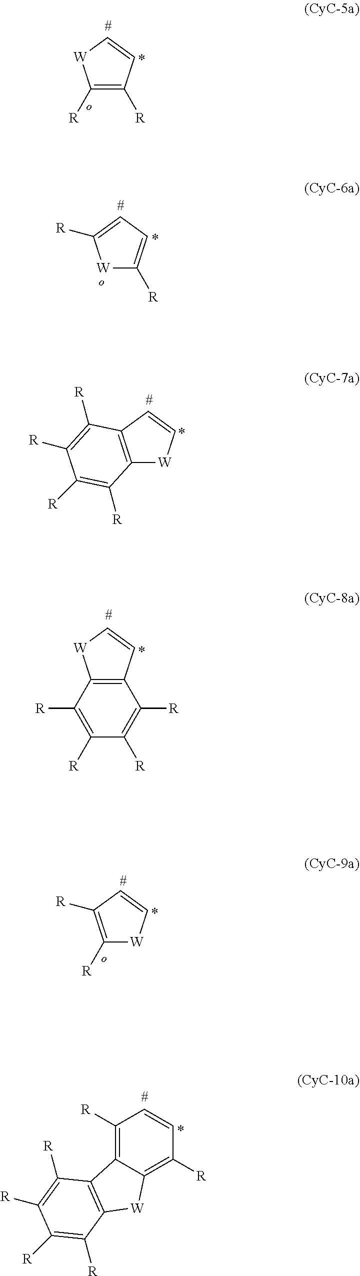

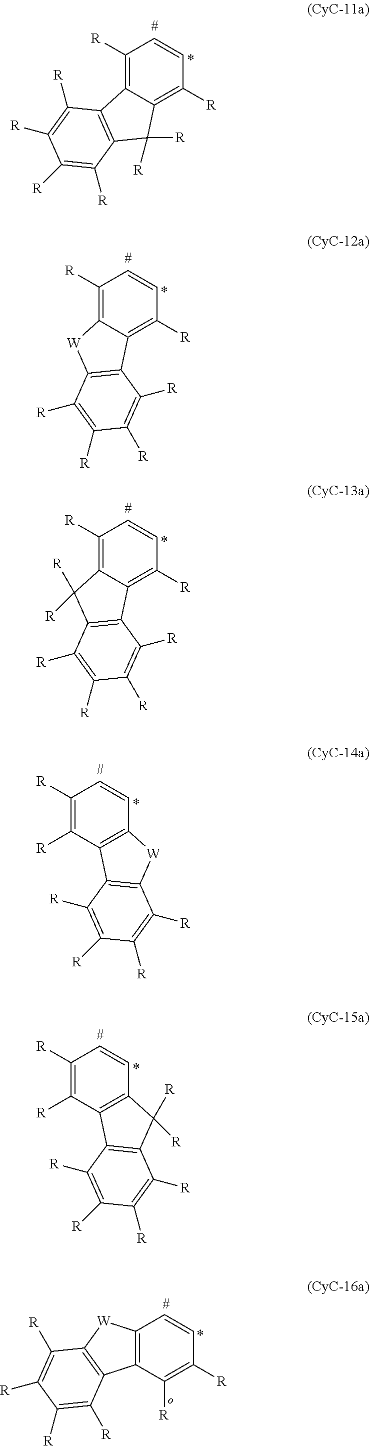

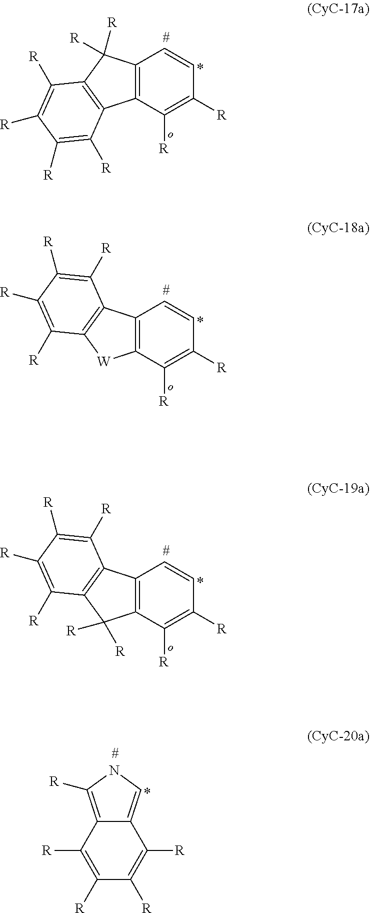

where the symbols used have the definitions given above and, when the bridge V is bonded to CyC in formula (2), one R radical is absent and the bridge V is bonded to the corresponding carbon atom. When the CyC group is bonded to the bridge V, the bond is preferably via the position marked “o” in the formulae depicted above, and so the R radical in this position in that case is preferably absent. The above-depicted structures which do not contain any carbon atom marked “o” are preferably not bonded directly to the bridge V.

Preferred groups among the (CyC-1) to (CyC-19) groups are the (CyC-1), (CyC-3), (CyC-8), (CyC-10), (CyC-12), (CyC-13) and (CyC-16) groups, and particular preference is given to the (CyC-1a), (CyC-3a), (CyC-8a), (CyC-10a), (CyC-12a), (CyC-13a) and (CyC-16a) groups.

In a further preferred embodiment of the invention, CyD is a heteroaryl group having 5 to 13 aromatic ring atoms, more preferably having 6 to 10 aromatic ring atoms, which coordinates to the metal via an uncharged nitrogen atom or via a carbene carbon atom and which may be substituted by one or more R radicals and which is bonded via a covalent bond to CyC.

Preferred embodiments of the CyD group are the structures of the following formulae (CyD-1) to (CyD-18) where the CyD group binds in each case at the position signified by # to CyC and coordinates at the position signified by * to the iridium,

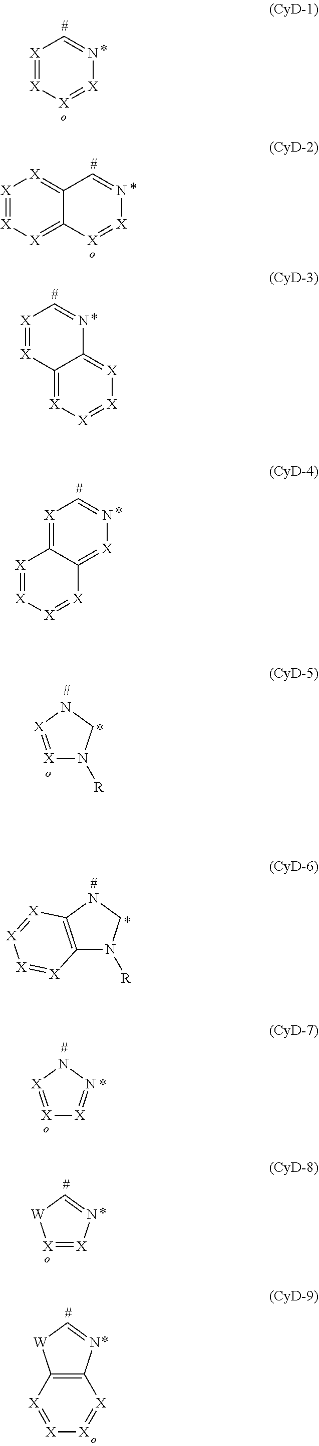

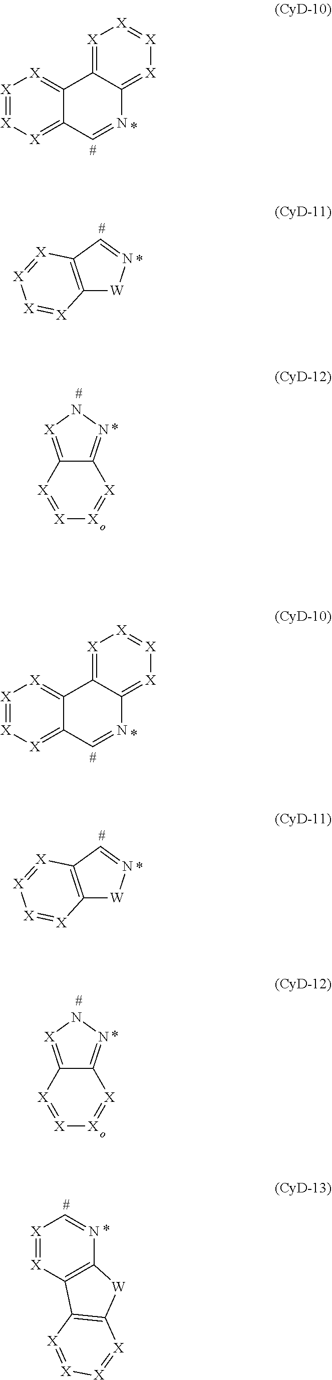

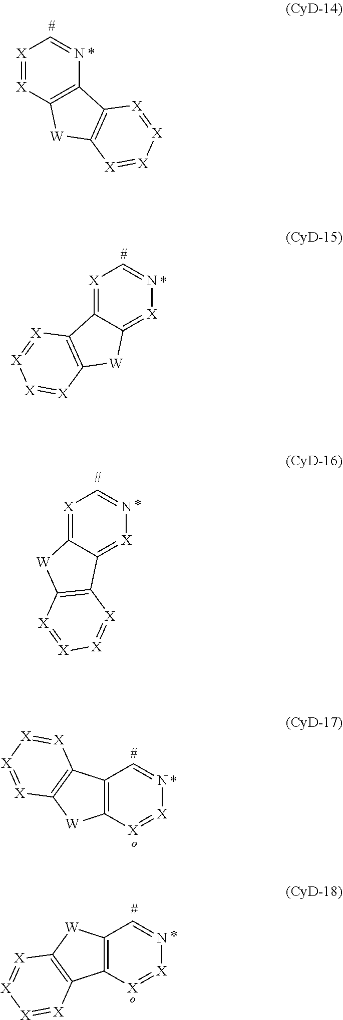

where X, W and R have the definitions given above, with the proviso that, when the bridge V in formula (2) is bonded to CyD, one symbol X is C and the bridge V is bonded to this carbon atom. When the CyD group is bonded to the bridge V, the bond is preferably via the position marked “o” in the formulae depicted above, and so the symbol X marked “o” in that case is preferably C. The above-depicted structures which do not contain any symbol X marked “o” are preferably not bonded directly to the bridge V, since such a bond to the bridge is not advantageous for steric reasons.

In this case, the (CyD-1) to (CyD-4) and (CyD-7) to (CyD-18) groups coordinate to the iridium via an uncharged nitrogen atom, and (CyD-5) and (CyD-6) groups via a carbene carbon atom.

Preferably, a total of not more than two symbols X in CyD are N, more preferably not more than one symbol X in CyD is N, and especially preferably all symbols X are CR, with the proviso that, when the bridge V in formula (2) is bonded to CyD, one symbol X is C and the bridge V is bonded to this carbon atom.

Particularly preferred CyD groups are the groups of the following formulae (CyD-11a) to (CyD-18a):

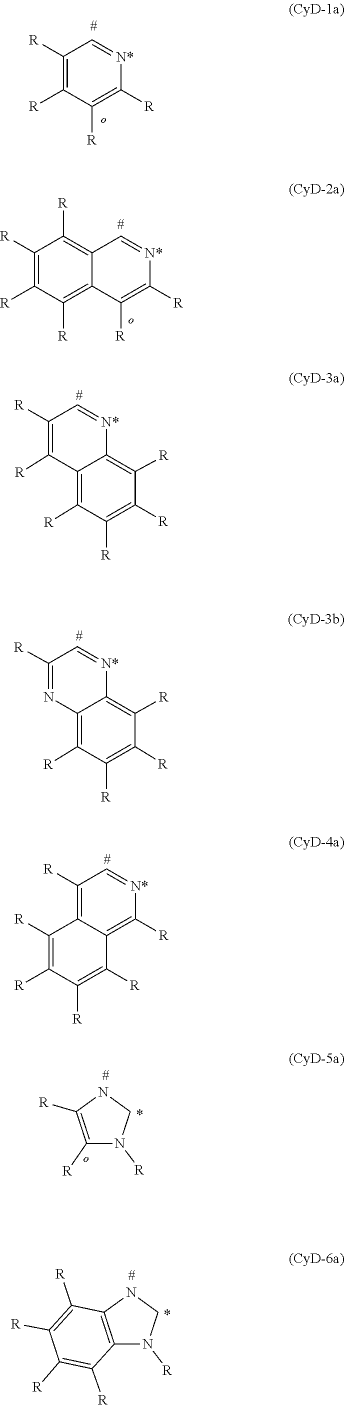

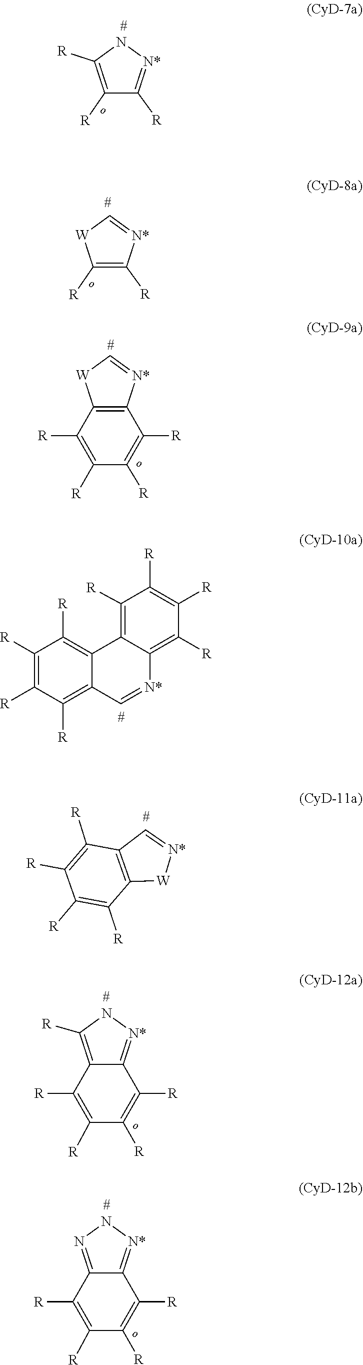

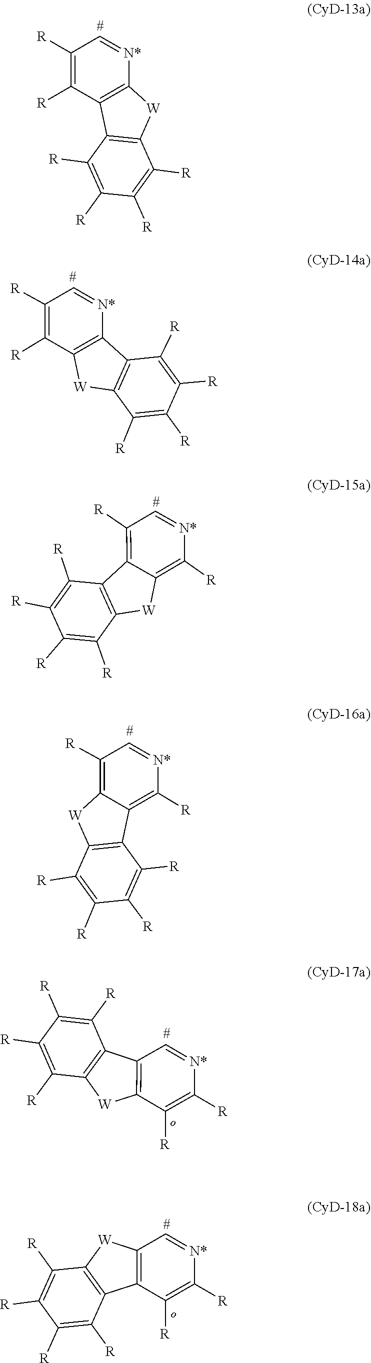

where the symbols used have the definitions given above and, when the bridge V is bonded to CyD in formula (2), one R radical is absent and the bridge V is bonded to the corresponding carbon atom. When the CyD group is bonded to the bridge V, the bond is preferably via the position marked “o” in the formulae depicted above, and so the R radical in this position in that case is preferably absent. The above-depicted structures which do not contain any carbon atom marked “o” are preferably not bonded directly to the bridge V.

Preferred groups among the (CyD-1) to (CyD-12) groups are the (CyD-1), (CyD-2), (CyD-3), (CyD-4), (CyD-5) and (CyD-6) groups, especially (CyD-1), (CyD-2) and (CyD-3), and particular preference is given to the (CyD-1a), (CyD-2a), (CyD-3a), (CyD-4a), (CyD-5a) and (CyD-6a) groups, especially (CyD-1a), (CyD-2a) and (CyD-3a).

In a preferred embodiment of the present invention, CyC is an aryl or heteroaryl group having 6 to 13 aromatic ring atoms, and at the same time CyD is a heteroaryl group having 5 to 13 aromatic ring atoms. More preferably, CyC is an aryl or heteroaryl group having 6 to 10 aromatic ring atoms, and at the same time CyD is a heteroaryl group having 5 to 10 aromatic ring atoms. Most preferably, CyC is an aryl or heteroaryl group having 6 aromatic ring atoms, and CyD is a heteroaryl group having 6 to 10 aromatic ring atoms. At the same time, CyC and CyD may be substituted by one or more R radicals.

The abovementioned preferred groups (CyC-1) to (CyC-20) and (CyD-1) to (CyD-18) may be combined with one another as desired. It is necessary here for compounds of the formula (2) that at least one of the CyC or CyD groups has a suitable linkage site to the bridge V, where suitable linkage sites in the abovementioned formulae are identified by “o”.

It is especially preferable when the CyC and CyD groups mentioned as particularly preferred above, i.e. the groups of the formulae (CyC-1a) to (CyC-20a) and the groups of the formulae (CyD1-a) to (CyD-18a), are combined with one another.

It is very particularly preferable when one of the (CyC-1), (CyC-3), (CyC-8), (CyC-10), (CyC-12), (CyC-13) and (CyC-16) groups, especially the (CyC-1a), (CyC-3a), (CyC-8a), (CyC-10a), (CyC-12a), (CyC-13a) and (CyC-16a) groups, is combined with one of the (CyD-1), (CyD-2) and (CyD-3) groups, especially with one of the (CyD-1a), (CyD-2a) and (CyD-3a) groups.

Preferred sub-ligands (L-1) are the structures of the formulae (L-1-1) and (L-1-2), and preferred sub-ligands (L-2) are the structures of the formulae (L-2-1) to (L-2-4):

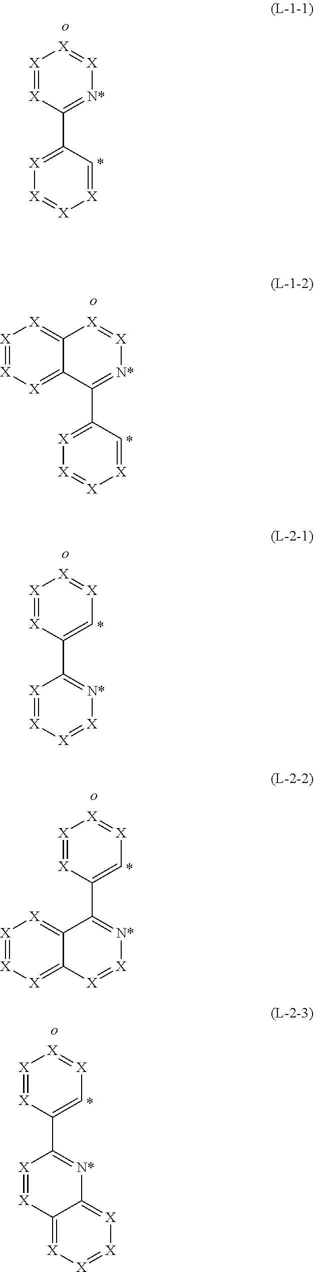

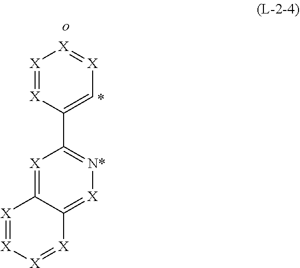

where the symbols used have the definitions given above and “o” in compounds of the formula (2) represents the position of the bond to the bridge V, in which case the corresponding X is C.

Particularly preferred sub-ligands (L-1) are the structures of the formulae (L-1-1a) and (L-1-2b), and particularly preferred sub-ligands (L-2) are the structures of the formulae (L-2-1a) to (L-2-4a)

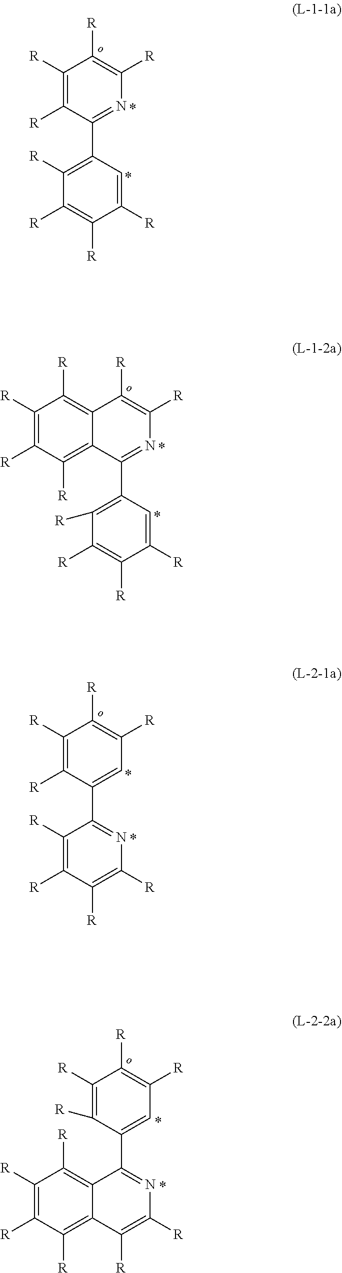

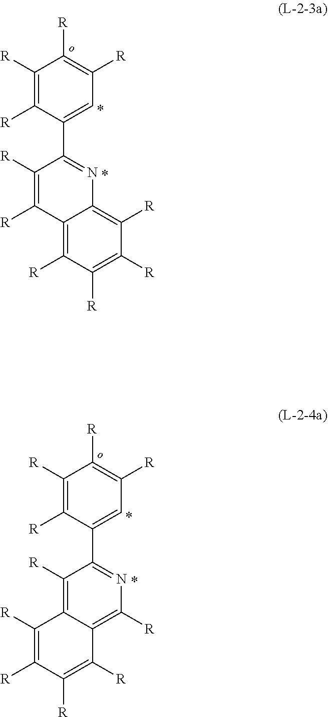

where the symbols used have the definitions given above and “o” in formula (2) represents the position of the bond to the bridge V, in which case the corresponding R radical is absent.

When two R radicals of which one is bonded to CyC and the other to CyD together form an aromatic ring system, this can result in bridged ligands or sub-ligands L¹ or L², in which case some of these bridged sub-ligands overall form a single larger heteroaryl group, for example benzo[h]quinoline, etc. The ring between the substituents on CyC and CyD is preferably formed by a group of one of the following formulae (3) to (12):

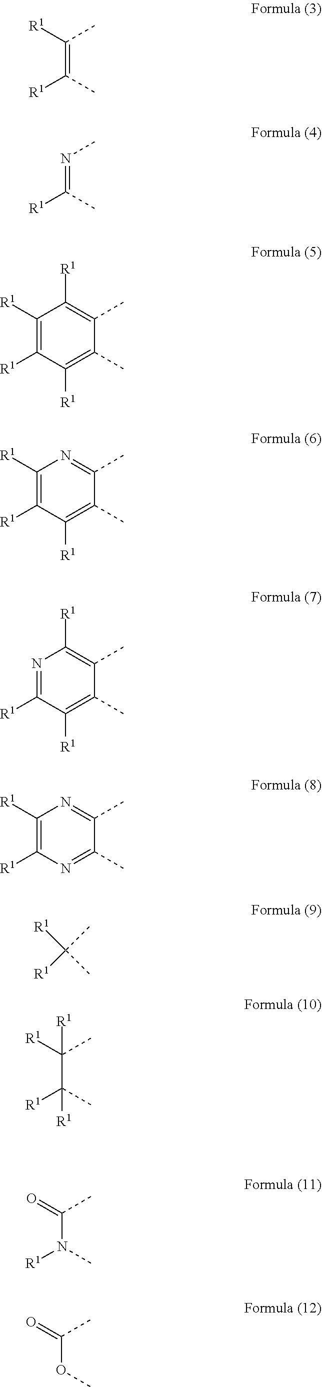

where R¹ has the definitions given above and the dotted bonds signify the bonds to CyC or CyD. It is possible here for the unsymmetric groups among those mentioned above to be incorporated in either of the two ways. For example, in the case of the group of the formula (12), the oxygen atom may bind to the CyC group and the carbonyl group to the CyD group, or the oxygen atom may bind to the CyD group and the carbonyl group to the CyC group.

At the same time, the group of the formula (9) is preferred particularly when this results in ring formation to give a six-membered ring, as shown below, for example, by the formulae (L-21) and (L-22).

Preferred ligands which arise through ring formation between two R radicals on the different cycles are the structures of the formulae (L-3) to (L-30) shown below:

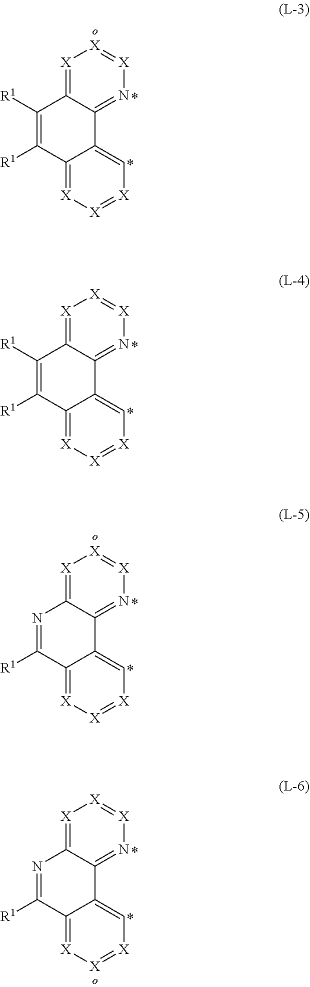

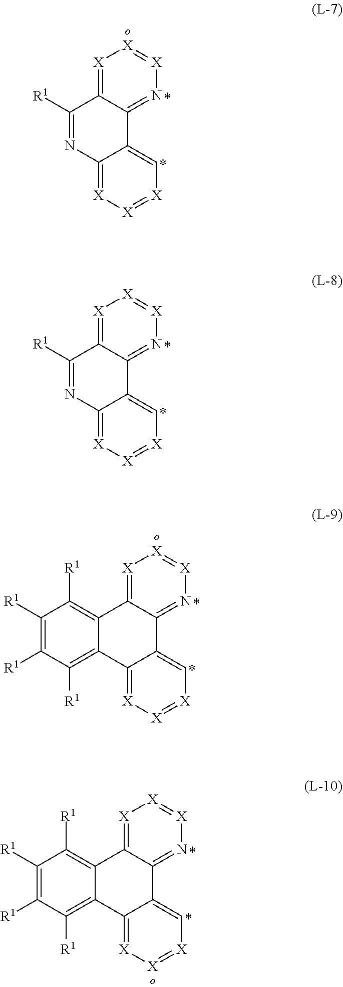

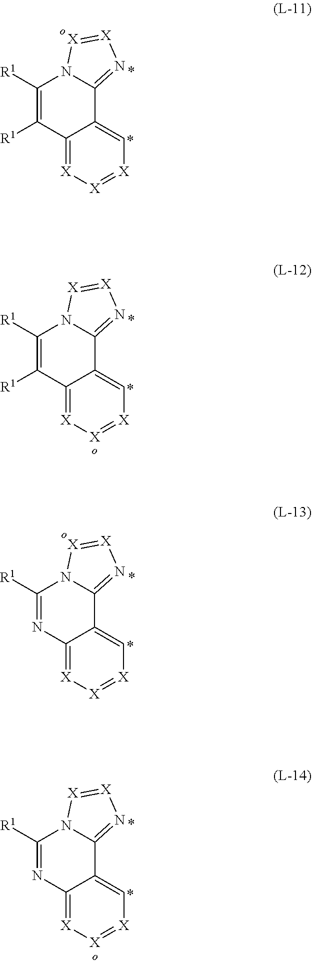

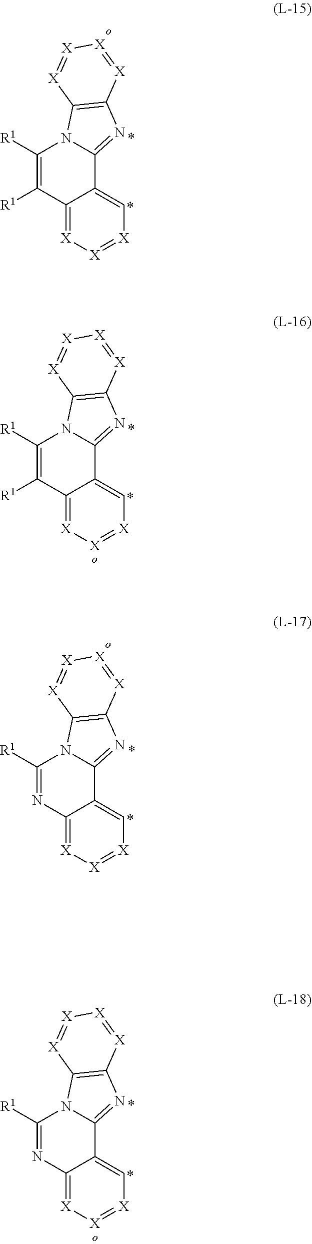

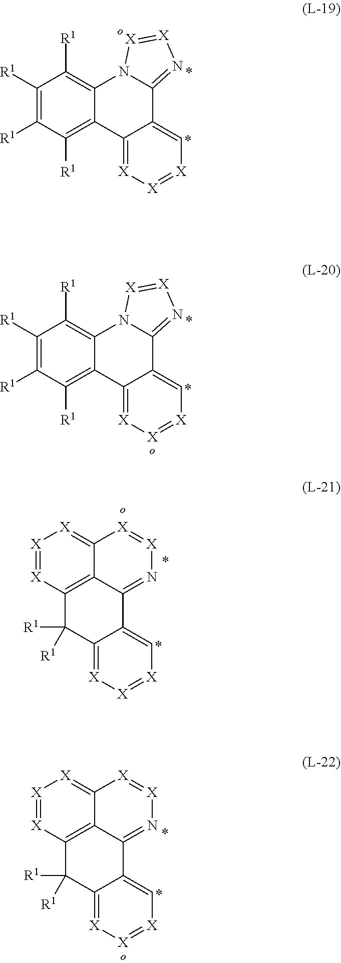

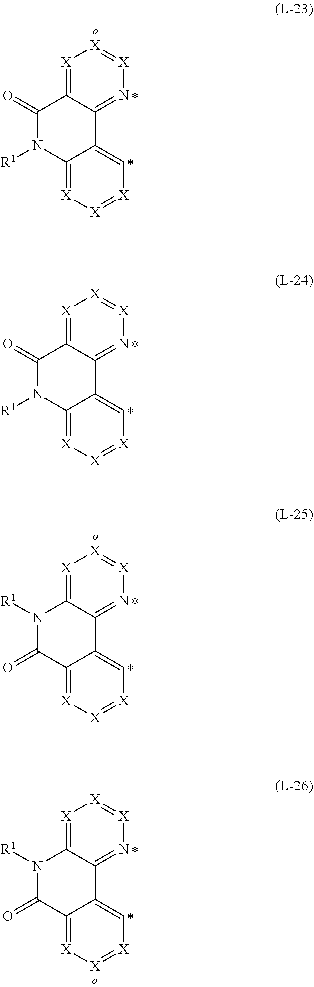

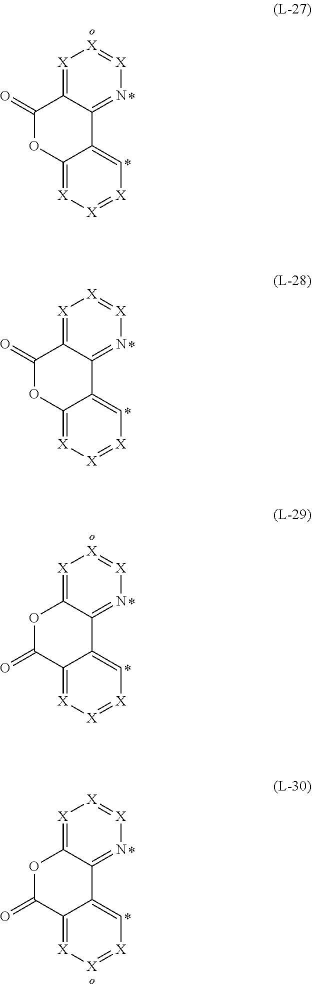

where the symbols used have the definitions given above and “o” in formula (2) indicates the position at which the sub-ligand is joined to the V group.

In a preferred embodiment of the ligands or sub-ligands of the formulae (L-3) to (L-30), a total of one symbol X is N and the other symbols X are CR, or all symbols X are CR.

In a further embodiment of the invention, it is preferable if, in the groups (CyC-1) to (CyC-20) or (CyD-1) to (CyD-18) or in the ligands or sub-ligands (L-3) to (L-30), one of the atoms X is N when an R group bonded as a substituent adjacent to this nitrogen atom is not hydrogen or deuterium. This applies analogously to the preferred structures (CyC-1a) to (CyC-20a) or (CyD-1a) to (CyD-18a) in which a substituent bonded adjacent to a non-coordinating nitrogen atom is preferably an R group which is not hydrogen or deuterium.

In this case, this substituent R is preferably a group selected from CF₃, OCF₃, alkyl groups having 1 to 10 carbon atoms, especially branched or cyclic alkyl groups having 3 to 10 carbon atoms, OR¹ where R¹ is an alkyl group having 1 to 10 carbon atoms, especially a branched or cyclic alkyl group having 3 to 10 carbon atoms, dialkylamino groups having 2 to 10 carbon atoms or aryl or heteroaryl groups having 5 to 10 aromatic ring atoms. These groups are sterically demanding groups. Further preferably, this R radical may also form a cycle with an adjacent R radical.

Further suitable bidentate ligands or sub-ligands are the ligands or sub-ligands of the following formulae (L-31) or (L-32):

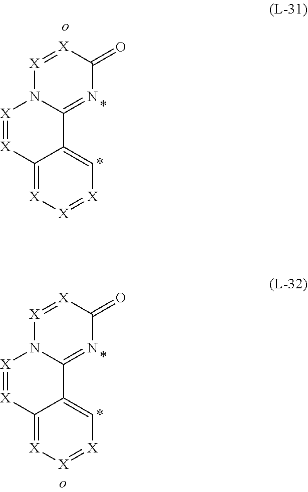

where R has the definitions given above, * represents the position of coordination to the iridium, “o” in formula (2) represents the position of linkage of the sub-ligand to V and the further symbols are as follows:
X is the same or different at each instance and is CR or N, with the proviso that not more than one X symbol per cycle is N.

When two R radicals bonded to adjacent carbon atoms in the ligands or sub-ligands (L-31) and (L-32) form an aromatic cycle with one another, this cycle together with the two adjacent carbon atoms is preferably a structure of the following formula (13):

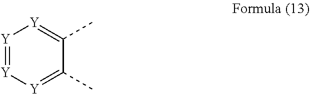

where the dotted bonds symbolize the linkage of this group within the ligand or sub-ligand and Y is the same or different at each instance and is CR¹ or N and preferably not more than one symbol Y is N.

In a preferred embodiment of the ligand or sub-ligand (L-31) or (L-32), not more than one such fused-on group is present. The ligands or sub-ligands are thus preferably of the following formulae (L-33) to (L-38):

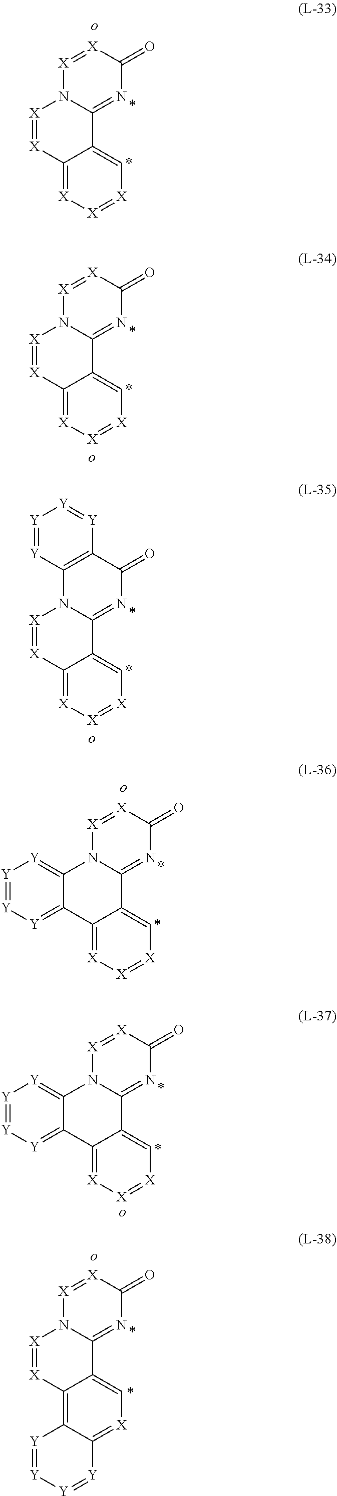

where X is the same or different at each instance and is CR or N, but the R radicals together do not form an aromatic or heteroaromatic ring system and the further symbols have the definitions given above.

In a preferred embodiment of the invention, in the ligand or sub-ligand of the formulae (L-31) to (L-38), a total of 0, 1 or 2 of the symbols X and, if present, Y are N. More preferably, a total of 0 or 1 of the symbols X and, if present, Y are N.

Preferred embodiments of the formulae (L-33) to (L-38) are the structures of the following formulae (L-33a) to (L-38f):

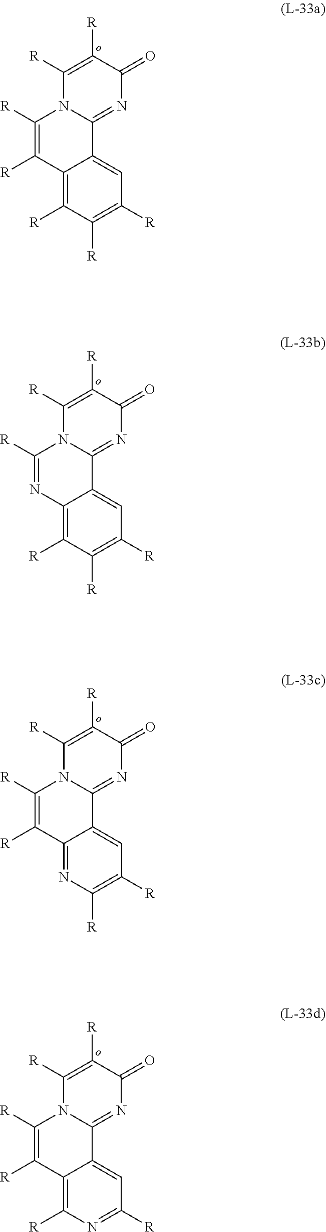

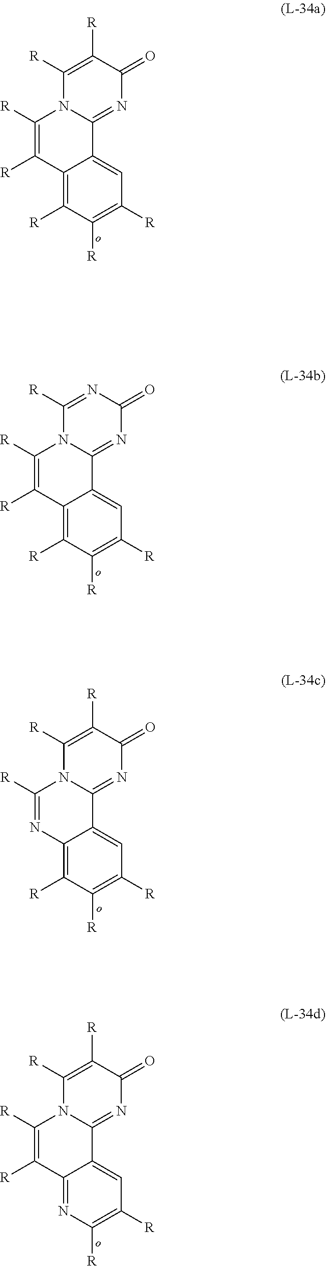

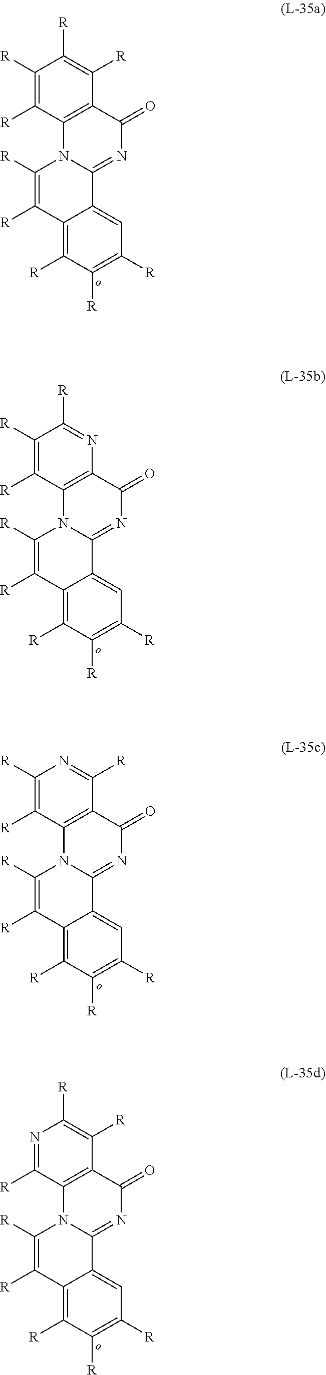

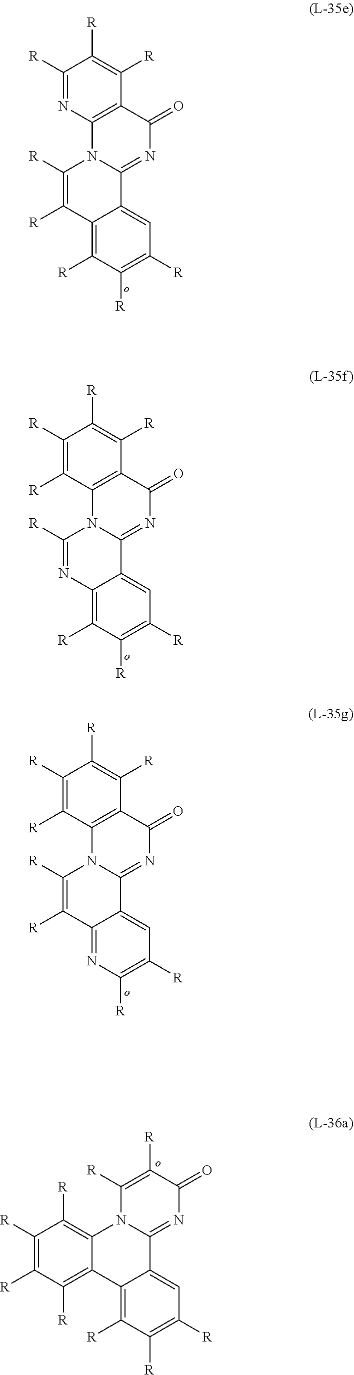

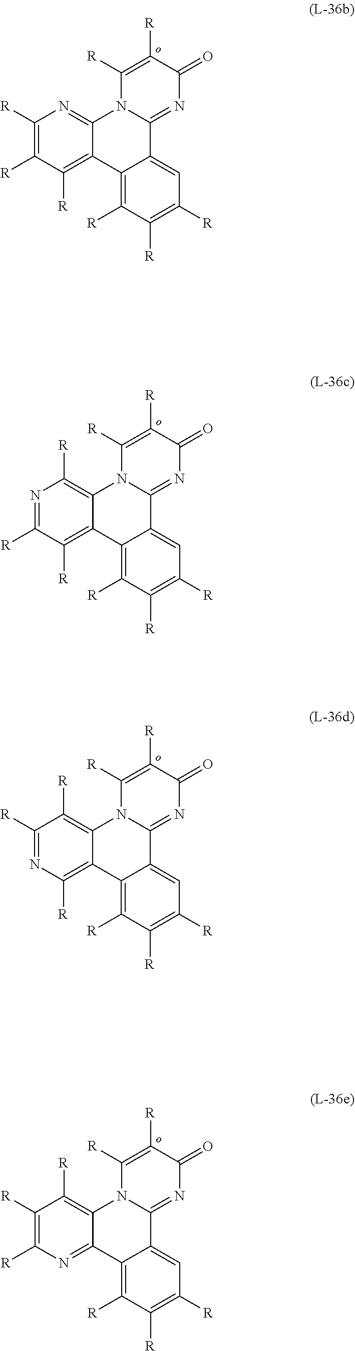

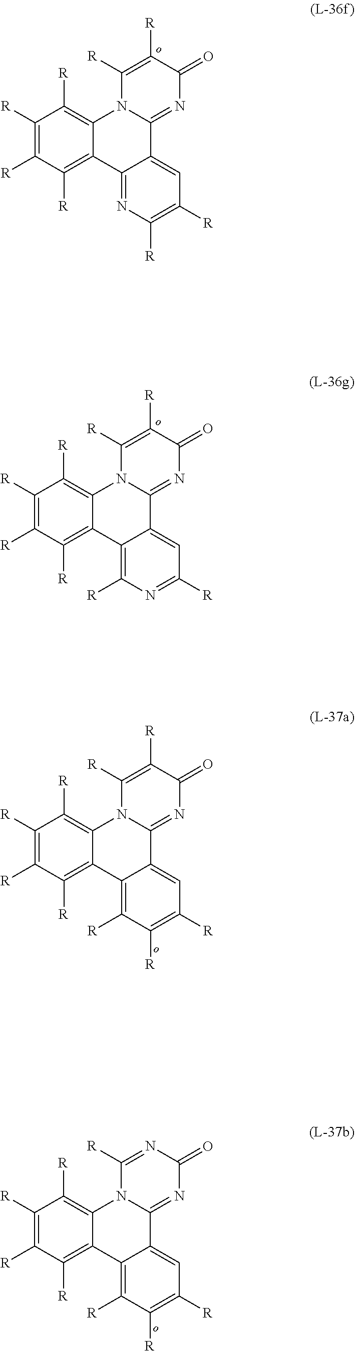

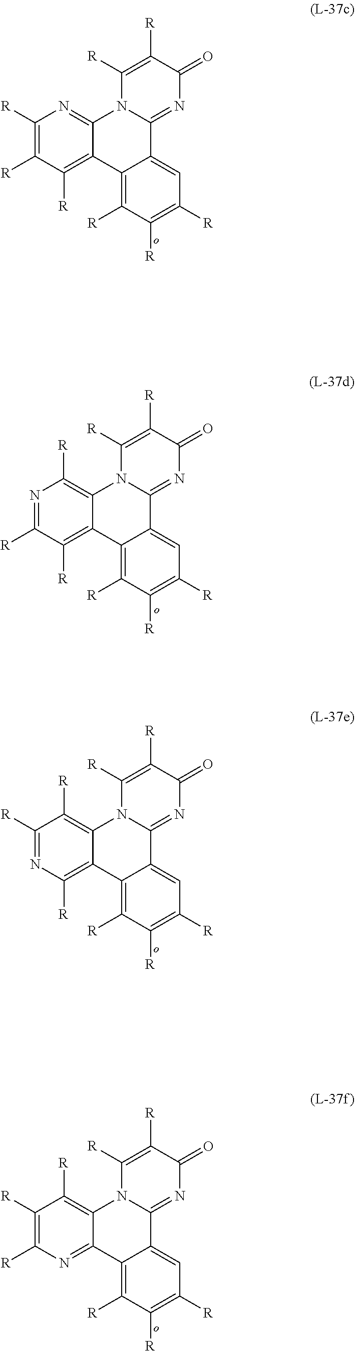

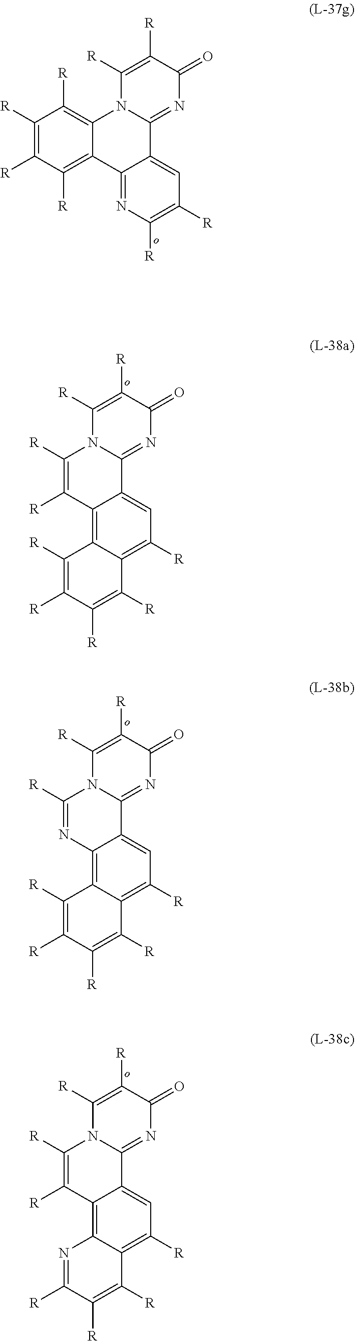

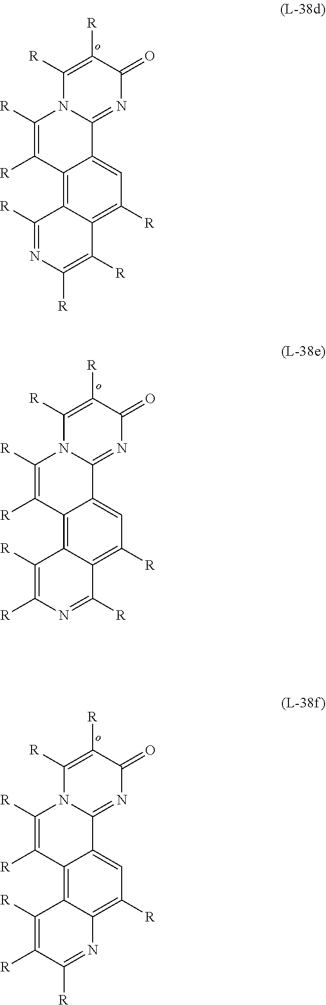

where the symbols used have the definitions given above and “o” indicates the position of the linkage to the bridge V, in which case the corresponding R group is absent.

In a preferred embodiment of the invention, the X group in the ortho position to the coordination to the metal is CR. In this radical, R bonded in the ortho position to the coordination to the metal is preferably selected from the group consisting of H, D, F and methyl.

In a further embodiment of the invention, it is preferable if one of the atoms X is N when a substituent bonded adjacent to this nitrogen atom is an R group which is not H or D. In this case, this substituent R is preferably a group selected from CF₃, OCF₃, alkyl groups having 1 to 10 carbon atoms, especially branched or cyclic alkyl groups having 3 to 10 carbon atoms, OR¹ where R¹ is an alkyl group having 1 to 10 carbon atoms, especially a branched or cyclic alkyl group having 3 to 10 carbon atoms, dialkylamino groups having 2 to 10 carbon atoms or aryl or heteroaryl groups having 5-5 to 10 aromatic ring atoms. These groups are sterically demanding groups.

Further preferably, this R radical may also form a cycle with an adjacent R radical.

In a preferred embodiment of the invention, L_{act} is a ligand or sub-ligand of the following formula (L-39) that coordinates to the iridium via the two D groups and which, when the complex is one of the formula (2), is bonded to V via the dotted bond, in which case the corresponding X is C:

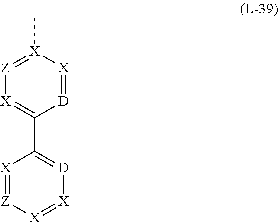

where:
D is C or N, with the proviso that one D is C and the other D is N;
X is the same or different at each instance and is CR or N;
Z is CR′, CR or N, with the proviso that exactly one Z is CR′ and the other Z is CR or N;
   where a maximum of one symbol X or Z per cycle is N;
R′ is a group of the following formula (14) or (15):

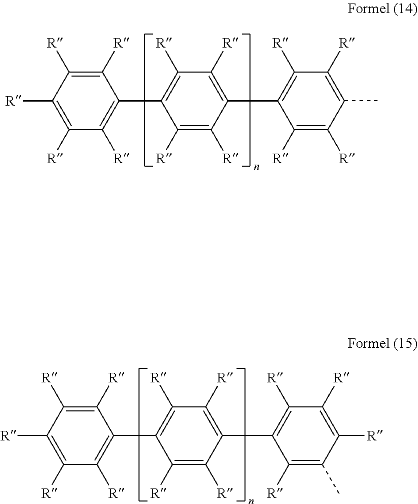

where the dotted bond indicates the attachment of the group;
R″ is the same or different at each instance and is H, D, F, CN, a straight chain alkyl group having 1 to 10 carbon atoms in which one or more hydrogen atoms may also be replaced by D or F, or a branched or cyclic alkyl group having 3 to 10 carbon atoms in which one or more hydrogen atoms may also be replaced by D or F, or an alkenyl group having 2 to 10 carbon atoms in which one or more hydrogen atoms may also be replaced by D or F; at the same time, two adjacent R″ radicals or two R″ radicals on adjacent phenyl groups together may also form a ring system; or two R″ on adjacent phenyl groups together are a group selected from C(R¹)₂, NR¹, O and S, such that the two phenyl rings together with the bridging group are a carbazole, dibenzofuran or dibenzothiophene, and the further R″ are as defined above;
n is 0, 1, 2, 3, 4 or 5.

In the case of ring formation by two substituents R″ on adjacent phenyl groups, the result may also be a fluorene or a phenanthrene or a triphenylene. It is likewise possible, as described above, for two R″ on adjacent phenyl groups together to be a group selected from NR¹, O and S, such that the two phenyl rings together with the bridging group are a carbazole, dibenzofuran or dibenzothiophene.

In a preferred embodiment of the invention, X is the same or different at each instance and is CR. Further preferably, one Z group is CR and the other Z group is CR′. More preferably, in the ligand or sub-ligand of the formula (L-39), the X groups are the same or different at each instance and are CR, and at the same time one Z group is CR and the other Z group is CR′. The ligand or sub-ligand L¹ preferably has a structure of one of the following formulae (L-39a) or (L-39b), where the linkage to the bridge V for polypodal structures of the formula (L-39) is via the position identified by “o” and no R radical is bonded at this position,

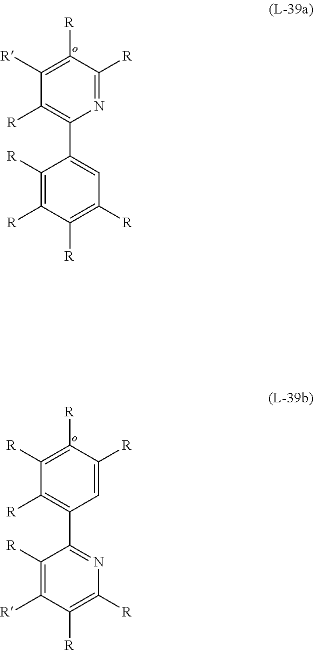

where the symbols used have the meanings given above.

More preferably, the sub-ligand L of the formula (L-39) has a structure of one of the following formulae (L-39a′) or (L-39b′), where the linkage to the bridge V for polypodal structures of the formula (L-39) is via the position identified by “o” and no R radical is bonded at this position,

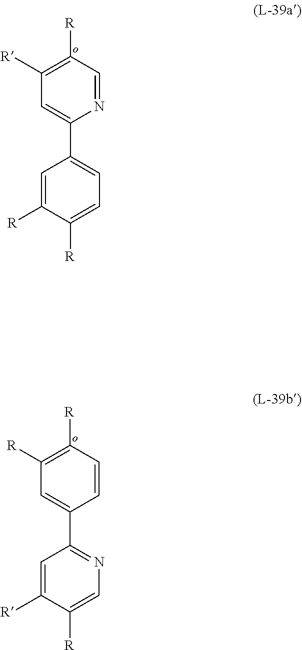

where the symbols used have the meanings given above.

The R radicals in the sub-ligand L_{act} of the formula (L-39) or formulae (L-39a), (L-39b), (L-39a′) and (L-39d′) are preferably selected from the group consisting of H, D, CN, OR¹, a straight-chain alkyl group having 1 to 6 carbon atoms, preferably having 1 to 3 carbon atoms, or a branched or cyclic alkyl group having 3 to 6 carbon atoms or an alkenyl group having 2 to 6 carbon atoms, preferably 2 to 4 carbon atoms, each of which may be substituted by one or more R¹ radicals, or a phenyl group which may be substituted by one or more nonaromatic R¹ radicals. It is also possible here for two or more adjacent R radicals together to form a ring system.

In this case, the substituent R bonded to the coordinating atom in the ortho position is preferably selected from the group consisting of H, D, F and methyl, more preferably H, D and methyl and especially H and D.

In addition, it is preferable when all substituents R that are in the ortho position to R′ are H or D.

When the R radicals in the sub-ligand L_{act} of the formula (L-39) together form a ring system, it is preferably an aliphatic, heteroaliphatic or heteroaromatic ring system. In addition, preference is given to ring formation between two R radicals on the two rings of the sub-ligand L_{act}, preferably forming a phenanthridine, or a phenanthridine which may contain still further nitrogen atoms. When R radicals together form a heteroaromatic ring system, this preferably forms a structure selected from the group consisting of quinoline, isoquinoline, dibenzofuran, dibenzothiophene and carbazole, each of which may be substituted by one or more R¹ radicals, and where individual carbon atoms in the dibenzofuran, dibenzothiophene and carbazole may also be replaced by N. Particular preference is given to quinoline, isoquinoline, dibenzofuran and azadibenzofuran. It is possible here for the fused-on structures to be bonded in any possible position. Preferred sub-ligands L₁ with fused-on benzo groups are the structures of the formulae (L-39c) to (L-39j) listed below, where the linkage to the bridge V for polypodal structures of the formula (L-39) is via the position identified by a dotted bond:

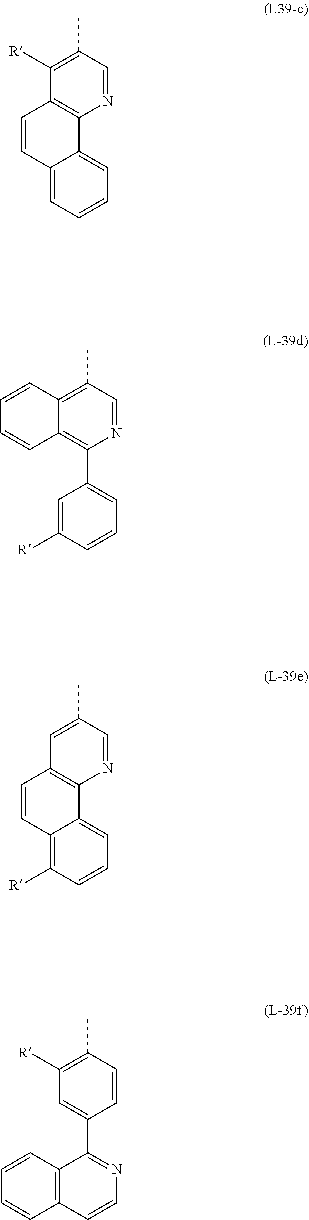

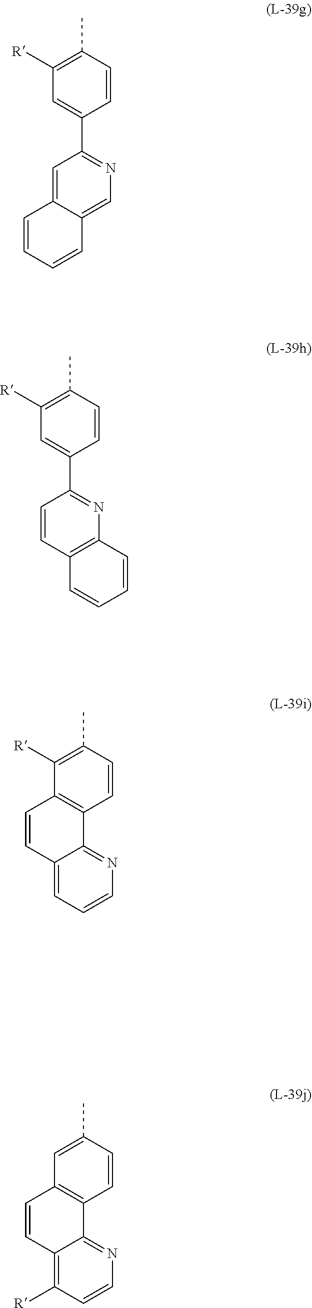

where the ligands may each also be substituted by one or more further R radicals and the fused-on structure may be substituted by one or more R¹ radicals. Preferably, there are no further R or R¹ radicals present.

Preferred sub-ligands L_{act} of the formula (L-39) with fused-on benzofuran or azabenzofuran groups are the structures of the formulae (L-39k) to (L-39z) listed below, where the linkage to the bridge V for polypodal structures of the formula (L-39) is via the position identified by a dotted bond and no R radical is bonded to this position:

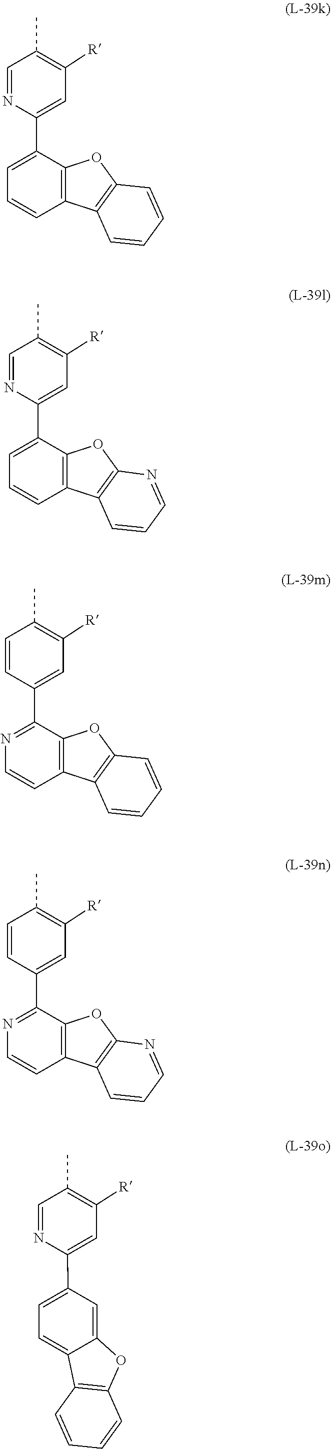

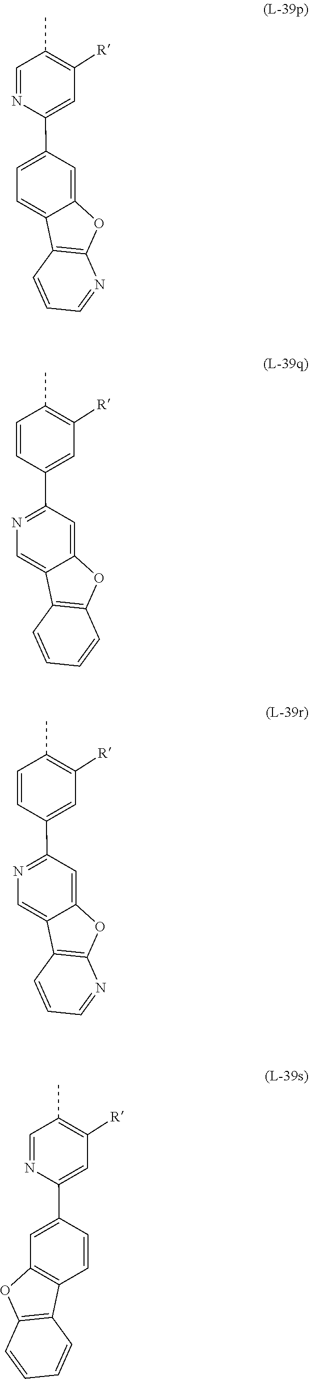

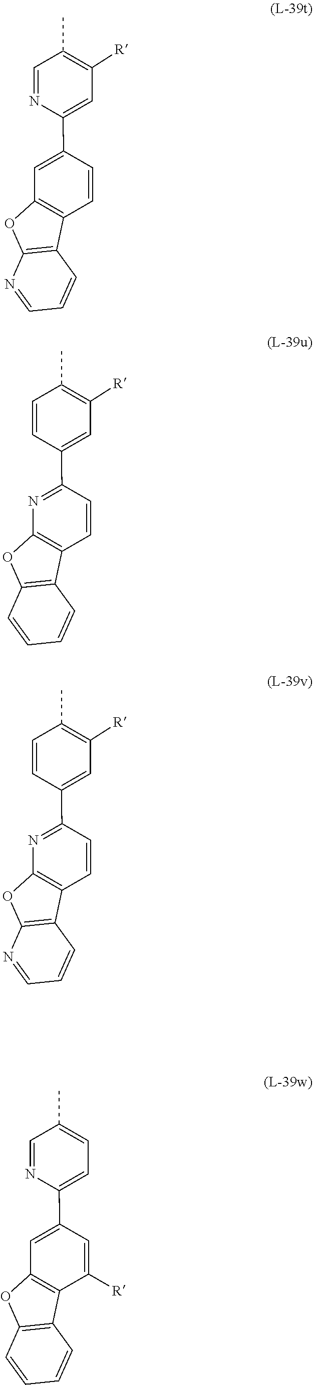

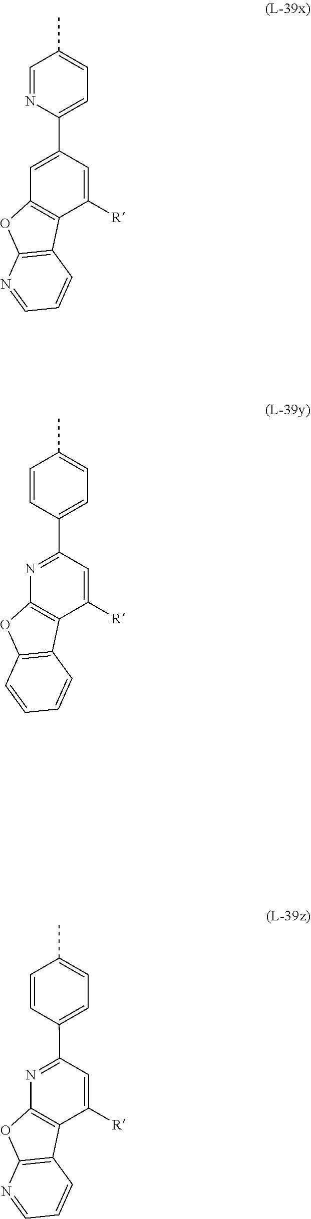

where the ligands may each also be substituted by one or more further R radicals and the fused-on structure may be substituted by one or more R¹ radicals. Preferably, there are no further R or R¹ radicals present. It is likewise possible for O in these structures to be replaced by S or NR¹.

As described above, R′ is a group of the formula (14) or (15). The two groups here differ merely in that the group of the formula (14) is bonded to the ligand or sub-ligand L¹ in the para position and the group of the formula (15) in the meta position.

In a preferred embodiment of the invention, n=0, 1 or 2, preferably 0 or 1 and most preferably 0.

In a further preferred embodiment of the invention, both substituents R″ bonded in the ortho positions to the carbon atom by which the group of the formula (14) or (15) is bonded to the phenylpyridine ligands are the same or different and are H or D.

Preferred embodiments of the structure of the formula (14) are the structures of the formulae (14a) to (14h), and preferred embodiments of the structure of the formula (15) are the structures of the formulae (15a) to (15h):

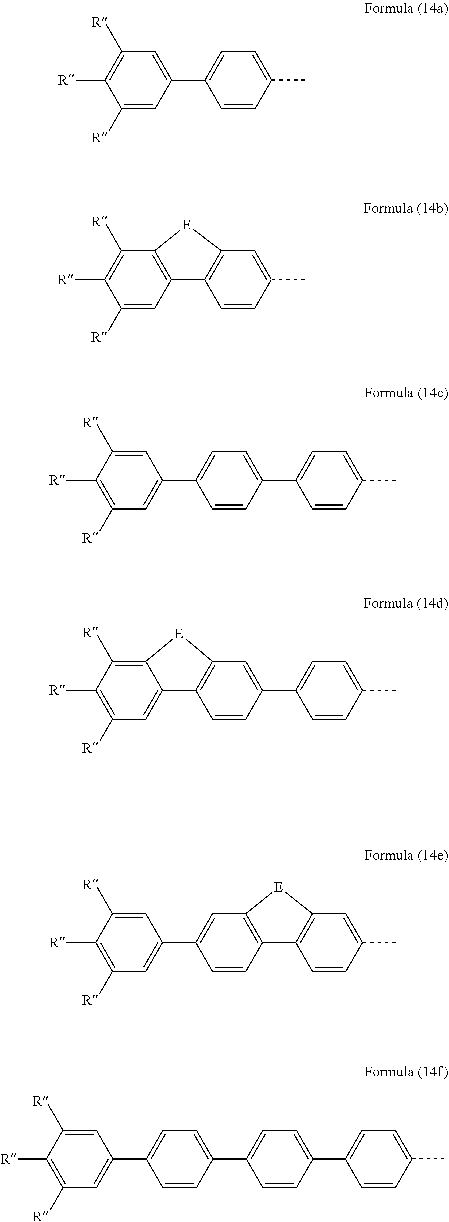

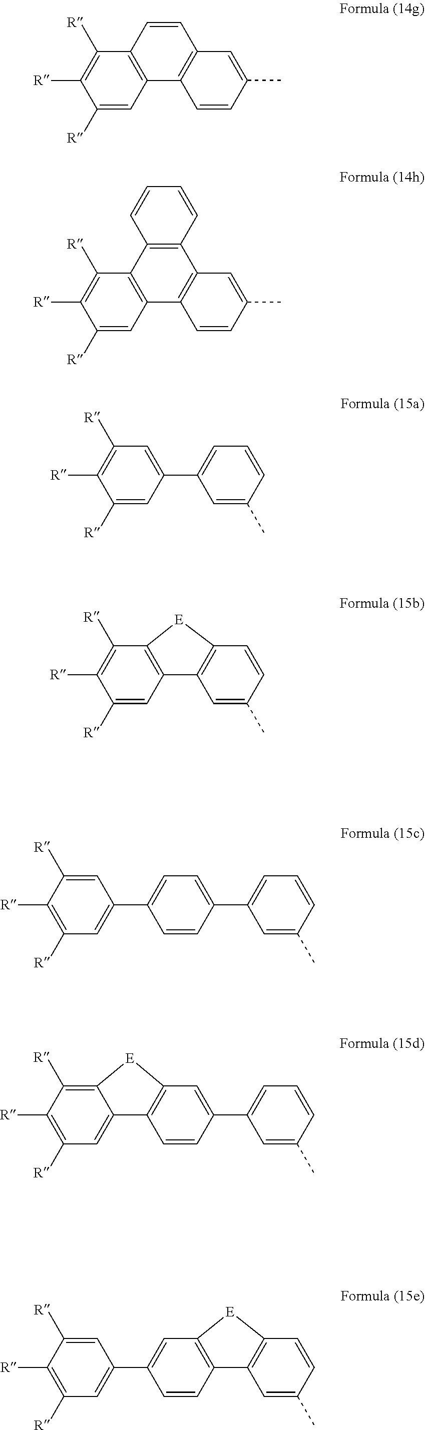

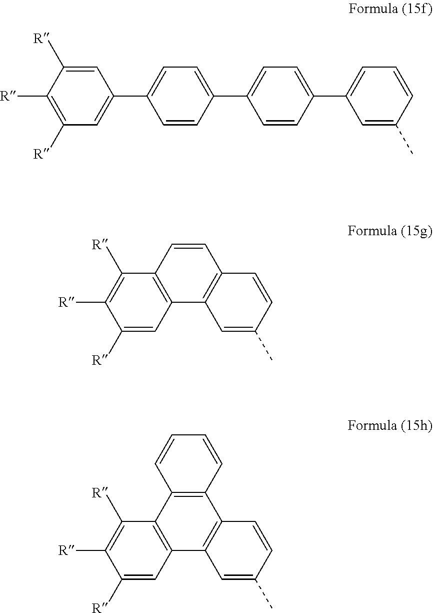

where E is C(R¹)₂, NR¹, O or S and the further symbols used have the definitions given above. R¹ here, when E=C(R¹)₂, is preferably the same or different at each instance and is an alkyl group having 1 to 6 carbon atoms, preferably having 1 to 4 carbon atoms, more preferably methyl. In addition, when E=NR¹, R¹ is preferably an aromatic or heteroaromatic ring system having 5 to 30 aromatic ring atoms, preferably having 6 to 24 aromatic ring atoms, more preferably having 6 to 12 aromatic ring atoms, especially phenyl.

Preferred substituents R″ on the groups of the formula (14) or (15) or the preferred embodiments are selected from the group consisting of H, D, CN and an alkyl group having 1 to 4 carbon atoms, more preferably H, D or methyl.

The complexes of the formula (2) are complexes having a tripodal hexadentate ligand, where the three sub-ligands L_{act} and L are covalently bonded to one another by a bridging unit V. These have the advantage over complexes of the formula (1) that they have a higher stability through the covalent linkage of the sub-ligands L_{act} and L.

In a preferred embodiment of the invention, the bridging unit V is a group of the following formula (16), where the dotted bonds represent the position of the linkage of the sub-ligands L_{act} and L:

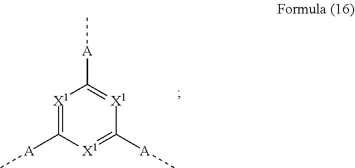

where:
X¹ is the same or different at each instance and is CR or N;
X² is the same or different at each instance and is CR or N;
A is the same or different at each instance and is CR₂—CR₂, CR₂—O, CR₂—NR, C(═O)—O, C(═O)—NR or a group of the following formula (17):

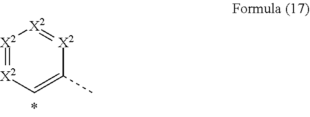

where the dotted bond in each case represents the position of the bond of the bidentate sub-ligands L_{act} or L to this structure, * represents the position of the linkage of the unit of the formula (17) to the central trivalent aryl or heteroaryl group.

Preferred substituents in the group of the formula (17) when X²═CR are selected from the above-described substituents R.

In a preferred embodiment of the invention, A is the same or different at each instance and is CR₂—CR₂ or a group of the formula (17). Preference is given here to the following embodiments:
all three A groups are the same group of the formula (17);
two A groups are the same group of the formula (17), and the third A group is CR₂—CR₂:
one A group is a group of the formula (17), and the two other A groups are the same CR₂—CR₂ group; or
all three A groups are the same CR₂—CR₂ group.

What is meant here by “the same group of the formula (17)” is that these groups all have the same base skeleton and the same substitution. Moreover, what is meant by “the same CR₂—CR₂ group” is that these groups all have the same substitution.

When A is CR₂—CR₂, R is preferably the same or different at each instance and is H or D, more preferably H.

The group of the formula (17) is an aromatic or heteroaromatic six-membered ring. In a preferred embodiment of the invention, the group of the formula (17) contains not more than one heteroatom in the aryl or heteroaryl group. This does not mean that any substituents bonded to this group cannot also contain heteroatoms. In addition, this definition does not mean that formation of rings by substituents does not give rise to fused aromatic or heteroaromatic structures, for example naphthalene, benzimidazole, etc. The group of the formula (17) is preferably selected from benzene, pyridine, pyrimidine, pyrazine and pyridazine.

Preferred embodiments of the group of the formula (17) are the structures of the following formulae (18) to (25):

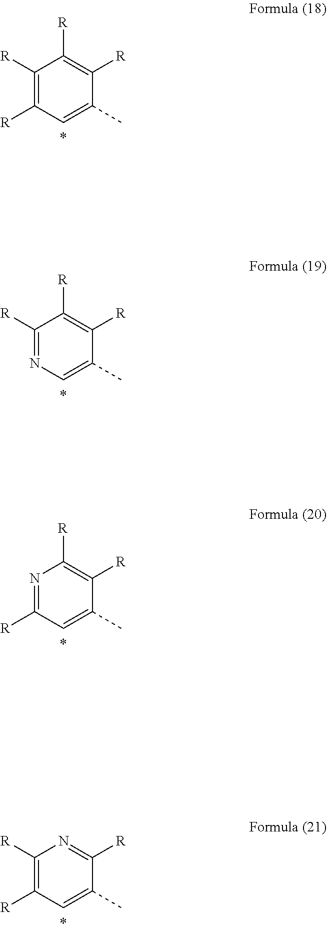

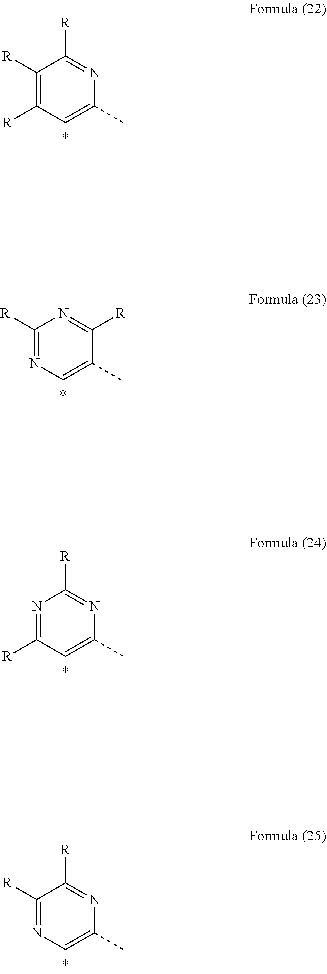

where the symbols used have the meanings given above.

Particular preference is given to the optionally substituted six-membered aromatic rings and six-membered heteroaromatic rings of the formulae (18) to (22). Very particular preference is given to ortho-phenylene, i.e. a group of the formula (18).

At the same time, as also detailed above in the description of the substituent, it is also possible for adjacent substituents together to form a ring system, such that fused structures, including fused aryl and heteroaryl groups, for example naphthalene, quinoline, benzimidazole, carbazole, dibenzofuran or dibenzothiophene, can form.

Stated hereinafter are preferred embodiments of the bridgehead V, i.e. the structure of the formula (16). Preferred embodiments of the group of the formula (16) are the structures of the following formulae (26) to (29):

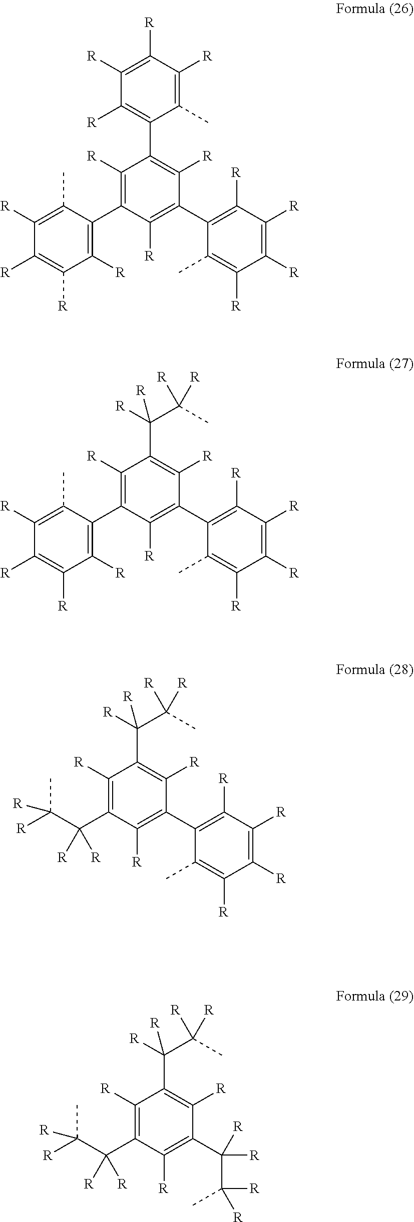

where the symbols used have the meanings given above.

More preferably, all substituents R in the central ring of the formulae (26) to (29) are H, and so the structures are preferably selected from the formulae (26a) to (29a)

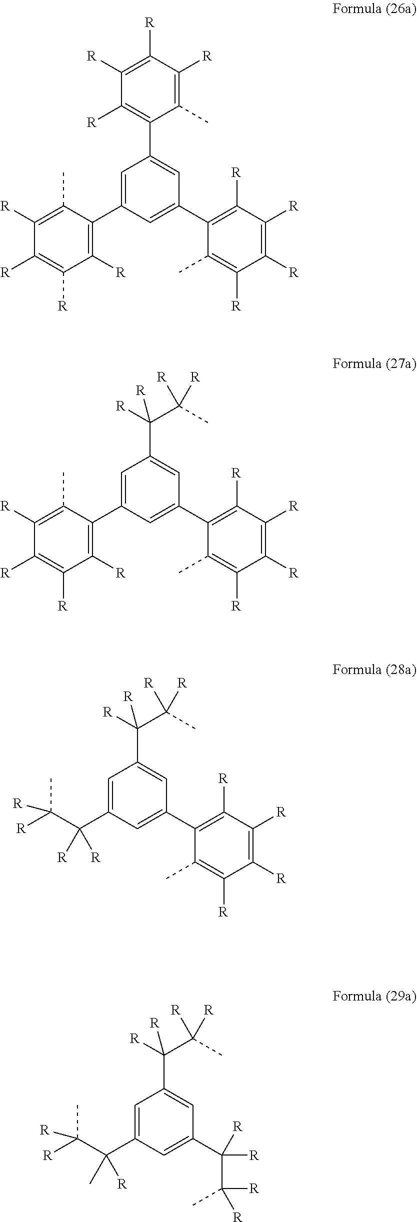

where the symbols used have the meanings given above.

More preferably, the groups of the formulae (26) to (29) are selected from the structures of the following formulae (26b) to (29b):

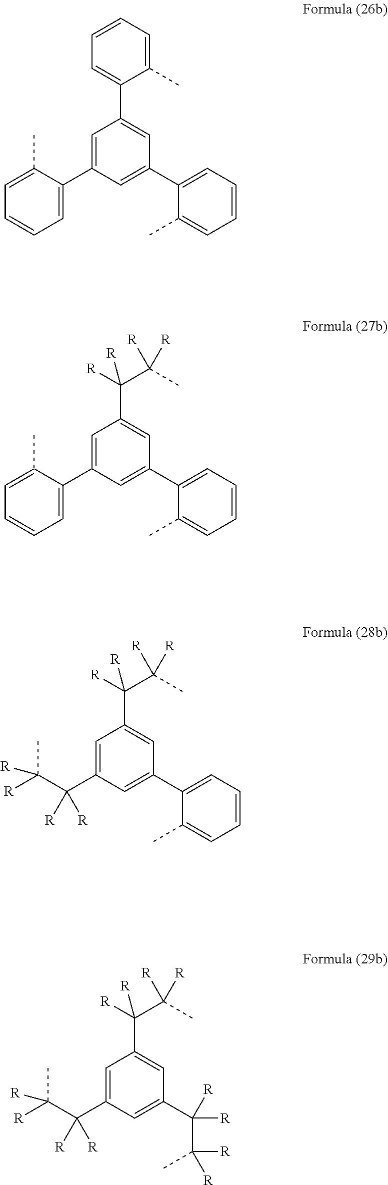

where R is the same or different at each instance and is H or D, preferably H.

Further examples of suitable bridgeheads V are the structures depicted below:

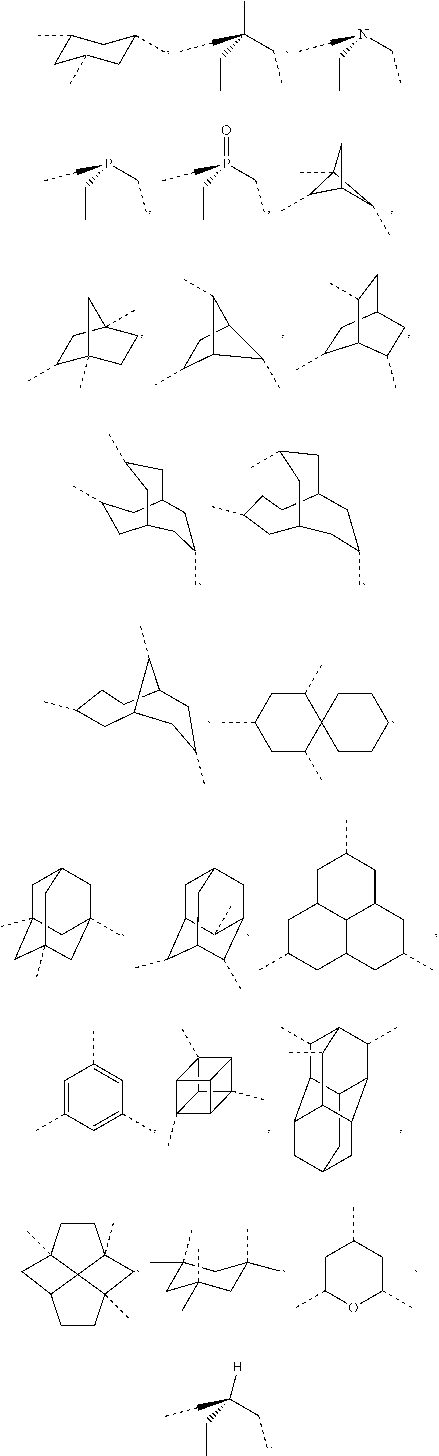

There follows a description of preferred substituents as may be present on the above-described sub-ligands L_{act} and/or L, but also on the bivalent arylene or heteroarylene group in the structure of the formula (16), i.e. in the structure of the formula (17).

In a further embodiment of the invention, the metal complex of the invention contains two R substituents or two R¹ substituents which are bonded to adjacent carbon atoms and together form an aliphatic ring according to one of the formulae described hereinafter. In this case, the two R substituents which form this aliphatic ring may be present on the bridge of the formula (16) and/or on one or more of the bidentate sub-ligands. The aliphatic ring which is formed by the ring formation by two R substituents together or by two R¹ substituents together is preferably described by one of the following formulae (30) to (36):

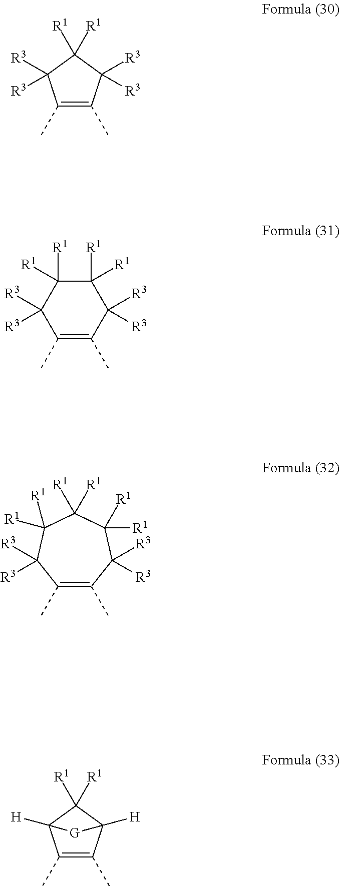

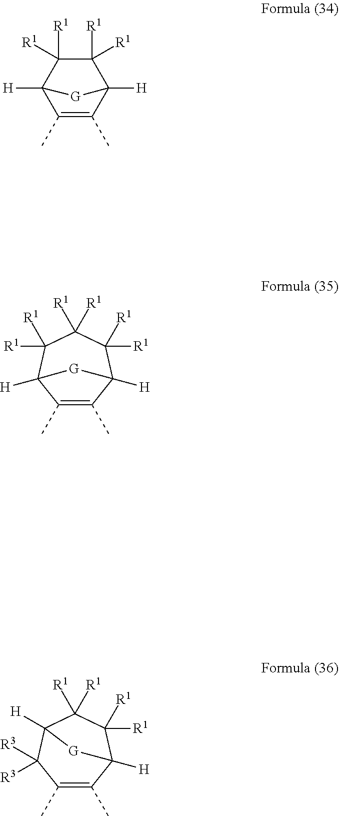

where R¹ and R² have the definitions given above, the dotted bonds signify the attachment of the two carbon atoms in the ligand, and in addition:
G is an alkylene group which has 1, 2 or 3 carbon atoms and may be substituted by one or more R² radicals, —CR²═CR²— or an ortho-bonded arylene or heteroarylene group which has 5 or 6 aromatic ring atoms and may be substituted by one or more R² radicals;
R³ is the same or different at each instance and is H, F, OR², a straight-chain alkyl group having 1 to 10 carbon atoms, a branched or cyclic alkyl group having 3 to 10 carbon atoms, where the alkyl group in each case may be substituted by one or more R² radicals, where one or more nonadjacent CH₂ groups may be replaced by R²C═CR², C≡C, Si(R²)₂, C═O, NR², O, S or CONR², or an aryl or heteroaryl group which has 5 or 6 aromatic ring atoms and may be substituted in each case by one or more R² radicals; at the same time, two R³ radicals which are bonded to the same carbon atom may together form an aliphatic ring system and thus form a spiro system; in addition, R³ with an adjacent R or R¹ radical may form an aliphatic ring system.

In the above-depicted structures of the formulae (30) to (36) and the further embodiments of these structures specified as preferred, a double bond is depicted in a formal sense between the two carbon atoms. This is a simplification of the chemical structure when these two carbon atoms are incorporated into an aromatic or heteroaromatic system and hence the bond between these two carbon atoms is formally between the bonding level of a single bond and that of a double bond.

Preferred embodiments of the groups of the formulae (30) to (36) can be found in patent applications WO 2014/023377, WO 2015/104045 and WO 2015/117718.

When R radicals are bonded within the bidentate ligands or sub-ligands L_{act} or L or within the bivalent arylene or heteroarylene groups of the formula (17) bonded within the formula (16) or the preferred embodiments, these R radicals are the same or different at each instance and are preferably selected from the group consisting of H, D, F, Br, I, N(R¹)₂, CN, Si(R¹)₃, B(OR¹)₂, C(═O)R¹, a straight-chain alkyl group having 1 to 10 carbon atoms or an alkenyl group having 2 to 10 carbon atoms or a branched or cyclic alkyl group having 3 to 10 carbon atoms, where the alkyl or alkenyl group may be substituted in each case by one or more R¹ radicals, or a phenyl group which may be substituted by one or more nonaromatic R¹ radicals, or a heteroaryl group which has 5 or 6 aromatic ring atoms and may be substituted by one or more nonaromatic R¹ radicals; at the same time, two adjacent R radicals together or R together with R¹ may also form a mono- or polycyclic, aliphatic or aromatic ring system. More preferably, these R radicals are the same or different at each instance and are selected from the group consisting of H, D, F, N(R¹)₂, a straight-chain alkyl group having 1 to 6 carbon atoms or a branched or cyclic alkyl group having 3 to 10 carbon atoms, where one or more hydrogen atoms may be replaced by D or F, or a phenyl group which may be substituted by one or more nonaromatic R¹ radicals, or a heteroaryl group which has 6 aromatic ring atoms and may be substituted by one or more nonaromatic R¹ radicals; at the same time, two adjacent R radicals together or R together with R¹ may also form a mono- or polycyclic, aliphatic or aromatic ring system.

Preferred R¹ radicals bonded to R are the same or different at each instance and are H, D, F, N(R²)₂, CN, a straight-chain alkyl group having 1 to 10 carbon atoms or an alkenyl group having 2 to 10 carbon atoms or a branched or cyclic alkyl group having 3 to 10 carbon atoms, where the alkyl group may be substituted in each case by one or more R² radicals, or a phenyl group which may be substituted by one or more R² radicals, or a heteroaryl group which has 5 or 6 aromatic ring atoms and may be substituted by one or more R² radicals; at the same time, two or more adjacent R¹ radicals together may form a mono- or polycyclic aliphatic ring system. Particularly preferred R¹ radicals bonded to R are the same or different at each instance and are H, F, CN, a straight-chain alkyl group having 1 to 5 carbon atoms or a branched or cyclic alkyl group having 3 to 5 carbon atoms, each of which may be substituted by one or more R² radicals, or a phenyl group which may be substituted by one or more R² radicals, or a heteroaryl group which has 5 or 6 aromatic ring atoms and may be substituted by one or more R² radicals; at the same time, two or more adjacent R¹ radicals together may form a mono- or polycyclic aliphatic ring system.

Preferred R² radicals are the same or different at each instance and are H, F or an aliphatic hydrocarbyl radical having 1 to 5 carbon atoms or an aromatic hydrocarbyl radical having 6 to 12 carbon atoms; at the same time, two or more R² substituents together may also form a mono- or polycyclic aliphatic ring system.

The abovementioned preferred embodiments are combinable with one another as desired within the limits of claim 1. In a particularly preferred embodiment of the invention, the abovementioned preferred embodiments apply simultaneously.

The iridium complexes of the invention are chiral structures. Both the tripodal complexes and the heteroleptic complexes of bidentate sub-ligands of the IrL₂L′ or IrLL′L″ type have C₁ symmetry. If the tripodal ligand of the complexes is additionally also chiral or bears three different sub-ligands (analogously in the case of the heteroleptic complexes with three different sub-ligands, i.e. of the IrLL′L″ type), the formation of diastereomers and multiple pairs of enantiomers is possible. In that case, the complexes of the invention include both the mixtures of the different diastereomers or the corresponding racemates and the individual isolated diastereomers or enantiomers.

The stereochemical relationships are set out hereinafter using the example of a tripodal complex, but are also applicable in an entirely analogous manner to the heteroleptic complexes of bidentate sub-ligands of the IrL₂L′ or IrLL′L″ type. For the sake of clarity, the complex is not a complex of the invention; instead, the situation is elucidated using a simple unsubstituted polypodal complex, but is equally applicable to the complexes of the invention. If tripodal ligands having two identical sub-ligands are used in the ortho-metallation, what is obtained is typically a racemic mixture of the C₁-symmetric complexes, i.e. of the Δ and Λ enantiomers. These may be separated by standard methods (chromatography on chiral materials/columns or optical resolution by crystallization).

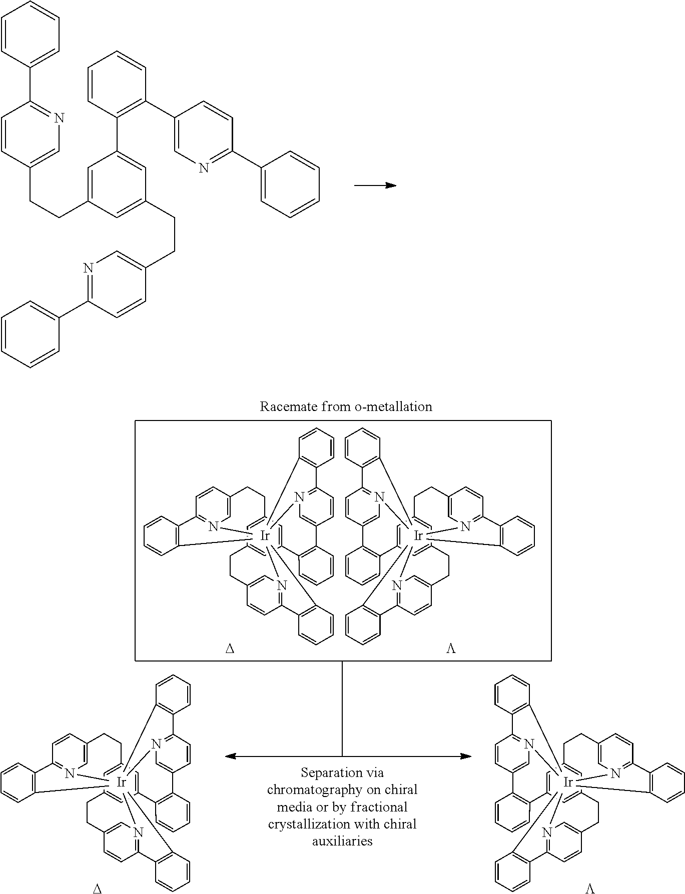

Optical resolution via fractional crystallization of diastereomeric salt pairs can be effected by customary methods. One option for this purpose is to oxidize the uncharged Ir(III) complexes (for example with peroxides or H₂O₂ or by electrochemical means), add the salt of an enantiomerically pure, monoanionic base (chiral base) to the cationic Ir(IV) complexes thus produced, separate the diastereomeric salts thus produced by fractional crystallization, and then reduce them with the aid of a reducing agent (e.g. zinc, hydrazine hydrate, ascorbic acid, etc.) to give the enantiomerically pure uncharged complex, as shown schematically below:

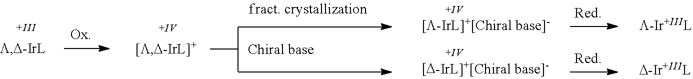

In addition, an enantiomerically pure or enantiomerically enriching synthesis is possible by complexation in a chiral medium (e.g. R- or S-1,1-binaphthol).

If ligands having three different sub-ligands are used in the complexation, what is typically obtained is a diastereomer mixture of the complexes which can be separated by standard methods (chromatography, crystallization, etc.).

Enantiomerically pure C₁-symmetric complexes can also be synthesized selectively, as shown in the scheme which follows. For this purpose, an enantiomerically pure C₁-symmetric ligand is prepared and complexed, the diastereomer mixture obtained is separated and then the chiral group is detached.

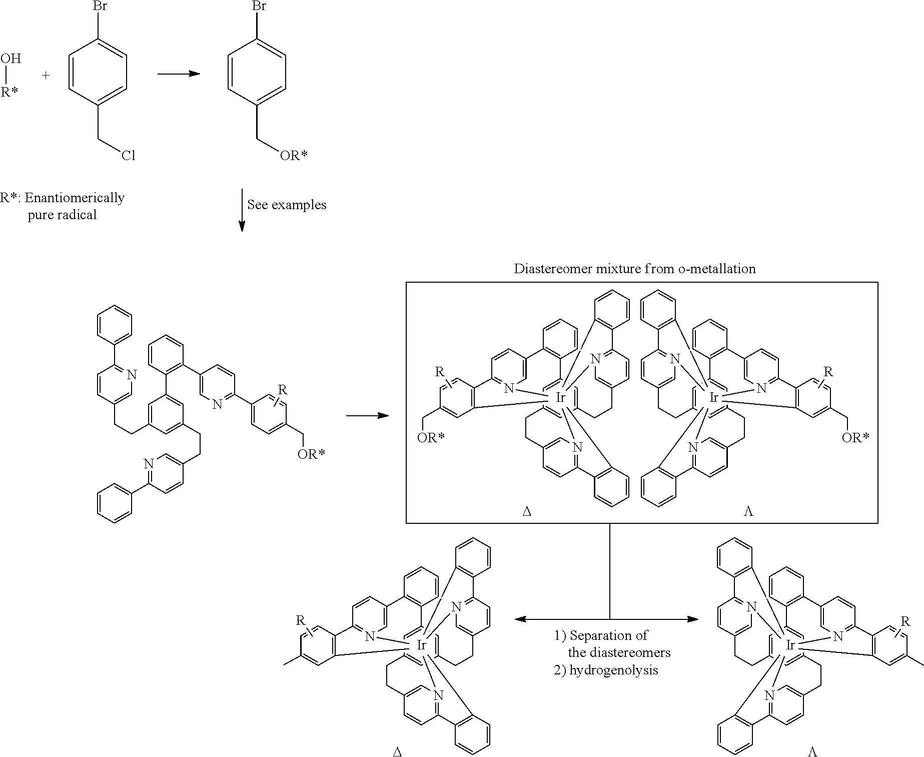

The tripodal complexes of the invention are preparable in principle by various processes. In general, for this purpose, an iridium salt is reacted with the corresponding free ligand.

Therefore, the present invention further provides a process for preparing the compounds of the invention by reacting the appropriate free ligands with iridium alkoxides of the formula (37), with iridium ketoketonates of the formula (38), with iridium halides of the formula (39) or with iridium carboxylates of the formula (40)

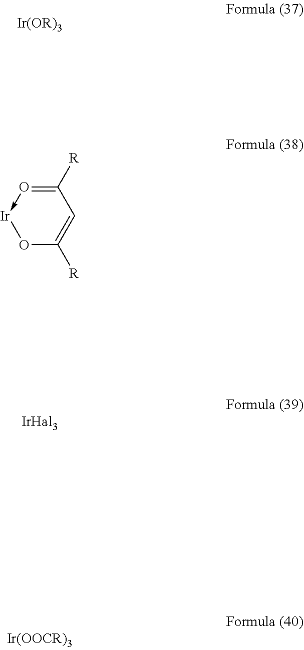

where R has the definitions given above, Hal=F, Cl, Br or I and the iridium reactants may also be in the form of the corresponding hydrate. R here is preferably an alkyl group having 1 to 4 carbon atoms.

It is likewise possible to use iridium compounds bearing both alkoxide and/or halide and/or hydroxyl and ketoketonate radicals. These compounds may also be charged. Corresponding iridium compounds of particular suitability as reactants are disclosed in WO 2004/085449. Particularly suitable are [IrCl₂(acac)₂]⁻, for example Na[IrCl₂(acac)₂], metal complexes with acetylacetonate derivatives as ligand, for example Ir(acac)₃ or tris(2,2,6,6-tetramethylheptane-3,5-dionato)iridium, and IrCl₃.xH₂O where x is typically a number from 2 to 4.

The synthesis of the complexes is preferably conducted as described in WO 2002/060910 and in WO 2004/085449. In this case, the synthesis can, for example, also be activated by thermal or photochemical means and/or by microwave radiation. In addition, the synthesis can also be conducted in an autoclave at elevated pressure and/or elevated temperature.

The reactions can be conducted without addition of solvents or melting aids in a melt of the corresponding ligands to be o-metallated. It is optionally also possible to add solvents or melting aids. Suitable solvents are protic or aprotic solvents such as aliphatic and/or aromatic alcohols (methanol, ethanol, isopropanol, t-butanol, etc.), oligo- and polyalcohols (ethylene glycol, propane-1,2-diol, glycerol, etc.), alcohol ethers (ethoxyethanol, diethylene glycol, triethylene glycol, polyethylene glycol, etc.), ethers (di- and triethylene glycol dimethyl ether, diphenyl ether, etc.), aromatic, heteroaromatic and/or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO) or sulfones (dimethyl sulfone, sulfolane, etc.). Suitable melting aids are compounds that are in solid form at room temperature but melt when the reaction mixture is heated and dissolve the reactants, so as to form a homogeneous melt. Particularly suitable are biphenyl, m-terphenyl, triphenyls, R- or S-binaphthol or else the corresponding racemate, 1,2-, 1,3- or 1,4-bisphenoxybenzene, triphenylphosphine oxide, 18-crown-6, phenol, 1-naphthol, hydroquinone, etc. Particular preference is given here to the use of hydroquinone.

The heteroleptic complexes of bidentate ligands of the IrL₂L′ type can be prepared according to the following scheme:

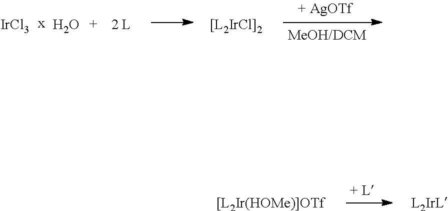

Proceeding from iridium(III) chloride hydrate, by reaction with 2 equivalents of the ligand L in a protic solvent or solvent mixture, typically a 3:1 mixture of 2-ethoxyethanol/water, under reflux, the chloro dimer [L₂IrCl]₂ is prepared. For further o-metallation, this is first converted to the methanol triflate [L₂Ir(HOMe)]OTf by reaction with silver triflate and methanol, typically in dichloromethane/methanol, and this is then reacted further with the ligand L′ to give the product. This method, used in many cases for preparation of heteroleptic complexes of bidentate ligands of the IrL₂L′ type, is described, for example, in WO 2010/027583 or in US 2014/0131676.

It is possible by these processes, if necessary followed by purification, for example chromatography, recrystallization, hot extraction and/or sublimation, to obtain the compounds of the invention in high purity, preferably more than 99% (determined by means of ¹H NMR and/or HPLC).

The compound of the invention can be used in the electronic device as active component, preferably as emitter in the emitting layer. The present invention thus further provides for the use of a compound of the invention in an electronic device, especially as emitter in the emitting layer of an OLED.

The present invention still further provides an electronic device comprising at least one compound of the invention.

An electronic device is understood to mean any device comprising anode, cathode and at least one layer, said layer comprising at least one organic or organometallic compound. The electronic device of the invention thus comprises anode, cathode and at least one layer containing at least one iridium complex of the invention. Preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), the latter being understood to mean both purely organic solar cells and dye-sensitized solar cells, organic optical detectors, organic photoreceptors, organic field-quench devices (O-FQDs), light-emitting electrochemical cells (LECs), oxygen sensors and organic laser diodes (O-lasers), comprising at least one compound of the invention in at least one layer. Compounds that emit in the infrared are suitable for use in organic infrared electroluminescent devices and infrared sensors. Particular preference is given to organic electroluminescent devices. The compounds of the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. In this case, it is possible that one or more hole transport layers are p-doped, for example with metal oxides such as MoO₃ or WO₃, or with (per)fluorinated electron-deficient aromatics or with electron-deficient cyano-substituted heteroaromatics (for example according to JP 4747558, JP 2006-135145, US 2006/0289882, WO 2012/095143), or with quinoid systems (for example according to EP1336208) or with Lewis acids, or with boranes (for example according to US 2003/0006411, WO 2002/051850, WO 2015/049030) or with carboxylates of the elements of main group 3, 4 or 5 (WO 2015/018539), and/or that one or more electron transport layers are n-doped.

It is likewise possible for interlayers to be introduced between two emitting layers, which have, for example, an exciton-blocking function and/or control charge balance in the electroluminescent device and/or generate charges (charge generation layer, for example in layer systems having two or more emitting layers, for example in white-emitting OLED components). However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are three-layer systems where the three layers exhibit blue, green and orange or red emission (for the basic construction see, for example, WO 2005/011013), or systems having more than three emitting layers. The system may also be a hybrid system wherein one or more layers fluoresce and one or more other layers phosphoresce. A preferred embodiment is tandem OLEDs. White-emitting organic electroluminescent devices may be used for lighting applications or else with colour filters for full-colour displays.

In a preferred embodiment of the invention, the organic electroluminescent device comprises the iridium complex of the invention as emitting compound in one or more emitting layers.

When the iridium complex of the invention is used as emitting compound in an emitting layer, it is preferably used in combination with one or more matrix materials. The mixture of the iridium complex of the invention and the matrix material contains between 0.1% and 99% by volume, preferably between 1% and 90% by volume, more preferably between 3% and 40% by volume and especially between 5% and 15% by volume of the iridium complex of the invention, based on the overall mixture of emitter and matrix material. Correspondingly, the mixture contains between 99.9% and 1% by volume, preferably between 99% and 10% by volume, more preferably between 97% and 60% by volume and especially between 95% and 85% by volume of the matrix material, based on the overall mixture of emitter and matrix material.

The matrix material used may generally be any materials which are known for the purpose according to the prior art. The triplet level of the matrix material is preferably higher than the triplet level of the emitter. Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, biscarbazole derivatives, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/015306, WO 2007/063754 or WO 2008/056746, zinc complexes, for example according to EP 652273 or WO 2009/062578, dibenzofuran derivatives, for example according to WO 2009/148015, WO 2015/169412, WO 2017/148564 or WO 2017/148565, or bridged carbazole derivatives, for example according to US 2009/0136779, WO 2010/050778, WO 2011/042107 or WO 2011/088877.

It may also be preferable to use a plurality of different matrix materials as a mixture, especially at least one electron-conducting matrix material and at least one hole-conducting matrix material. A preferred combination is, for example, the use of an aromatic ketone, a triazine derivative or a phosphine oxide derivative with a triarylamine derivative or a carbazole derivative as mixed matrix for the metal complex of the invention. Preference is likewise given to the use of a mixture of a charge-transporting matrix material and an electrically inert matrix material (called a “wide bandgap host”) having no significant involvement, if any, in the charge transport, as described, for example, in WO 2010/108579 or WO 2016/184540. Preference is likewise given to the use of two electron-transporting matrix materials, for example triazine derivatives and lactam derivatives, as described, for example, in WO 2014/094964.

It is further preferable to use a mixture of two or more triplet emitters, especially two or three triplet emitters, together with one or more matrix materials. In this case, the triplet emitter having the shorter-wave emission spectrum serves as co-matrix for the triplet emitter having the longer-wave emission spectrum. For example, the metal complexes of the invention can be combined with a metal complex emitting at shorter wavelength, for example a blue-, green- or yellow-emitting metal complex, as co-matrix. For example, it is also possible to use the metal complexes of the invention as co-matrix for triplet emitters that emit at longer wavelength, for example for red-emitting triplet emitters. In this case, it may also be preferable when both the shorter-wave- and the longer-wave-emitting metal complex is a compound of the invention. A preferred embodiment in the case of use of a mixture of three triplet emitters is when two are used as co-host and one as emitting material. These triplet emitters preferably have the emission colours of green, yellow and red or blue, green and orange.

A preferred mixture in the emitting layer comprises an electron-transporting host material, what is called a “wide bandgap” host material which, owing to its electronic properties, is not involved to a significant degree, if at all, in the charge transport in the layer, a co-dopant which is a triplet emitter which emits at a shorter wavelength than the compound of the invention, and a compound of the invention.

A further preferred mixture in the emitting layer comprises an electron-transporting host material, what is called a “wide bandgap” host material which, owing to its electronic properties, is not involved to a significant degree, if at all, in the charge transport in the layer, a hole-transporting host material, a co-dopant which is a triplet emitter which emits at a shorter wavelength than the compound of the invention, and a compound of the invention.

The compounds of the invention can also be used in other functions in the electronic device, for example as hole transport material in a hole injection or transport layer, as charge generation material, as electron blocker material, as hole blocker material or as electron transport material, for example in an electron transport layer. It is likewise possible to use the compounds of the invention as matrix material for other phosphorescent metal complexes in an emitting layer.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum.

Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (O-SC) or the emission of light (OLED/PLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

Suitable charge transport materials as usable in the hole injection or hole transport layer or electron blocker layer or in the electron transport layer of the organic electroluminescent device of the invention are, for example, the compounds disclosed in Y. Shirota et al., Chem. Rev. 2007, 107(4), 953-1010, or other materials as used in these layers according to the prior art. Preferred hole transport materials which can be used in a hole transport, hole injection or electron blocker layer in the electroluminescent device of the invention are indenofluoreneamine derivatives (for example according to WO 06/122630 or WO 06/100896), the amine derivatives disclosed in EP 1661888, hexaazatriphenylene derivatives (for example according to WO 01/049806), amine derivatives having fused aromatic systems (for example according to U.S. Pat. No. 5,061,569), the amine derivatives disclosed in WO 95/09147, monobenzoindenofluoreneamines (for example according to WO 08/006449), dibenzoindenofluoreneamines (for example according to WO 07/140847), spirobifluoreneamines (for example according to WO 2012/034627, WO 2014/056565), fluoreneamines (for example according to EP 2875092, EP 2875699 and EP 2875004), spirodibenzopyranamines (e.g. EP 2780325) and dihydroacridine derivatives (for example according to WO 2012/150001).

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapour deposition in vacuum sublimation systems at an initial pressure of typically less than 10⁻⁵ mbar, preferably less than 10⁻⁶ mbar. It is also possible that the initial pressure is even lower or even higher, for example less than 10⁻⁷ mbar.

Preference is likewise given to an organic electroluminescent device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured.

Preference is additionally given to an organic electroluminescent device, characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution.

The organic electroluminescent device can also be produced as a hybrid system by applying one or more layers from solution and applying one or more other layers by vapour deposition. For example, it is possible to apply an emitting layer comprising a metal complex of the invention and a matrix material from solution, and to apply a hole blocker layer and/or an electron transport layer thereto by vapour deposition under reduced pressure.

These methods are known in general terms to those skilled in the art and can be applied by those skilled in the art without any problems to organic electroluminescent devices comprising the compounds of the invention. In a preferred embodiment of the invention, the emitting layer is applied by a sublimation method.

The electronic devices of the invention, especially organic electroluminescent devices, are notable for one or more of the following advantages over the prior art:
1. The iridium complexes of the invention are highly efficient when used as emitter in an OLED. More particularly, the external quantum efficiency (EQE) is much better than in the case of complexes having an optical orientation anisotropy Θ>0.24°.
2. The iridium complexes of the invention, when used as emitter in an OLED, show only a very small voltage shift, if any. The voltage shift refers here to a shift to a higher use voltage when the emitter concentration in the emitting layer is increased. This results in a lower operating voltage compared to materials having a voltage shift. More particularly, the voltage shift is much lower than in the case of complexes that are optically oriented but where the angle α between the transition dipole moment μ_{act} and the electrical dipole moment d is >40°. A reduction in the voltage shift, apart from a reduction in operating voltage, also leads to an improvement in lifetime.
3. The iridium complexes of the invention, when used as emitter in an OLED, show a very good lifetime. More particularly, the lifetime is better than in the case of iridium complexes that have good orientation but have an angle α between the transition dipole moment μ_{act} and the electrical dipole moment d of >40°.

The invention is illustrated in more detail by the examples which follow, without any intention of restricting it thereby. The person skilled in the art will be able to use the details given, without exercising inventive skill, to produce further electronic devices of the invention and hence to execute the invention over the entire scope claimed.

### DESCRIPTION OF THE FIGURES

FIG. 1: Flow diagram for discovery of suitable complexes with optical orientation anisotropy Θ≤0.24 and angle α(μ_{act},d)≤40° between transition dipole moment of the active ligand μ_{act} and electrical dipole moment of the complex d by extension of one ligand and modification of the two others. (QC=quantum-chemical calculation)

FIG. 2: Transition dipole moment μ_{L} of one of the three ppy ligands, and electrical dipole moment of the singlet ground state d of Ir(ppy)₃.

FIG. 3:

a) Selection of extension units based on the ratio between the square roots of the eigenvalues λ_{z}≥λ_{y}≥λₓ of the gyration tensor.
b) Influence of the extension unit R on the optical orientation anisotropy Θ using the example of Ir(ppy-CN)₂(ppy-R).

FIG. 4:

a) Definition of the long axis p_{z} and attachment point of the extension unit.
b) Diagram for discovering the attachment point to the ligand via angle β_{Cn} between transition dipole moment of the ligand μ_{L} and p_{z}.

FIG. 5: Transition dipole moment of the active ligand μ_{act} in the heteroleptic complex Ir(ppy)₂(ppy-C3-biphenyl); this lies closer to the extension axis p_{z} than was to be expected from the homoleptic complex Ir(ppy)₃ (μ_{L} of the homoleptic complex as a dotted line).

FIG. 6:

a) Electrical dipole moment d in the C3 axis of symmetry in the homoleptic complex Ir(ppy)₃ (α(μ_{act},d)=80°).
b) Loss of symmetry through extension of the active ligand, such that d points somewhat more along the active ligand and, at the same time, there is also a change in the direction of μ_{act} compared to Ir(ppy)₃ (α(μ_{act},d)=55°).
c) and d) Further distance of d from the C3 axis of symmetry through electronically active cyano groups in the two co-ligands at position C8 or C7 (α(μ_{act},d)=25° for Ir(ppy-C7-CN)₂(ppy-C3-biphenyl)).

FIG. 7:

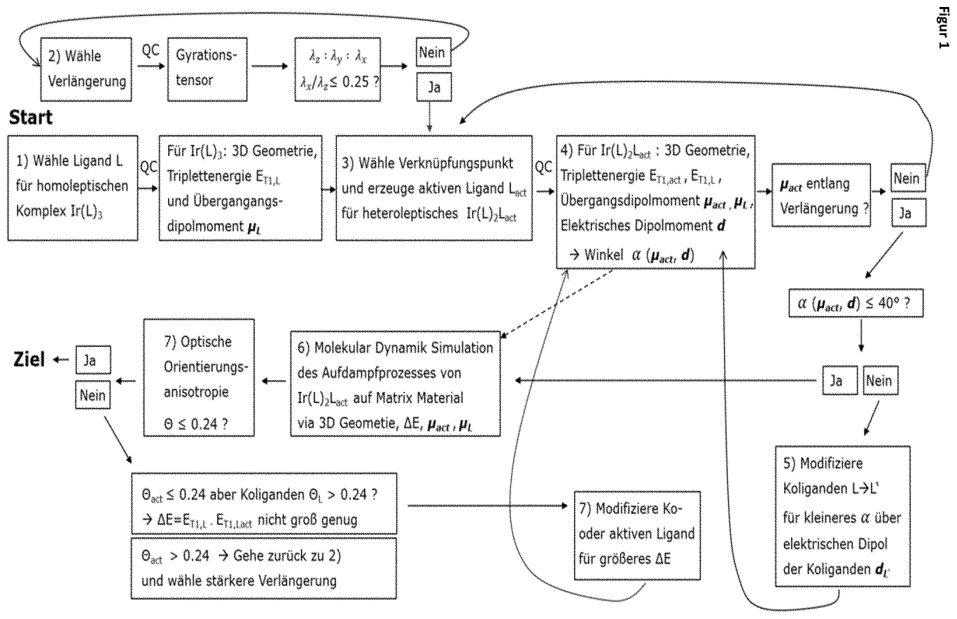

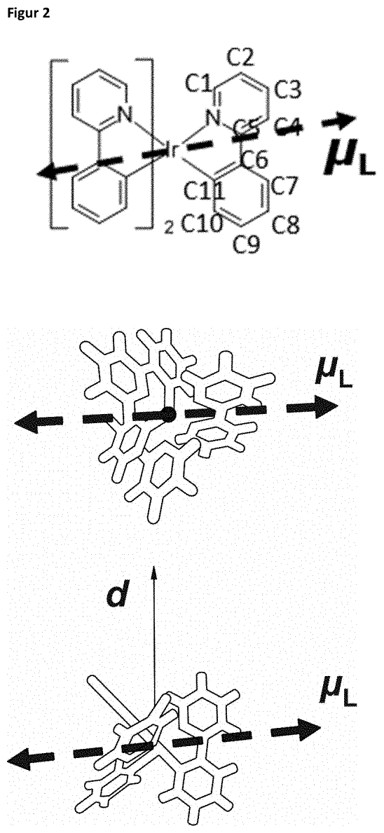

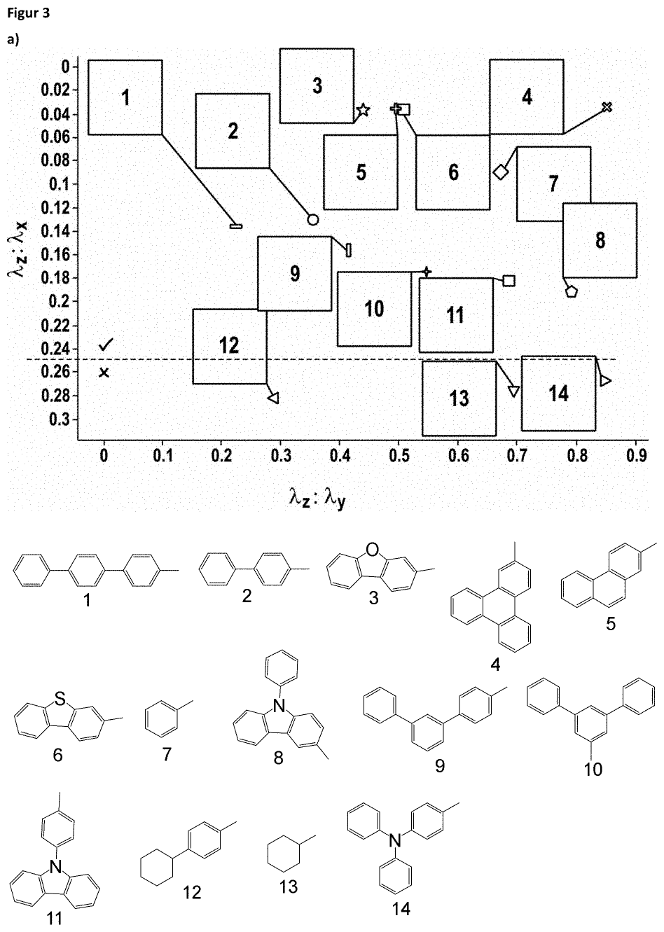

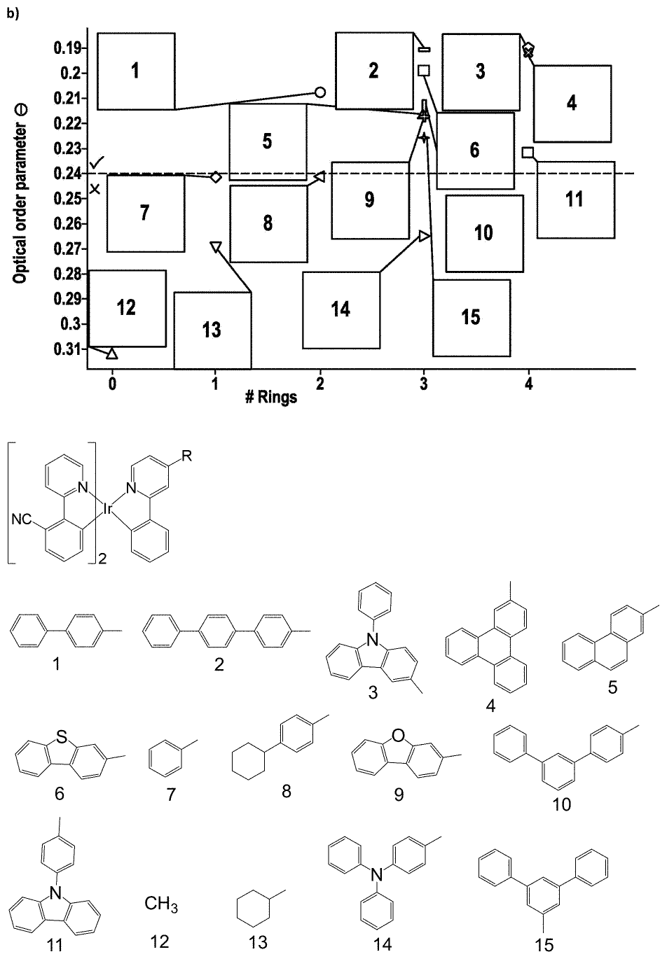

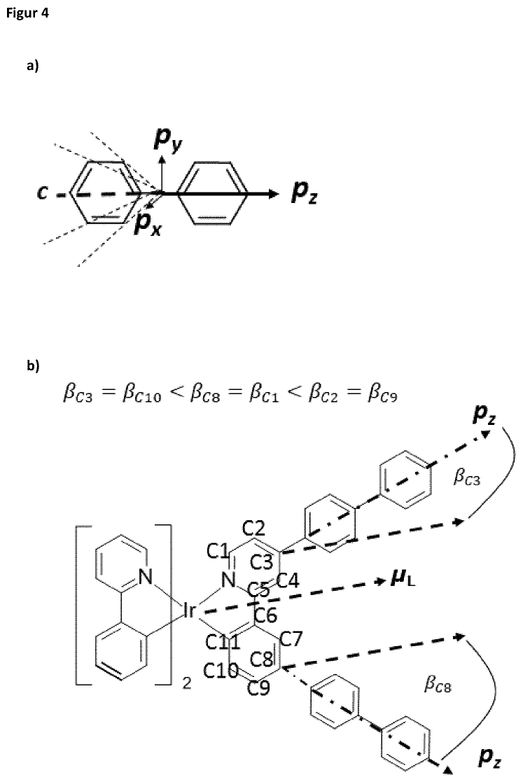

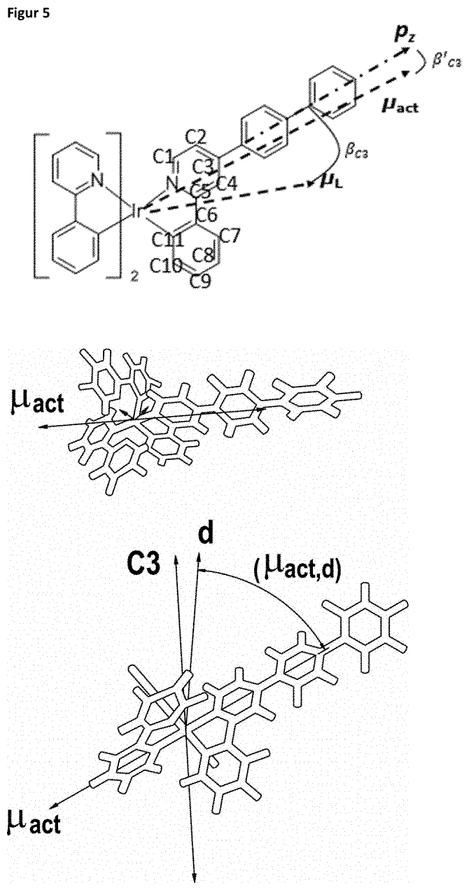

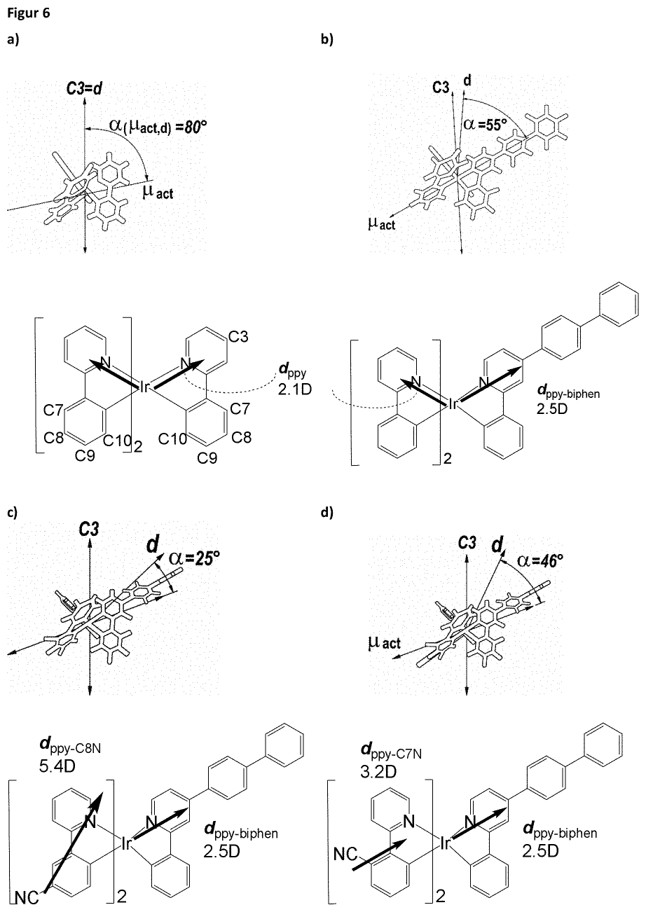

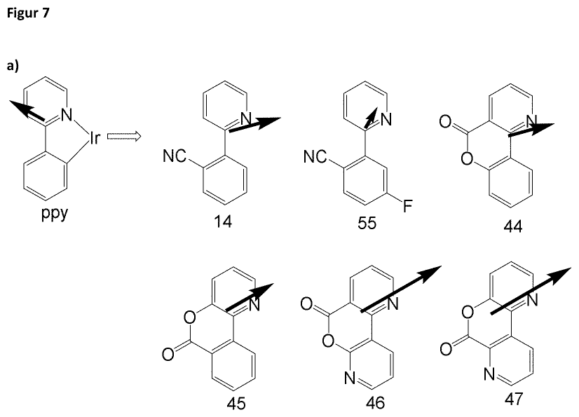

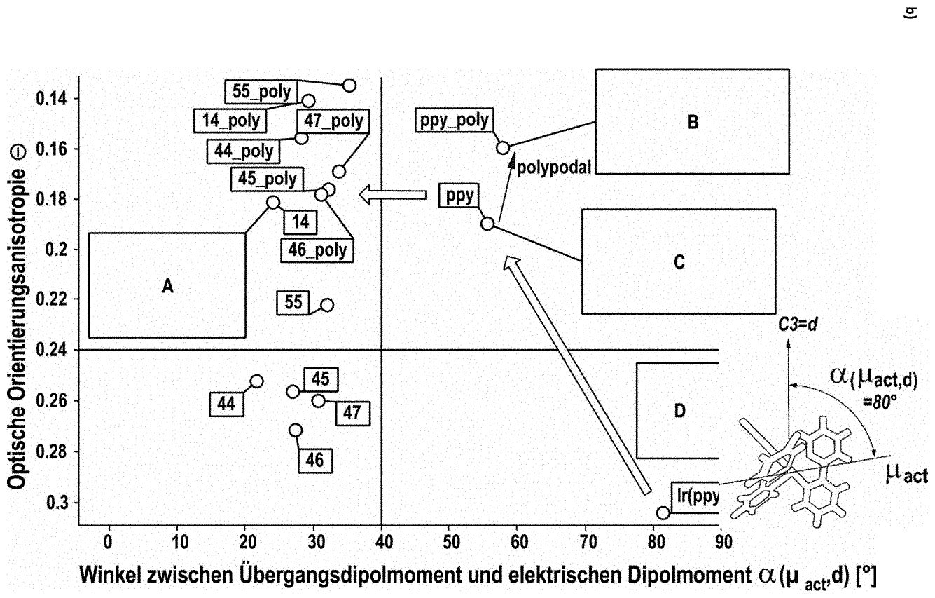

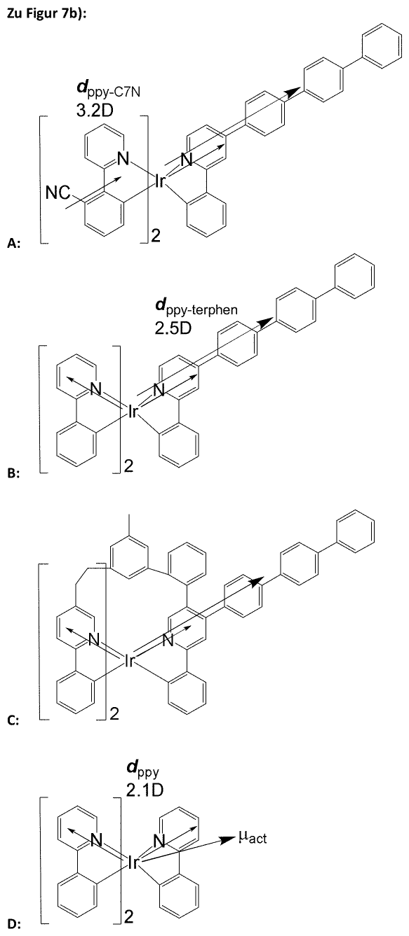

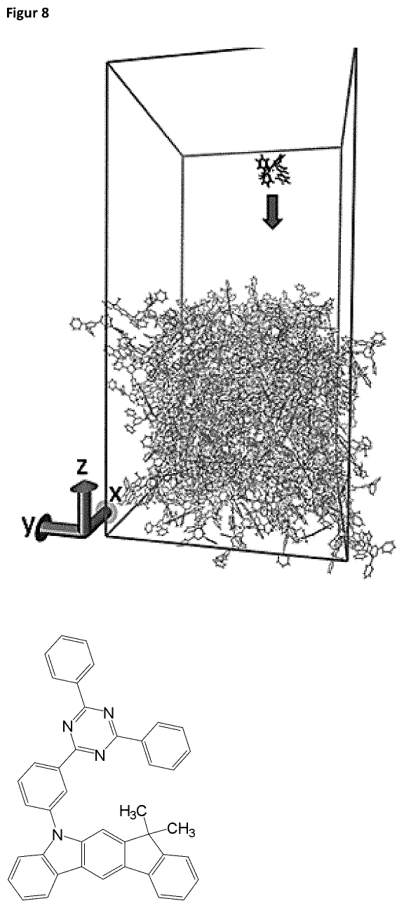

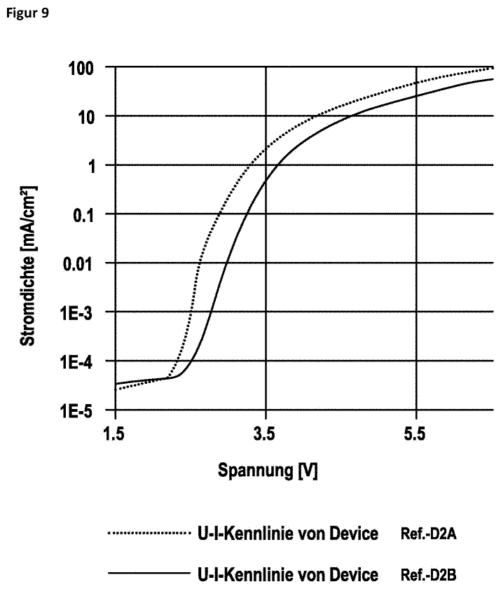

a) Electronically modified ppy co-ligands L which, owing to altered electrical dipole moments (arrows), lead to small angles α(μ_{act},d) between transition dipole moment μ_{act} and electrical dipole moment d of the overall complex Ir(L)₂L_{act} with active ppy-C3-terphenylligand. The length of the arrows corresponds to the magnitude of the electrical dipole moments of the ligands.
b) Optical orientation anisotropy Θ and angle α(μ_{act},d) for the co-ligands L from a) in combination with active (ppy-C3-terphenyl), once without polypodal bridging and once with polypodal bridging (identified in the nomenclature by the addition “poly” for polypodal), as shown on the right as the structure.

FIG. 8: Simulation box of 263 matrix molecules of the structure depicted that represent an isotropic substrate for the process of vapour deposition of an emitter, for example Ir(ppy)₃ (description in part 2 of the Examples).

FIG. 9: Voltage shift at the transition from emitter concentration 5% to 15% by volume with a reference emitter where the angle α(μ_{act},d) is >40°.

### EXAMPLES

Part 1: Method of Determining the Angle α(μ_{act},d) Between Transition Dipole Moment of the Active Ligand μ_{act} and the Electrical Dipole Moment of the Overall Complex d by Means of Quantum-Chemical Calculations
1.1 Quantum-Chemical Calculation of the Emitter Triplet Energies E_{T1,L} and E_{T1,act} for Co-Ligand Ir(L) and the Active Ligand Ir(L_{act}) and the Electrical Dipole Moment of the Overall Complex d

In order to determine the energies of the three lowest triplet states of an emitter each centred on one of the ligands (without taking account of relativistic effects), the geometries are optimized with UB3LYP/LANL2DZ+6-31G(d) level, using 6-31G(d) as the basis for all non-metal atoms, while LanL2DZ is used for the iridium atoms. Let the three triplet energies obtained be \tilde{E}_{T1,i}, where i=1, 2, 3 relate to the three ligands. The assignment of the triplet states obtained to the ligands identified as active or inactive is made with the aid of the spin density and the bond lengths between the central iridium atom and the atoms coordinated thereto. The zero point energy is calculated for all three triplet states (let this energy be [symbol] _{T1,i}), and hence it is also verified that the geometries obtained constitute a minimum. Equally, the singlet ground state of the complexes is optimized at the B3LYP/LANL2DZ+6-31G(d) level (let its energy be \tilde{E}_{S0}), and the zero-point energy (let this energy be [symbol] _{S0}) is likewise determined.

The electrical dipole moment of the overall complex d is determined on the basis of this singlet ground state calculation, and the geometry is used for the force field of the molecular dynamics simulation in part 2.

The triplet energies of the individual ligands i=1, 2, 3 are determined as:

E_{T1,i}=\tilde{E}_{T1,i}+ [symbol] _{T1,i}−É_{S0}− [symbol] _{S0}

The ligand with the smallest triplet energy is referred to hereinafter as active ligand and its triplet energy as E_{T1,act}; the two others are referred to as co-ligands and their triplet energy as E_{T1,L} (N.B.: the triplet energies of the two co-ligands are not strictly degenerate, but merely about the same).

The triplet states of the organic extension units are determined by analogous calculations. For this purpose, the neutral ground state of the extension unit is optimized with B3LYP/6-31G(d) and then frequencies for determination of the zero-point energy are calculated. Equally, the triplet state is optimized with UB3LYP/6-31G(d) and its zero-point energy is calculated. Analogously to the triplet energies of the ligands of the metal complexes, the zero-point energy-corrected adiabatic triplet transition is calculated as the triplet energy of the aromatic extension units.

### 1.2 Quantum-Chemical Calculation of the Electrical Dipole Moments of the Individual Ligands

The electrical dipole moments of the individual ligands (with Ir replaced by H) are calculated with B3LYP/6-31G(d) on the basis of the B3LYP/6-31G(d)-optimized ground state geometry, and serve to predict the electrical dipole moment of the overall complex by means of vector addition in the octahedral binding situation.

For all quantum chemistry calculations, the Gaussian09 software package using the standard convergence settings is used.

1.3 Quantum Chemical Calculation of the Transition Dipole Moments μ_{L} and μ_{act} for Co-Ligands and Active Ligands

The transition dipole moments of the three ligands of the emitter μᵢ with i=1, 2, 3 are calculated with TD-B3LYP and the relativistic ZORA Hamiltonian (zero-order regular approximation). This is done using the triplet energies of the three ligands optimized at the UB3LYP/LANL2DZ+6-31G(d) level (see 1.1 above), using 6-31G(d) as the basis for all non-metal atoms, while LanL2DZ is used for the iridium atoms. Only the geometries of the lowest-energy triplet states are used, i.e. those states from which emission is expected, assuming that the population of the excited triplet states approximates to a Boltzmann distribution (see 2.2). In the TD-DFT calculation with B3LYP, which explicitly takes account of spin-orbit coupling by means of the relativistic ZORA Hamiltonian, the all-electron DZP basis sets of ADF are used for all non-metal atoms, while the all-electron TZP basis is used for iridium. Transition dipole moments are obtained for all spin sub-states. The actual transition dipole moment used for the ligand is the vector of the brightest spin sub-state of the ligand. This usually corresponds to the third-lowest state of a ligand. The brightest state refers to that state with the greatest transition dipole moment or the highest oscillator intensity, accompanied by the highest radiative rate Rᵢ. The complex transition dipole moment of ligand i is projected onto the real axis in the complex plane and identified by μᵢ. The ligand with the smallest triplet energy is also referred to as active ligand (see 1.1), and its transition dipole moment is referred to as μ_{act}, while the two others are identified as co-ligands with transition dipole moment μ_{L}. For this calculation, the ADF program is used (taking account of the standard convergence criteria and the full kernel of the functional).

1.4 Calculation of the Angle α(μ_{act},d) Between Transition Dipole Moment of the Active Ligand μ_{act} and Electrical Dipole Moment of the Overall Complex

The angle α(μ_{act},d) between the electrical dipole moment d of the complex and the transition dipole moment of the active ligand μ_{act} is calculated by α(μ_{act},d)=a cos [μ_{act}*d/(|μ_{act}∥d|)]×180°/π via the arccosine of the scalar product (*) of the two vectors and their magnitudes (∥). Since this at first allows values of α(μ_{act},d)=0° to +180°, but μ_{act} describes a dipole that oscillates back and forth (i.e. μ_{act} describes exactly the same physics as −μ_{act}), it is then necessary, for values α>90°, instead to use α′=180°−α, such that, for example, rather than α=120°, α′=180°−20°=60° is then used. Thus, the possible values for α(μ_{act},d) are limited to 0° to 90°, preference being given to smaller angles.

### 1.5 Calculation of the Eigenvalues of the Gyration Tensor for the Aromatic Extension Unit

For the extension unit, the gyration tensor Sₘₙ is defined via the positions rₘ⁽ⁱ⁾ with m=x, y, z of the i=1 . . . N atoms, as found from the quantum-chemical optimizations of geometry in the neutral ground state at B3LYP/6-31G(d) level (as described at the end of part 1.1). This is done by inserting the centre of geometry into the zero point of the system of coordinates, such that the following definition and diagonal form are applicable to Sₘₙ:

$${S}_{mn} {=}^{def} \frac{1}{N} {\sum }_{n = 1}^{N} {r}_{m}^{( i )} {r}_{n}^{( i )}$$

$$S = [ \begin{matrix}{λ}_{x}^{2} & 0 & 0 \\ 0 & {λ}_{y}^{2} & 0 \\ 0 & 0 & {λ}_{z}^{2}\end{matrix} ]$$

$${\sum }_{n = 1}^{N} {r}^{( i )} = 0$$

$${λ}_{x}^{2} \leq {λ}_{y}^{2} \leq {λ}_{z}^{2}$$

For calculation of the three eigenvectors of the gyration tensor (for definition of the axis of extension p_{z}) and the roots of the eigenvalues λ_{x,y,z} for the determination of the “flatness” of the extension unit, the atom coordinates r⁽ⁱ⁾ can be transferred, for example, to the polystat module of the free software package GROMACS (J. Chem. Theory Comput. 4(3):435-447, 2008), which gives the roots of the eigenvalues and eigenvectors, where p_{z} is the eigenvector for the greatest eigenvalue λ_{z}.

### Part 2: Calculation of the Optical Orientation Anisotropy Θ by Means of Molecular Dynamics Simulation of the Vapour Deposition Process

### 2.1 Simulation of the Complex Orientation

For the calculation of the optical orientation anisotropy Θ, the process of vapour deposition of the emitters is simulated by means of molecular dynamics. For this purpose, first of all, for adequate statistics, 576 independent substrates each consisting of an isotropic film of the matrix material TMM shown below are simulated, onto each of which an emitter is vapour-deposited later on. For this purpose, for each substrate, 263 matrix molecules with random orientation are arranged in a cubic simulation box with edge length L=9 nm and then equilibrated in x, y, z by means of molecular dynamics in the NPT ensemble (constant particle number N, constant pressure P=1 bar and constant temperature=700 K) and periodic boundary conditions, and then cooled to 300 K at a cooling rate of 10 K/ns, so as to give a cubic box with edge length of about L=6 nm. All molecular dynamics situations are conducted with free software GROMACS (J. Chem. Theory Comput. 4(3):435-447, 2008) with a time increment of 0.002 ps and with frozen bond lengths. The pressure is kept constant with the aid of the Berendsen thermostat (J. Chem. Phys., 81(8):3684, 1984) and compressibility 4.5×10⁻⁵ bar; temperature is treated by means of velocity rescaling (J. Chem. Phys., 126(1):014101, 2007) with time constant 2 ps and electrostatic interactions by means of the particle mesh Ewald method (J. Chem. Phys., 103:8577-8592, 1995).

For the force field of the matrix and the emitter molecules, the basis used is the OPLSaa (“Optimized for Liquid Simulations all atoms”) force field (J. Am. Chem. Soc., 110(6):1657-1666, 1988) with geometric averages for the Lennard Jones parameter. However, the geometry used for the force fields is the quantum-chemically optimized singlet ground state geometry—at B3LYP/6-31G(d) level for TMM and B3LYP/LANL2DZ+6-31G(d) for Ir complexes (as described in part 1.1). The equilibrium positions for bond lengths, angles and torsion potentials are likewise used from this singlet ground state geometry and atom charges are generated by means of the Merz-Kolmann method by a fit of the electrostatic potential (ESP) of the electron density from these quantum-chemical calculations. Bond lengths are frozen in the course of the molecular dynamics simulation, and unknown force constants of the angle and torsion potentials are calculated by means of quantum-chemical energy scans (Rühle et al., J. Chem. Theory Comput., 2011, 7 (10), pp 3335-3345).

According to the present invention, the material depicted below is used as TMM.

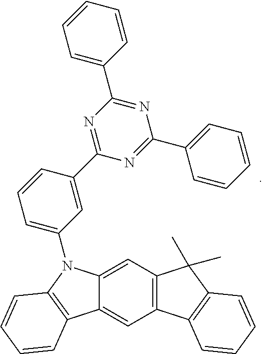 [SMILES: CC1(C)c2ccccc2-c2cc3c4ccccc4n(-c4cccc(-c5nc(-c6ccccc6)nc(-c6ccccc6)n5)c4)c3cc21]

For all substrates, the z direction is then defined as the surface normal and the simulation box is extended along z to 12 nm, but the periodic boundary conditions in x and y are retained. Thereafter, an emitter with random orientation and centroid is positioned with random x,y coordinates and z=3 nm above the matrix film (defined as the highest z coordinate of all matrix atoms; see FIG. 8) and initiated with a velocity of 0.1 nm/ps in substrate direction. Then, in the NVT (constant particle number N, constant volume and constant temperature=300 K) ensemble, the process of vapour deposition of this emitter on the substrate is simulated for 6 ns and the coordinates of the emitter are read out every 20 ps. A simulation box of 263 matrix molecules of the structure depicted that represent an isotropic substrate for the process of vapour deposition of an emitter, for example Ir(ppy)₃, is shown in FIG. 8.

### 2.2. Calculation of the Optical Orientation Anisotropy Θ

In order to calculate the optical orientation anisotropy Θ, an average is calculated over all substrates and emitters read out, such that a total of N=576*6000 ps/20 ps=172 800 orientations is available.

For this purpose, the three transition dipole moments μᵢ with i=1, 2, 3 for the three ligands from the quantum-chemical calculation (see part 1.3 of the Examples) are rotated onto every emitter read out from the molecular dynamics, choosing appropriate rotation and translation of the atom coordinates from the singlet ground state calculation (see part 1.1 of the Examples) such that the iridium atom and the 6 atoms bonded thereto from the quantum-chemical calculation have minimum spatial difference from those from the molecular dynamics.

For the average optical orientation anisotropy Θᵢ of the transition dipole moment i=1, 2, 3, only the z components of the n=1 . . . N transition dipole moments μ_{z,i}ⁿ rotated into the simulation box are considered (i.e. in the direction of the substrate normal), such that

$${Θ}_{i} = {\sum }_{n = 1}^{N} {( {μ}_{z , i}^{n} )}^{2} / {\sum }_{n = 1}^{N} ( {( {μ}_{x , i}^{n} )}^{2} + {( {μ}_{y , i}^{n} )}^{2} + {( {μ}_{z , i}^{n} )}^{2} ) .$$

The three average optical orientation anisotropies of the three transition dipole moments of the three ligands are then used to create a final average for the overall complex via Boltzmann weighting and quantitative weighting, such that ultimately

$${Θ}_{i} = {\sum }_{i = 1}^{3} {Θ}_{i} {p}_{i} {q}_{i} / {\sum }_{i = 1}^{3} {p}_{i} {q}_{i} ,$$

where the Boltzmann weighting

$${p}_{i} = exp [ - \frac{{E}_{T 1 , i}}{{k}_{B} T} ] / {\sum }_{i = 1}^{3} [ - \frac{{E}_{T 1 , i}}{{k}_{B} T} ]$$

expresses the triplet energy E_{T1,i} of the ligand i from the quantum chemical calculation (part 1.1) in relation to the thermal energy (T=300 K, k_{B}=Boltzmann constant) and the quantitative weighting qᵢ=Rᵢ/Σᵢ₌₁³ Rᵢ is calculated from the radiative rates Rᵢ of the ligand i from the quantum-chemical calculation (part 1.3).

The optical orientation anisotropies Θ thus ascertained give sufficiently good agreement with angle-dependent photoluminescence measurements for 10% emitter in the above-depicted triplet matrix material TMM (correlation coefficient R²=0.70 for 30 emitters analysed).

### Part 3: Measurement of Emitter Orientation in the Vapour-Deposited Film

In order to experimentally ascertain the orientation of the complexes in the emissive layer, an individual layer of a complex in a host material (matrix material) is vapour-deposited onto a quartz glass substrate with a Sunic Clustertool. There is 10% by volume of the complex and 90% of the matrix present here in the layer. The sample is encapsulated. The measured optical properties of the pure matrix material, using physical laws of optics, can be used to calculate a result for a potential 100% horizontal and 100% vertical orientation of the molecules. According to the present invention, the TMM used is the material depicted in part 2 of the Examples.

In the measurement setup, the vapour-deposited sample containing the complex is irradiated with a laser, the molecules are excited and then the photoluminescence spectrum emitted is measured in an angle-dependent manner. Subsequently, the measurements are fitted to the extreme orientations calculated (see paragraph above) and hence the orientation factor (optical orientation anisotropy) is determined. A perfect horizontal orientation of the molecules is described by Θ=0, the isotropic case by Θ=0.33, and the completely vertically aligned case by Θ=1. This value reflects the averaged orientation over all molecules in the layer that have been excited by the photoluminescence process, meaning that all complex molecules lie within the measurement spot irradiated by the laser. It is not possible to determine the orientation of a single molecule by this method.

### Part 4: Measurement of Photoluminescence Quantum Efficiency (PLQE)

In a glovebox, under a protective gas atmosphere with a maximum of 5 ppm of oxygen, 1 mg of the complex is weighed out and dissolved in toluene seccosolv in a concentration of 1 mg/100 ml. The dissolved complexes are introduced into an analytical cuvette. Absorption and photoluminescence spectra are measured with a Perkin-Elmer Lambda 9 spectrometer and Hitachi F4500. The end of the absorption band is ascertained. Subsequently, the PLQE is measured in a commercial setup from Hamamatsu (C9920-01, -02). First of all, the samples are installed into an Ulbricht sphere. The measurement is commenced about 10 nm below the ascertained absorption edge of the complex and then measurement is continued in step widths of 10 nm. The measurement is always effected in alternation between reference and sample before a new excitation wavelength is set and the next measurement commences. The wavelength is increased and measurements are made constantly until there is a distinct rise in quantum efficiency. Subsequently, averaging of the measurements is conducted in order to quantify the value of the PLQE for the material analysed.

### Part 5: Synthesis of the Complexes

The syntheses which follow, unless stated otherwise, are conducted under a protective gas atmosphere in dried solvents. The metal complexes are additionally handled with exclusion of light or under yellow light. The solvents and reagents can be purchased, for example, from Sigma-ALDRICH or ABCR. The respective figures in square brackets or the numbers quoted for individual compounds relate to the CAS numbers of the compounds known from the literature. In the case of compounds that can have multiple isomeric, tautomeric, diastereomeric or enantiomeric forms, one form is shown in a representative manner.

### A: Synthesis of the Synthons S and the Bidentate Ligands L

### Example S1

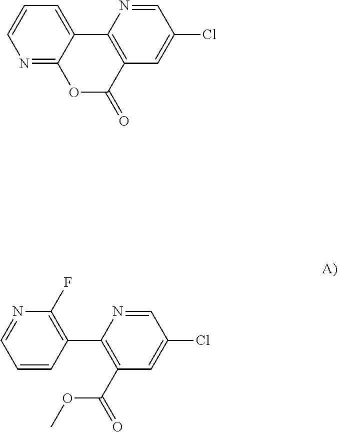 [SMILES: O=c1oc2ncccc2c2ncc(Cl)cc12 ; COC(=O)c1cc(Cl)cnc1-c1cccnc1F]

A mixture of 20.6 g (100 mmol) of methyl 2,5-dichloropyridine-3-carboxylate [67754-03-4], 15.5 g (110 mmol) of (2-fluoropyridin-3-yl)boronic acid [174669-73-9], 41.4 g (300 mmol) of potassium carbonate, 702 mg (1 mmol) of bis(triphenylphosphino)palladium(II) chloride [13965-03-2], 300 ml of methanol and 300 ml of acetonitrile is heated under reflux for 16 h. After cooling, the reaction mixture is stirred into 3 l of water and stirred for a further 30 min, and the precipitated product is filtered off with suction, washed three times with 50 ml each time of methanol, dried under reduced pressure, taken up in 500 ml of DCM and filtered through a silica gel bed in the form of a DCM slurry, said silica gel bed is washed through with 500 ml of DCM, the DCM is largely removed under reduced pressure, and the residue is recrystallized from acetonitrile. Yield: 20.9 g (78 mmol), 78%; purity: about 95% by ¹H NMR.

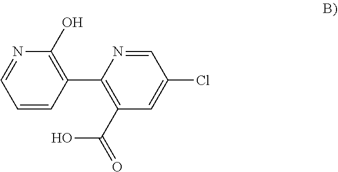 [SMILES: O=C(O)c1cc(Cl)cnc1-c1cccnc1O]

A mixture of 26.7 g (100 mmol) of A), 16.8 g (300 mmol) of potassium hydroxide, 250 ml of ethanol and 75 ml of water is stirred at 70° C. for 16 h. After cooling, the mixture is acidified to pH˜5 by addition of 1 N hydrochloric acid and stirred for a further 1 h. The precipitated product is filtered off with suction, washed once with 50 ml of water and once with 50 ml of methanol, and then dried under reduced pressure. Yield: 23.8 g (95 mmol), 95%; purity: about 97% by ¹H NMR.

### C) S1

A mixture of 25.1 g (100 mmol) B) and 951 mg (5 mmol) of p-toluenesulfonic acid monohydrate in 500 ml of toluene is heated under reflux on a water separator for 16 h. After cooling, the reaction mixture is stirred in an ice/water bath for another 1 h. The solids are filtered off with suction, washed with 50 ml of toluene and dried under reduced pressure. The solids are then extracted by stirring with 300 ml of water, filtered off with suction and washed with 100 ml of water in order to remove the p-toluenesulfonic acid. After filtration with suction and drying under reduced pressure, the final drying is effected by azeotropic drying twice with toluene. Yield: 20.5 g (88 mmol), 88%; purity: about 97% by ¹H NMR.

In an analogous manner, it is possible to prepare the compounds below.

| Ex. | Reactant | Product | Yield |
|---|---|---|---|
| S2 | 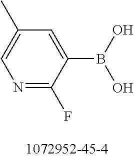 | 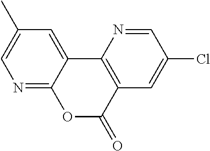 [SMILES: Cc1cnc2oc(=O)c3cc(Cl)cnc3c2c1] | 65% |
| S3 | 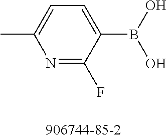 | 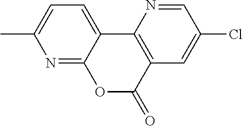 [SMILES: Cc1ccc2c(n1)oc(=O)c1cc(Cl)cnc12] | 61% |
| S4 | 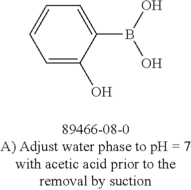 | 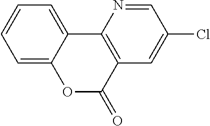 [SMILES: O=c1oc2ccccc2c2ncc(Cl)cc12] | 44% |

### Example S10

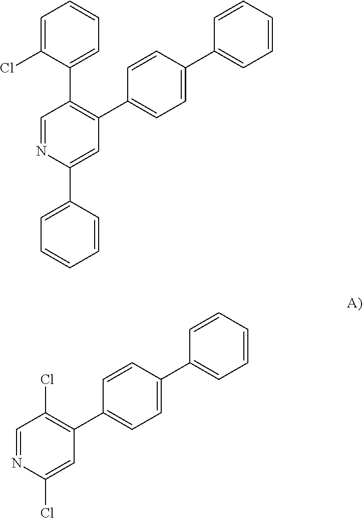 [SMILES: Clc1ccccc1-c1cnc(-c2ccccc2)cc1-c1ccc(-c2ccccc2)cc1 ; Clc1cc(-c2ccc(-c3ccccc3)cc2)c(Cl)cn1]

A mixture of 27.4 g (100 mmol) of 2,5-dichloro-4-iodopyridine [796851-03-1], 19.8 g (100 mmol) of 4-biphenylboronic acid [5122-94-1], 41.4 g (300 mmol) of potassium carbonate, 702 mg (1 mmol) of bis(triphenylphosphino)palladium(II) chloride [13965-03-2], 300 ml of methanol and 300 ml of acetonitrile is heated under reflux for 16 h. After cooling, the reaction mixture is stirred into 3 l of warm water and stirred for a further 30 min, and the precipitated product is filtered off with suction, washed three times with 50 ml each time of methanol, dried under reduced pressure, taken up in 500 ml of DCM, filtered through a silica gel bed in the form of a DCM slurry and then recrystallized from acetonitrile. Yield: 28.5 g (95 mmol), 95%; purity: about 97% by ¹H NMR.

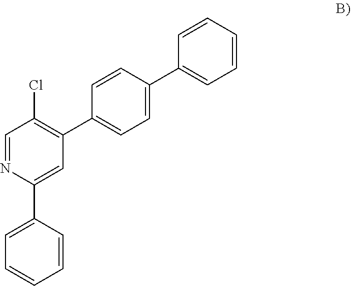 [SMILES: Clc1cnc(-c2ccccc2)cc1-c1ccc(-c2ccccc2)cc1]

### Variant 1:

Procedure as described in A), except that, rather than 4-biphenylboronic acid, 12.2 g (100 mmol) of phenylboronic acid [98-80-6] is used. Reaction time 24-30 h. Yield: 26.0 g (76 mmol), 76%; purity: about 97% by ¹H NMR.

### Variant 2:

Alternatively, the Suzuki coupling can also be effected in the biphasic toluene/dioxane/water system (2:1:2 w) using 3 equivalents of tripotassium phosphate and 1 mol % of bis(triphenylphosphino)palladium(II) chloride.

### C) S10

A mixture of 34.2 g (100 mmol) of S10 Stage B), 17.2 g (110 mmol) of 2-chlorophenylboronic acid [3900-89-8], 63.7 g (300 mmol) of tripotassium phosphate, 1.64 g (4 mmol) of SPhos, 449 mg (2 mmol) of palladium(II) acetate, 600 ml of THE and 200 ml of water is heated under reflux for 24 h. After cooling, the aqueous phase is removed, the organic phase is concentrated to dryness, the glassy residue is taken up in 200 ml of ethyl acetate/DCM (4:1 w) and filtered through a silica gel bed (about 500 g of silica gel) in the form of an ethyl acetate/DCM (4:1 vv) slurry, and the core fraction is separated out. The core fraction is concentrated to about 100 ml, and the crystallized product is filtered off with suction, washed twice with 50 ml each time of methanol and dried under reduced pressure. Further purification is effected by fractional Kugelrohr distillation under reduced pressure (˜10⁻³-10⁻⁴ mbar), with removal of a little S10 Stage B) in the initial fraction, leaving higher oligomers. Yield: 29.7 g (71 mmol), 71%; purity: about 95% by ¹H NMR.

Analogously, by using the corresponding boronic acids/esters in A), B) and C), it is possible to prepare the compounds below.

| | Reactant | | |
|---|---|---|---|
| Ex. | Variant 1 | Product | Yield |
| S11 | 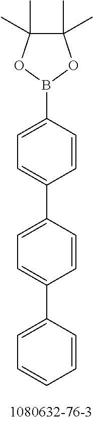 | 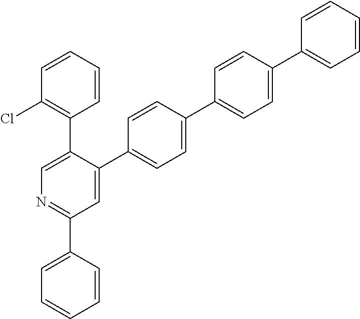 [SMILES: Clc1ccccc1-c1cnc(-c2ccccc2)cc1-c1ccc(-c2ccc(-c3ccccc3)cc2)cc1] | 53% |
| S12 | 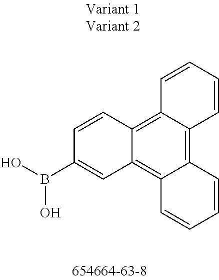 [SMILES: OB(O)c1ccc2c3ccccc3c3ccccc3c2c1] | 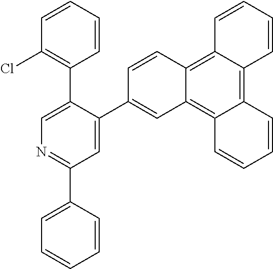 [SMILES: Clc1ccccc1-c1cnc(-c2ccccc2)cc1-c1ccc2c3ccccc3c3ccccc3c2c1] | 30% 58% |
| S13 | 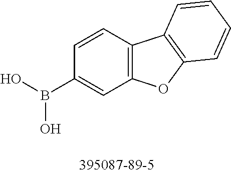 [SMILES: OB(O)c1ccc2c(c1)oc1ccccc12] | 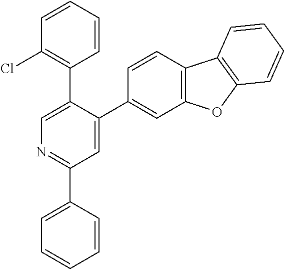 [SMILES: Clc1ccccc1-c1cnc(-c2ccccc2)cc1-c1ccc2c(c1)oc1ccccc12] | 47% |
| S14 | 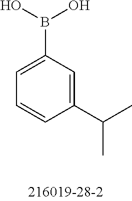 | 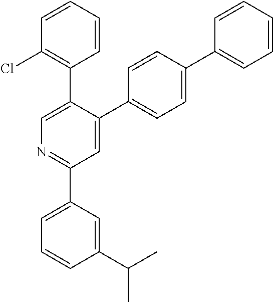 [SMILES: CC(C)c1cccc(-c2cc(-c3ccc(-c4ccccc4)cc3)c(-c3ccccc3Cl)cn2)c1] | 48% |
| S15 | 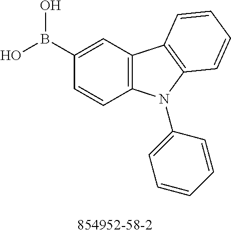 [SMILES: OB(O)c1ccc2c(c1)c1ccccc1n2-c1ccccc1] | 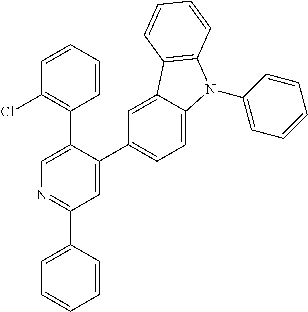 [SMILES: Clc1ccccc1-c1cnc(-c2ccccc2)cc1-c1ccc2c(c1)c1ccccc1n2-c1ccccc1] | 55% |
| S16 | 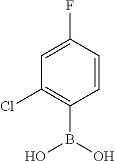 [SMILES: OB(O)c1ccc(F)cc1Cl] | 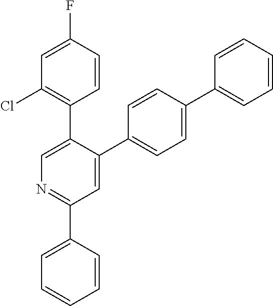 [SMILES: Fc1ccc(-c2cnc(-c3ccccc3)cc2-c2ccc(-c3ccccc3)cc2)c(Cl)c1] | 53% |

### Example S50

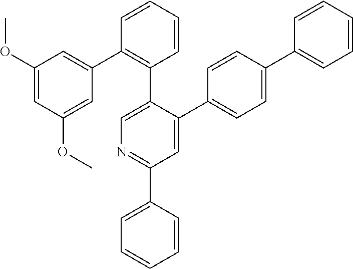 [SMILES: COc1cc(OC)cc(-c2ccccc2-c2cnc(-c3ccccc3)cc2-c2ccc(-c3ccccc3)cc2)c1]

To a mixture of 41.8 g (100 mmol) of S10, 20.0 g (110 mmol) of (3,5-dimethoxyphenyl)boronic acid [192182-54-0], 63.7 g (300 mmol) of tripotassium phosphate, 300 ml of toluene, 150 ml of dioxane and 300 ml of water are added, with good stirring, 1.64 g (4 mmol) of SPhos and then 449 mg (2 mmol) of palladium(II) acetate, and the mixture is heated under reflux for 24 h. After cooling, the organic phase is removed and washed twice with 300 ml each time of water and once with 300 ml of saturated sodium chloride solution, and dried over magnesium sulfate. The desiccant is filtered off, the filtrate is concentrated to dryness under reduced pressure and the vitreous crude product is recrystallized from acetonitrile at boiling. Yield: 40.0 g (77 mmol), 77%; purity: about 95% by ¹H NMR.

In an analogous manner, it is possible to prepare the compounds below.

| Ex. | Reactant | Product | Yield |
|---|---|---|---|
| S51 | S11 | 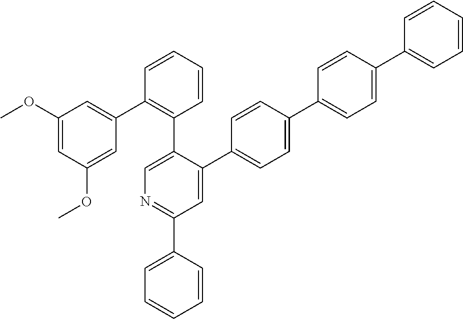 [SMILES: COc1cc(OC)cc(-c2ccccc2-c2cnc(-c3ccccc3)cc2-c2ccc(-c3ccc(-c4ccccc4)cc3)cc2)c1] | 74% |
| S52 | S12 | 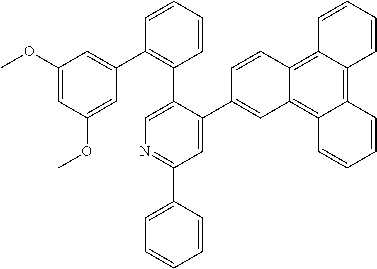 [SMILES: COc1cc(OC)cc(-c2ccccc2-c2cnc(-c3ccccc3)cc2-c2ccc3c4ccccc4c4ccccc4c3c2)c1] | 70% |
| S53 | S13 | 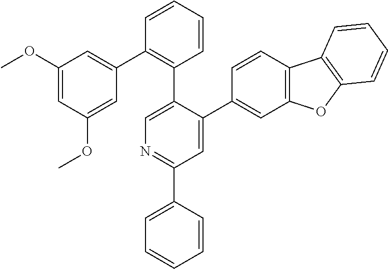 [SMILES: COc1cc(OC)cc(-c2ccccc2-c2cnc(-c3ccccc3)cc2-c2ccc3c(c2)oc2ccccc23)c1] | 67% |
| S54 | S14 | 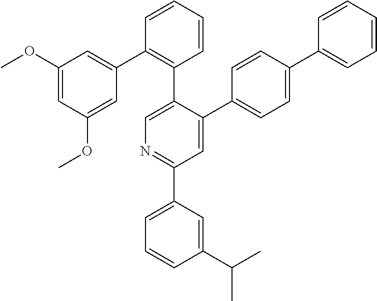 [SMILES: COc1cc(OC)cc(-c2ccccc2-c2cnc(-c3cccc(C(C)C)c3)cc2-c2ccc(-c3ccccc3)cc2)c1] | 71% |
| S55 | S15 | 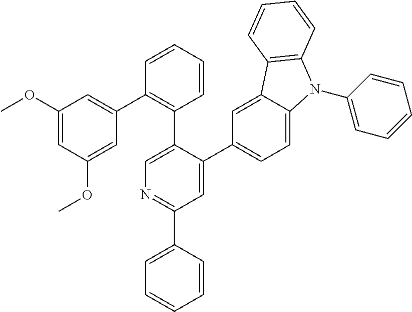 [SMILES: COc1cc(OC)cc(-c2ccccc2-c2cnc(-c3ccccc3)cc2-c2ccc3c(c2)c2ccccc2n3-c2ccccc2)c1] | 70% |
| S56 | S16 | 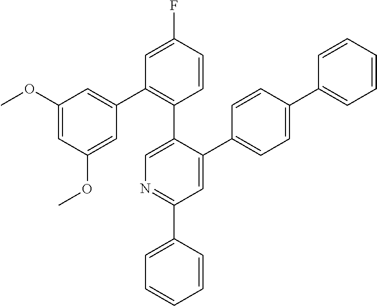 [SMILES: COc1cc(OC)cc(-c2cc(F)ccc2-c2cnc(-c3ccccc3)cc2-c2ccc(-c3ccccc3)cc2)c1] | 75% |

### Example S100

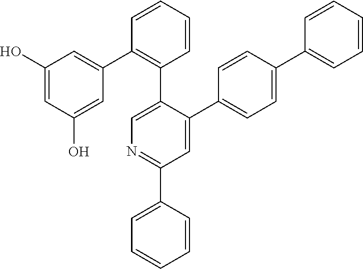 [SMILES: Oc1cc(O)cc(-c2ccccc2-c2cnc(-c3ccccc3)cc2-c2ccc(-c3ccccc3)cc2)c1]

A mixture of 52.0 g (100 mmol) of S50 and 231.2 g (2 mol) of pyridinium hydrochloride is heated to 220° C. (heating mantle) on a water separator for 4 h, discharging the distillate from time to time. The reaction mixture is left to cool down, 1000 ml of water is added dropwise starting from a temperature of ˜150° C. (caution: delayed boiling), the mixture is stirred for 2 h, then the mixture is neutralized by adding 10% ammonia while stirring and stirred for a further 5 h, and 10% ammonia is optionally added again until a neutral reaction. The solids are filtered off with suction, washed three times with 70 ml each time of MeOH and dried under reduced pressure. Residual water still present is removed by azeotropic drying with ethanol. Yield: 42.3 g (86 mmol), 86%; purity: about 95% by ¹H NMR.

In an analogous manner, it is possible to prepare the compounds below.

| Ex. | Reactant | Product | Yield |
|---|---|---|---|
| S101 | S51 | 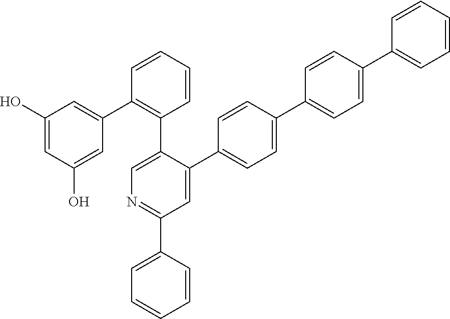 [SMILES: Oc1cc(O)cc(-c2ccccc2-c2cnc(-c3ccccc3)cc2-c2ccc(-c3ccc(-c4ccccc4)cc3)cc2)c1] | 88% |
| S102 | S52 | 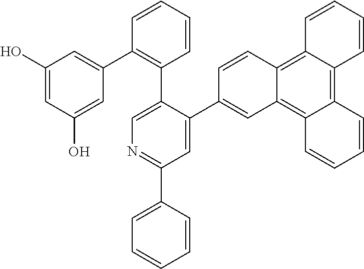 [SMILES: Oc1cc(O)cc(-c2ccccc2-c2cnc(-c3ccccc3)cc2-c2ccc3c4ccccc4c4ccccc4c3c2)c1] | 84% |
| S103 | S53 | 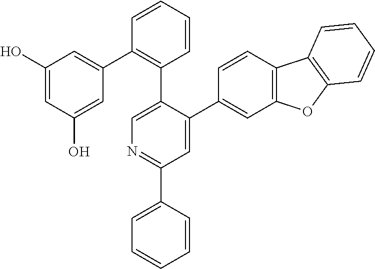 [SMILES: Oc1cc(O)cc(-c2ccccc2-c2cnc(-c3ccccc3)cc2-c2ccc3c(c2)oc2ccccc23)c1] | 85% |
| S104 | S54 | 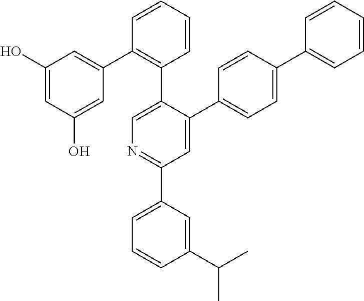 [SMILES: CC(C)c1cccc(-c2cc(-c3ccc(-c4ccccc4)cc3)c(-c3ccccc3-c3cc(O)cc(O)c3)cn2)c1] | 89% |
| S105 | S55 | 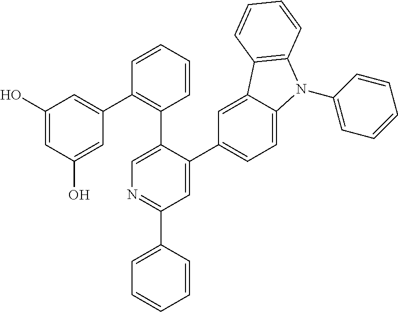 [SMILES: Oc1cc(O)cc(-c2ccccc2-c2cnc(-c3ccccc3)cc2-c2ccc3c(c2)c2ccccc2n3-c2ccccc2)c1] | 83% |
| S106 | S56 | 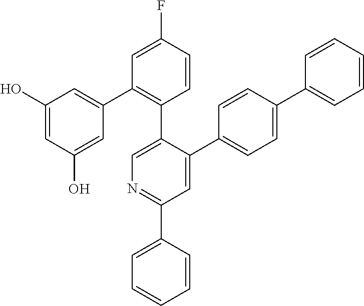 [SMILES: Oc1cc(O)cc(-c2cc(F)ccc2-c2cnc(-c3ccccc3)cc2-c2ccc(-c3ccccc3)cc2)c1] | 87% |

### Example S150

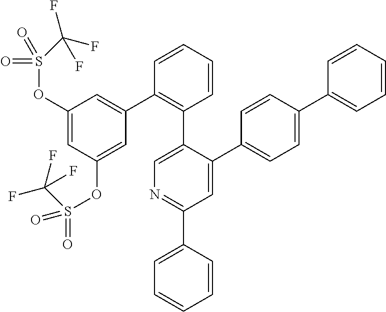 [SMILES: O=S(=O)(Oc1cc(OS(=O)(=O)C(F)(F)F)cc(-c2ccccc2-c2cnc(-c3ccccc3)cc2-c2ccc(-c3ccccc3)cc2)c1)C(F)(F)F]

To a suspension of 49.2 g (100 mmol) of S100 in 500 ml of DCM are added, while cooling with ice at 0° C. and with good stirring, 31.6 ml (400 mmol) of pyridine and then, dropwise, 50.4 ml (300 mmol) of trifluoromethanesulfonic anhydride. The mixture is stirred at 0° C. for 1 h and then at room temperature for 4 h. The reaction solution is poured onto 3 l of ice-water and stirred for a further 15 min, the organic phase is removed, washed once with 300 ml of ice-water, once with 300 ml of saturated sodium hydrogencarbonate solution and once with 300 ml of saturated sodium chloride solution and dried over magnesium sulfate, the desiccant is filtered off, the filtrate is concentrated to dryness and the foam is recrystallized from ethyl acetate at boiling. Yield: 49.1 g (65 mmol), 65%; purity: about 95% by ¹H NMR.

In an analogous manner, it is possible to prepare the compounds below.

| Ex. | Reactant | Product | Yield |
|---|---|---|---|
| S151 | S101 | 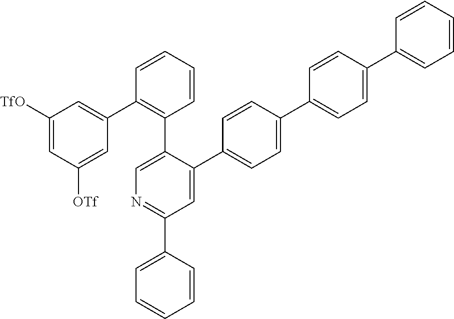 [SMILES: O=S(=O)(Oc1cc(OS(=O)(=O)C(F)(F)F)cc(-c2ccccc2-c2cnc(-c3ccccc3)cc2-c2ccc(-c3ccc(-c4ccccc4)cc3)cc2)c1)C(F)(F)F] | 72% |
| S152 | S102 | 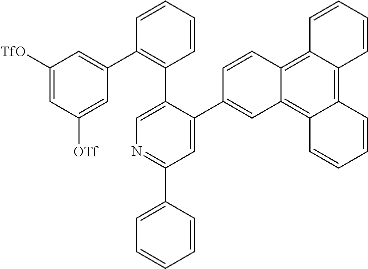 [SMILES: O=S(=O)(Oc1cc(OS(=O)(=O)C(F)(F)F)cc(-c2ccccc2-c2cnc(-c3ccccc3)cc2-c2ccc3c4ccccc4c4ccccc4c3c2)c1)C(F)(F)F] | 71% |
| S153 | S103 | 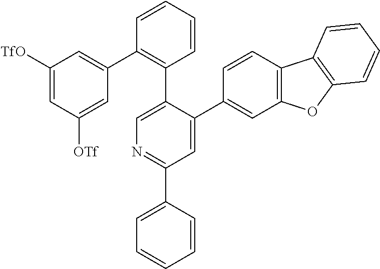 [SMILES: O=S(=O)(Oc1cc(OS(=O)(=O)C(F)(F)F)cc(-c2ccccc2-c2cnc(-c3ccccc3)cc2-c2ccc3c(c2)oc2ccccc23)c1)C(F)(F)F] | 68% |
| S154 | S104 | 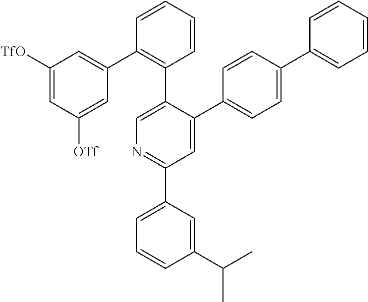 [SMILES: CC(C)c1cccc(-c2cc(-c3ccc(-c4ccccc4)cc3)c(-c3ccccc3-c3cc(OS(=O)(=O)C(F)(F)F)cc(OS(=O)(=O)C(F)(F)F)c3)cn2)c1] | 70% |
| S155 | S105 | 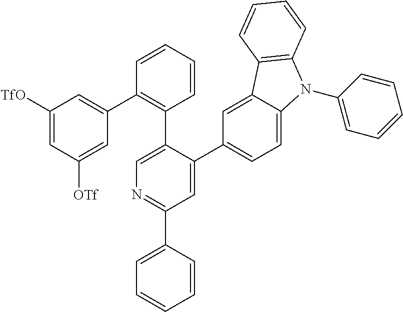 [SMILES: O=S(=O)(Oc1cc(OS(=O)(=O)C(F)(F)F)cc(-c2ccccc2-c2cnc(-c3ccccc3)cc2-c2ccc3c(c2)c2ccccc2n3-c2ccccc2)c1)C(F)(F)F] | 60% |
| S156 | S106 | 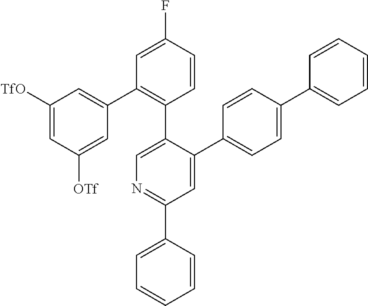 [SMILES: O=S(=O)(Oc1cc(OS(=O)(=O)C(F)(F)F)cc(-c2cc(F)ccc2-c2cnc(-c3ccccc3)cc2-c2ccc(-c3ccccc3)cc2)c1)C(F)(F)F] | 69% |

### Example S200

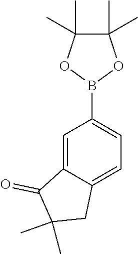 [SMILES: CC1(C)Cc2ccc(B3OC(C)(C)C(C)(C)O3)cc2C1=O]

To a mixture of 23.9 g (100 mmol) of 6-bromo-2,3-dihydro-2,2-dimethyl-1H-inden-1-one [165730-10-9], 26.7 g (105 mmol) of bis(pinacolato)diborane, 29.4 g (300 mmol) of potassium acetate (anhydrous), 50 g of glass beads (diameter 3 mm) and 300 ml of THE are added, with good stirring, 821 mg (2 mmol) of SPhos and then 225 mg (1 mmol) of palladium(II) acetate, and the mixture is heated under reflux for 8 h. After cooling, the salts and glass beads are removed by suction filtration through a Celite bed in the form of a THE slurry, which is washed through with a little THF, and the filtrate is concentrated to dryness. The residue is taken up in 300 ml of ethyl acetate, washed twice with 200 ml each time of water and once with 200 ml of saturated sodium chloride solution, and dried over magnesium sulfate. The desiccant is filtered off using a silica gel bed in the form of an ethyl acetate slurry, the filtrate is concentrated to dryness, the residue is taken up in 100 ml of DCM and 100 ml of n-heptane, and the DCM is removed gradually under reduced pressure, crystallizing the product. The crystallized product is filtered off with suction, washed twice with 30 ml each time of n-heptane and dried under reduced pressure. Yield: 23.8 g (83 mmol), 83%; purity: about 95% by ¹H NMR.

In an analogous manner, it is possible to prepare the compounds below.

| Ex. | Reactant | Product | Yield |
|---|---|---|---|
| S201 | 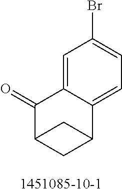 [SMILES: O=C1c2cc(Br)ccc2C2CC1C2] | 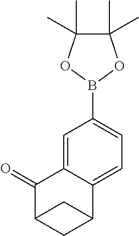 [SMILES: CC1(C)OB(c2ccc3c(c2)C(=O)C2CC3C2)OC1(C)C] | 76% |

### Example S250

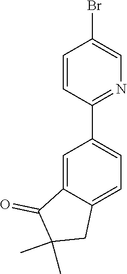 [SMILES: CC1(C)Cc2ccc(-c3ccc(Br)cn3)cc2C1=O]

A mixture of 23.7 g (100 mmol) of 2,5-dibromopyridine [624-28-2], 28.6 g (100 mmol) of S200, 27.6 g (200 mmol) of potassium carbonate, 50 g of glass beads (diameter 3 mm), 702 mg (1 mmol) of bis(triphenylphosphino)palladium(II) chloride [13965-03-2], 200 ml of acetonitrile and 200 ml of methanol is heated under reflux for 16 h. After cooling, the solvent is largely removed under reduced pressure, and the residue is taken up in 500 ml of ethyl acetate, washed three times with 200 ml each time of water and once with 300 ml of saturated sodium chloride solution and dried over magnesium sulfate. The desiccant is filtered off, the filtrate is concentrated to dryness and the solids are recrystallized from acetonitrile. Yield: 22.1 g (70 mmol), 70%; purity: about 95% by ¹H NMR.

In an analogous manner, it is possible to prepare the compounds below.

| Ex. | Reactant | Product | Yield |
|---|---|---|---|
| S251 | S201 | 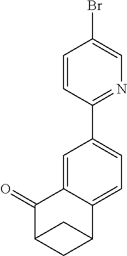 [SMILES: O=C1c2cc(-c3ccc(Br)cn3)ccc2C2CC1C2] | 74% |
| L100 | 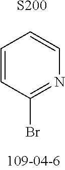 | 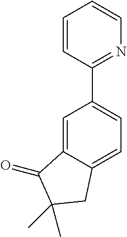 [SMILES: CC1(C)Cc2ccc(-c3ccccn3)cc2C1=O] | 70% |
| L101 | S201 109-04-6 | 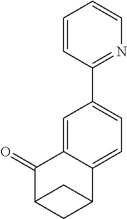 [SMILES: O=C1c2cc(-c3ccccn3)ccc2C2CC1C2] | 67% |

### B: Synthesis of the Tripodal Ligands

### Ligand L1:

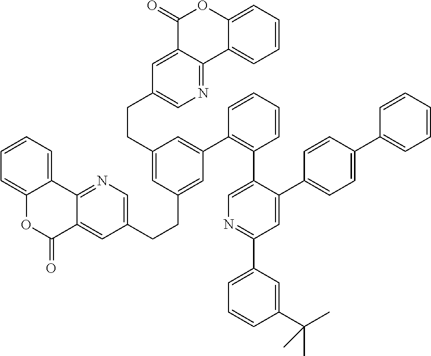 [SMILES: CC(C)(C)c1cccc(-c2cc(-c3ccc(-c4ccccc4)cc3)c(-c3ccccc3-c3cc(CCc4cnc5c(c4)c(=O)oc4ccccc45)cc(CCc4cnc5c(c4)c(=O)oc4ccccc45)c3)cn2)c1]

Preparation according to G. A. Molander et al., Organic Letters (2009), 11(11), 2369-2372. To a well-stirred suspension, cooled to 0° C., of 13.4 g (100 mmol) of potassium vinyltrifluoroborate [13682-77-4] in 500 ml of THE is added dropwise 200 ml (100 mmol) of a 9-BBN solution (0.5 M in THF), and then the mixture is stirred at room temperature for 2 h. To this solution are added 27.5 g (50 mmol) of S154, 17.4 g (300 mmol) of anhydrous KF, 1.18 g (3 mmol) DavePhos and 449 mg (2 mmol) of palladium(II) acetate, and the reaction mixture is stirred at 50° C. for 60 h. Then the THF is removed under reduced pressure, the residue is taken up in 500 ml of toluene, and 100 ml of water, 23.2 g (1 mmol) of S4, 41.5 g (300 mmol) of potassium carbonate and 1.87 g (3 mmol) of RuPhos are added, and the mixture is heated under gentle reflux for 30 h. After cooling, the aqueous phase is removed and the toluene phase is washed once with 200 ml of water and once with 200 ml of saturated sodium chloride solution, and then dried over magnesium sulfate. The desiccant is filtered off, the toluene is removed under reduced pressure and the residue is chromatographed on silica gel with n-heptane/ethyl acetate 3:1>1:1 (w). Yield: 16.3 g (18 mmol), 36%; purity: about 97% by ¹H NMR.

In an analogous manner, it is possible to prepare the compounds below.

| Ex. | Reactant | Product | Yield |
|---|---|---|---|
| L2 | S151 S4 | 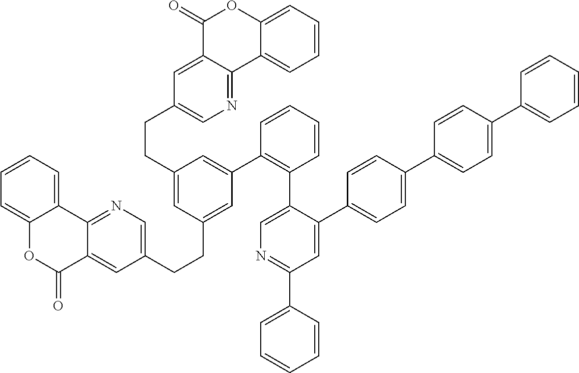 [SMILES: O=c1oc2ccccc2c2ncc(CCc3cc(CCc4cnc5c(c4)c(=O)oc4ccccc45)cc(-c4ccccc4-c4cnc(-c5ccccc5)cc4-c4ccc(-c5ccc(-c6ccccc6)cc5)cc4)c3)cc12] | 33% |
| L3 | S152 S4 | 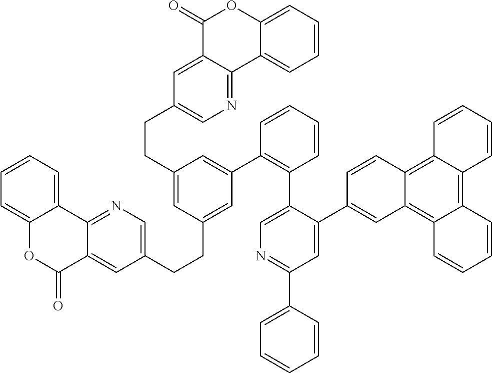 [SMILES: O=c1oc2ccccc2c2ncc(CCc3cc(CCc4cnc5c(c4)c(=O)oc4ccccc45)cc(-c4ccccc4-c4cnc(-c5ccccc5)cc4-c4ccc5c6ccccc6c6ccccc6c5c4)c3)cc12] | 37% |
| L4 | S153 S4 | 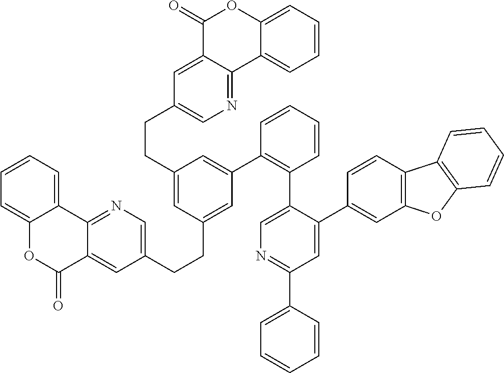 [SMILES: O=c1oc2ccccc2c2ncc(CCc3cc(CCc4cnc5c(c4)c(=O)oc4ccccc45)cc(-c4ccccc4-c4cnc(-c5ccccc5)cc4-c4ccc5c(c4)oc4ccccc45)c3)cc12] | 29% |
| L5 | S154 S4 | 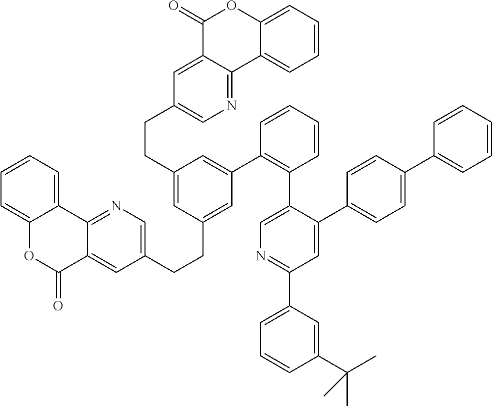 [SMILES: CC(C)(C)c1cccc(-c2cc(-c3ccc(-c4ccccc4)cc3)c(-c3ccccc3-c3cc(CCc4cnc5c(c4)c(=O)oc4ccccc45)cc(CCc4cnc5c(c4)c(=O)oc4ccccc45)c3)cn2)c1] | 30% |
| L6 | S155 S4 | 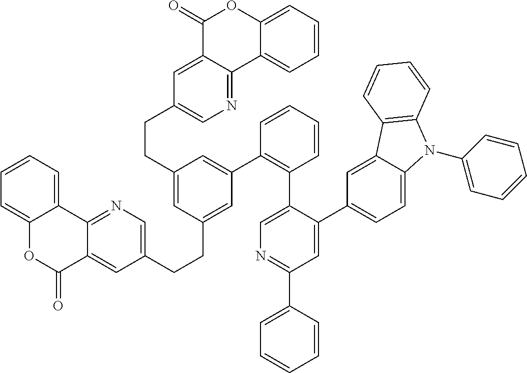 [SMILES: O=c1oc2ccccc2c2ncc(CCc3cc(CCc4cnc5c(c4)c(=O)oc4ccccc45)cc(-c4ccccc4-c4cnc(-c5ccccc5)cc4-c4ccc5c(c4)c4ccccc4n5-c4ccccc4)c3)cc12] | 33% |
| L7 | S156 S4 | 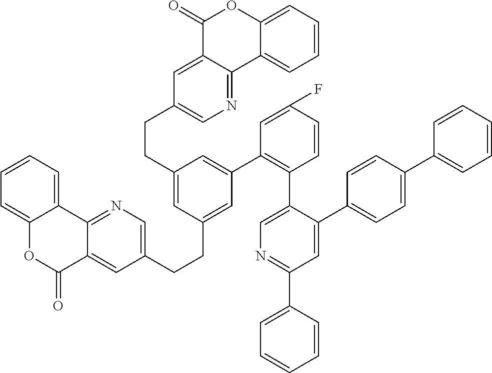 [SMILES: O=c1oc2ccccc2c2ncc(CCc3cc(CCc4cnc5c(c4)c(=O)oc4ccccc45)cc(-c4cc(F)ccc4-c4cnc(-c5ccccc5)cc4-c4ccc(-c5ccccc5)cc4)c3)cc12] | 28% |
| L8 | S150 S1 | 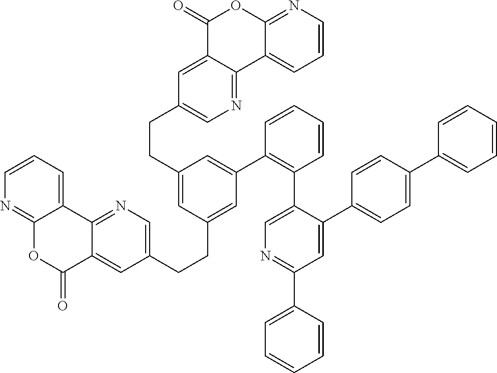 [SMILES: O=c1oc2ncccc2c2ncc(CCc3cc(CCc4cnc5c(c4)c(=O)oc4ncccc45)cc(-c4ccccc4-c4cnc(-c5ccccc5)cc4-c4ccc(-c5ccccc5)cc4)c3)cc12] | 26% |
| L9 | S150 S2 | 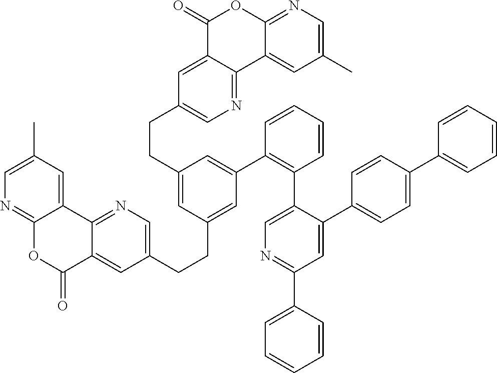 [SMILES: Cc1cnc2oc(=O)c3cc(CCc4cc(CCc5cnc6c(c5)c(=O)oc5ncc(C)cc56)cc(-c5ccccc5-c5cnc(-c6ccccc6)cc5-c5ccc(-c6ccccc6)cc5)c4)cnc3c2c1] | 29% |
| L10 | S150 S3 | 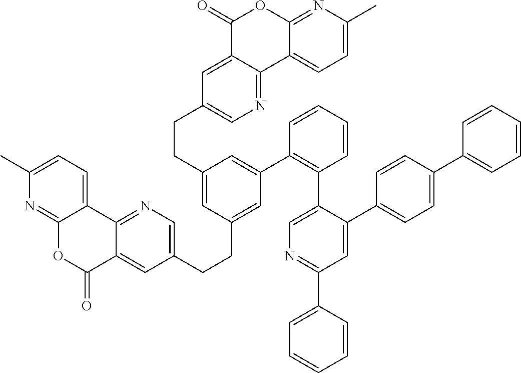 [SMILES: Cc1ccc2c(n1)oc(=O)c1cc(CCc3cc(CCc4cnc5c(c4)c(=O)oc4nc(C)ccc45)cc(-c4ccccc4-c4cnc(-c5ccccc5)cc4-c4ccc(-c5ccccc5)cc4)c3)cnc12] | 30% |
| L11 | 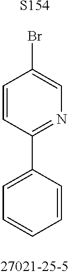 | 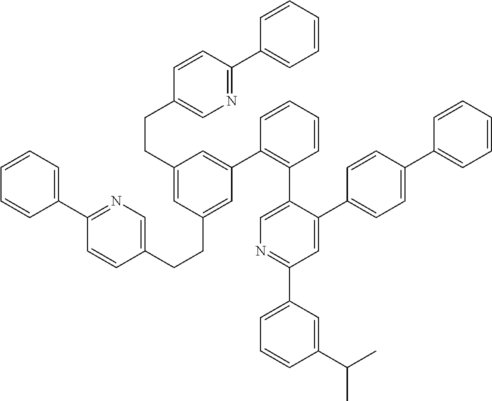 [SMILES: CC(C)c1cccc(-c2cc(-c3ccc(-c4ccccc4)cc3)c(-c3ccccc3-c3cc(CCc4ccc(-c5ccccc5)nc4)cc(CCc4ccc(-c5ccccc5)nc4)c3)cn2)c1] | 40% |
| L12 | 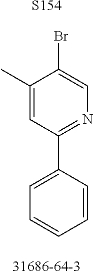 | 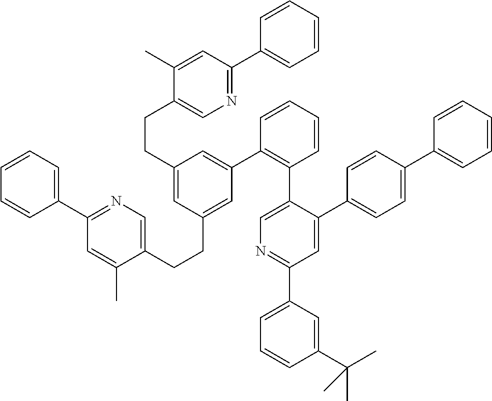 [SMILES: Cc1cc(-c2ccccc2)ncc1CCc1cc(CCc2cnc(-c3ccccc3)cc2C)cc(-c2ccccc2-c2cnc(-c3cccc(C(C)(C)C)c3)cc2-c2ccc(-c3ccccc3)cc2)c1] | 33% |
| L13 | S150 S250 | 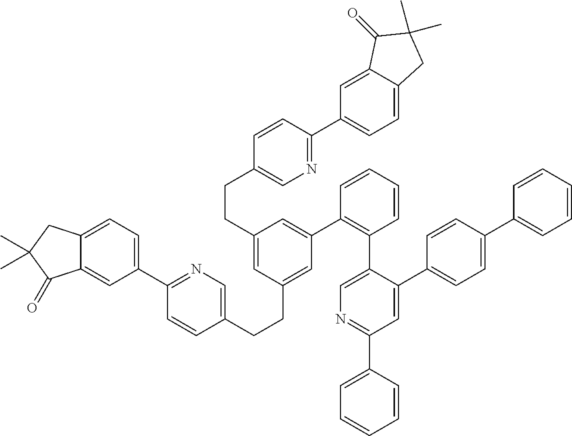 [SMILES: CC1(C)Cc2ccc(-c3ccc(CCc4cc(CCc5ccc(-c6ccc7c(c6)C(=O)C(C)(C)C7)nc5)cc(-c5ccccc5-c5cnc(-c6ccccc6)cc5-c5ccc(-c6ccccc6)cc5)c4)cn3)cc2C1=O] | 35% |
| L14 | S150 S251 | 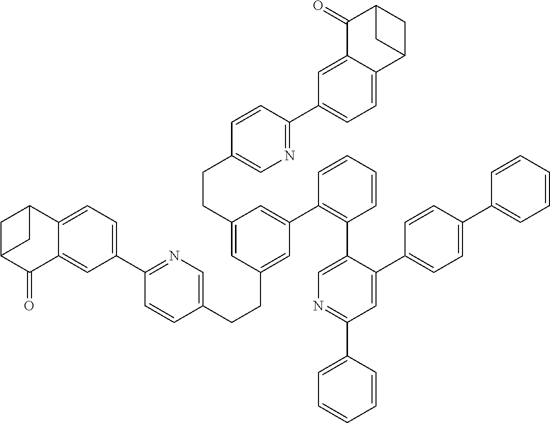 [SMILES: O=C1c2cc(-c3ccc(CCc4cc(CCc5ccc(-c6ccc7c(c6)C(=O)C6CC7C6)nc5)cc(-c5ccccc5-c5cnc(-c6ccccc6)cc5-c5ccc(-c6ccccc6)cc5)c4)cn3)ccc2C2CC1C2] | 37% |

### C

### 1) Synthesis of the Tripodal Metal Complexes

### Example Ir(L1)

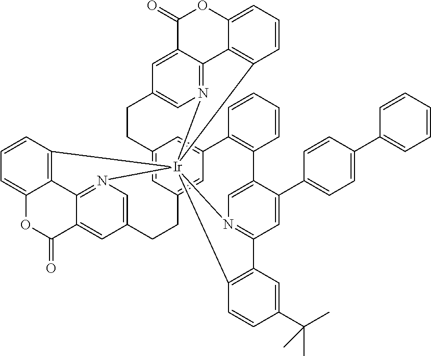

A mixture of 9.06 g (10 mmol) of ligand L1, 4.90 g (10 mmol) of trisacetylacetonatoiridium(III) [15635-87-7] and 120 g of hydroquinone [123-31-9] is initially charged in a 1000 ml two-neck round-bottom flask with a glass-sheathed magnetic bar. The flask is provided with a water separator (for media of lower density than water) and an air condenser with argon blanketing. The flask is placed in a metal heating bath. The apparatus is purged with argon from the top via the argon blanketing system for 15 min, allowing the argon to flow out of the side neck of the two-neck flask. Through the side neck of the two-neck flask, a glass-sheathed Pt-100 thermocouple is introduced into the flask and the end is positioned just above the magnetic stirrer bar. Then the apparatus is thermally insulated with several loose windings of domestic aluminum foil, the insulation being run up to the middle of the riser tube of the water separator. Then the apparatus is heated rapidly with a heated laboratory stirrer system to 250-255° C., measured with the Pt-100 temperature sensor which dips into the molten stirred reaction mixture. Over the next 2 h, the reaction mixture is kept at 250-255° C., in the course of which a small amount of condensate is distilled off and collects in the water separator. After 2 h, the mixture is allowed to cool down to 190° C., the heating mantle is removed and then 100 ml of ethylene glycol are added dropwise. After cooling to 100° C., 400 ml of methanol are slowly added dropwise. The yellow suspension thus obtained is filtered through a double-ended frit, and the yellow solids are washed three times with 50 ml of methanol and then dried under reduced pressure. The crude yield is quantitative. The solid thus obtained is dissolved in 1500 ml of dichloromethane and filtered through about 1 kg of silica gel in the form of a dichloromethane slurry (column diameter about 18 cm) with exclusion of air in the dark, leaving dark-coloured components at the start. The core fraction is cut out and concentrated on a rotary evaporator, with simultaneous continuous dropwise addition of MeOH until crystallization. After filtration with suction, washing with a little MeOH and drying under reduced pressure, the orange product is purified further by continuous hot extraction three times with dichloromethane/isopropanol 1:1 (vv) and then hot extraction three times with dichloromethane/acetonitrile 1:1 (vv) (amount initially charged in each case about 200 ml, extraction thimble: standard Soxhlet thimbles made of cellulose from Whatman) with careful exclusion of air and light. The loss into the mother liquor can be adjusted via the ratio of dichloromethane (low boilers and good dissolvers):isopropanol or acetonitrile (high boilers and poor dissolvers). It should typically be 3-6% by weight of the amount used. Hot extraction can also be accomplished using other solvents such as toluene, xylene, ethyl acetate, butyl acetate, etc. Finally, the product is subjected to fractional sublimation under high vacuum at p about 10⁻⁶ mbar and T about 400-430° C. Yield: 6.46 g (5.8 mmol), 58%; purity: >99.8% by HPLC.

The metal complexes are typically obtained as a 1:1 mixture of the Λ and Δ isomers/enantiomers. The images of the complexes adduced hereinafter typically show only one isomer. If ligands having three different sub-ligands are used, or chiral ligands are used as a racemate, the metal complexes derived are obtained as a diastereomer mixture. These can be separated by fractional crystallization or by chromatography, for example with an automatic column system (CombiFlash from A. Semrau). If chiral ligands are used in enantiomerically pure form, the metal complexes derived are obtained as a diastereomer mixture, the separation of which by fractional crystallization or chromatography leads to pure enantiomers. The separated diastereomers or enantiomers can be purified further as described above, for example by hot extraction.

In an analogous manner, it is possible to prepare the following compounds:

| Ex. | Ligand | Product | Yield |
|---|---|---|---|
| Ir(L2) | L2 | 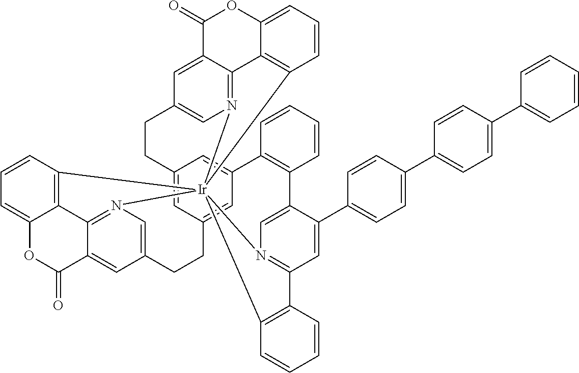 | 55% |
| Ir(L3) | L3 | 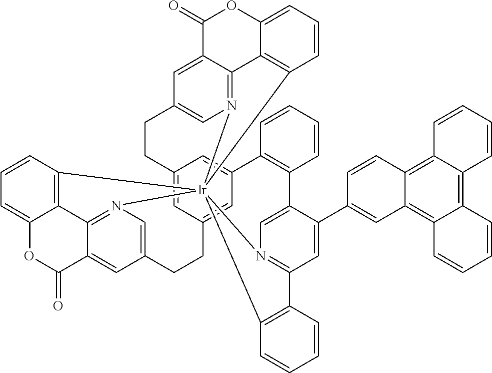 | 57% |
| Ir(L4) | L4 | 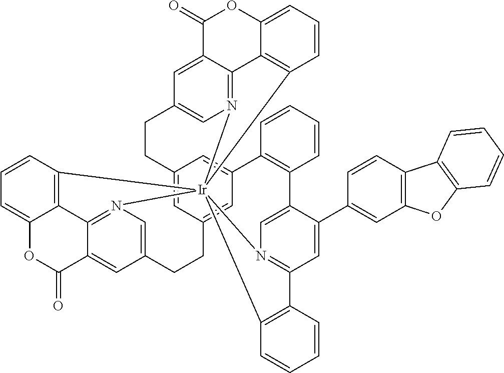 | 59% |
| Ir(L5) | L5 | 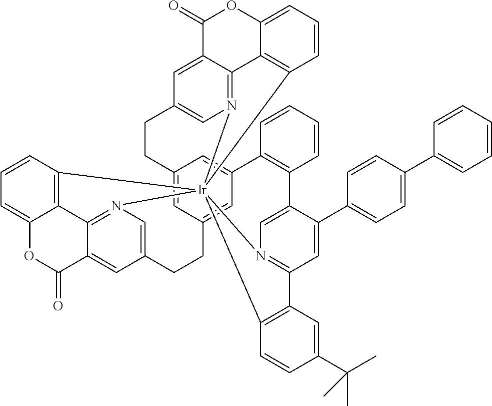 | 56% |
| Ir(L6) | L6 | 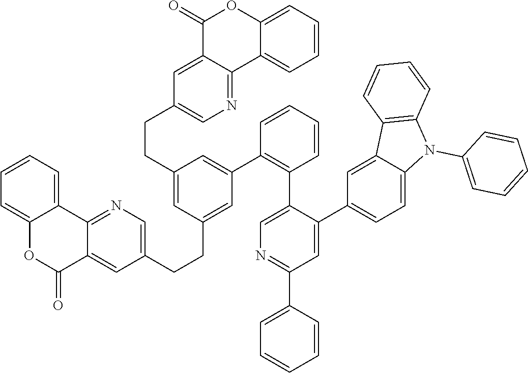 [SMILES: O=c1oc2ccccc2c2ncc(CCc3cc(CCc4cnc5c(c4)c(=O)oc4ccccc45)cc(-c4ccccc4-c4cnc(-c5ccccc5)cc4-c4ccc5c(c4)c4ccccc4n5-c4ccccc4)c3)cc12] | 54% |
| Ir(L7) | L7 | 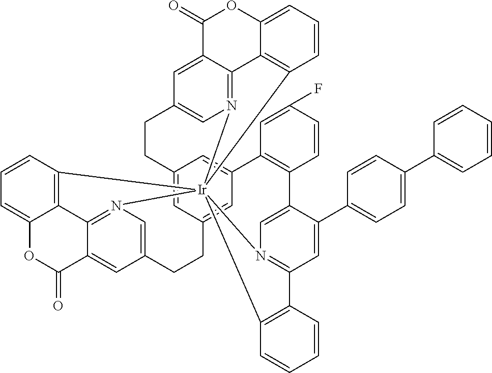 | 58% |
| Ir(L8) | L8 | 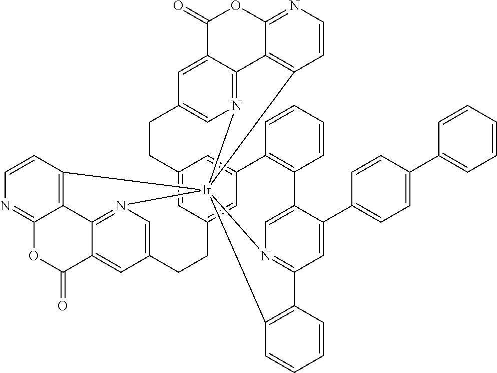 | 49% |
| Ir(L9) | L9 | 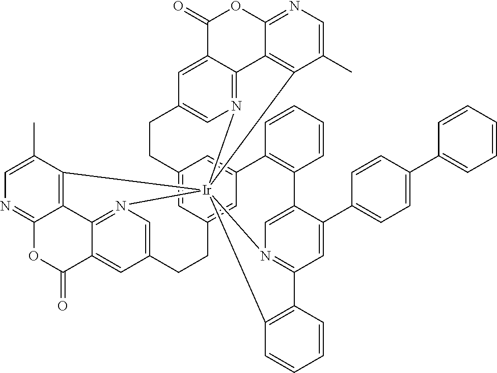 | 37% |
| Ir(L10) | L10 | 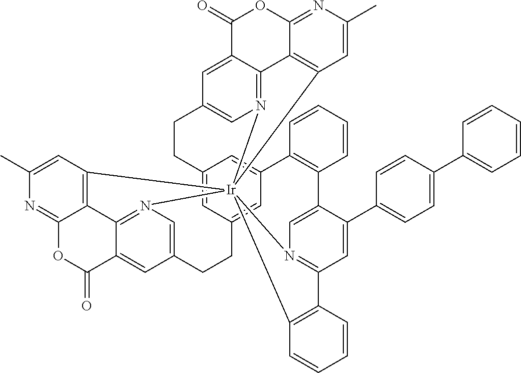 | 46% |
| Ir(L11) | L11 | 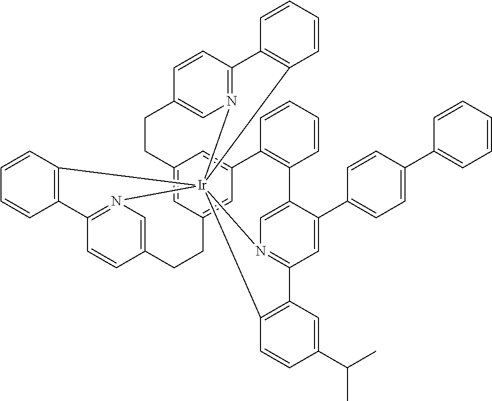 | 70% |
| Ir(L12) | L12 | 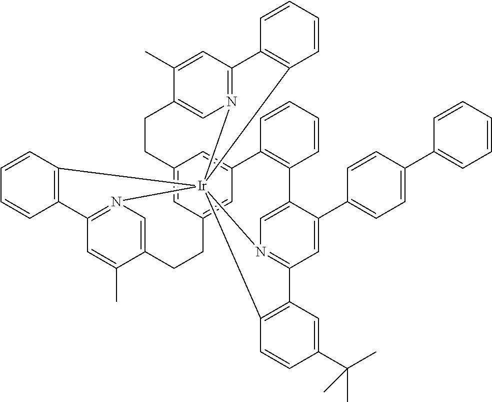 | 67% |
| Ir(L13) | L13 | 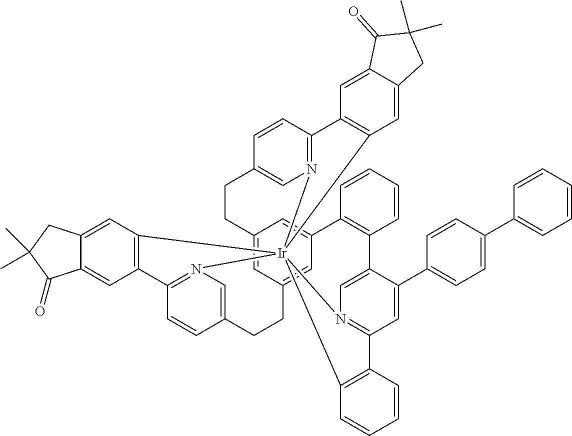 | 65% |
| Ir(L14) | L14 | 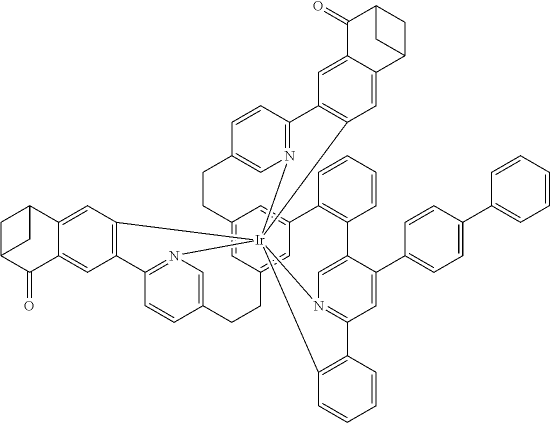 | 62% |

### 2) Bromination of the Metal Complexes

To a solution or suspension of 10 mmol of a complex bearing A×C—H groups (with A=1, 2, 3) in the para position to the iridium in 500 ml to 2000 ml of dichloromethane according to the solubility of the metal complexes is added, in the dark and with exclusion of air, at −30 to +3000, A×10.5 mmol of N-halosuccinimide (halogen: Cl, Br, I), and the mixture is stirred for 20 h. Complexes of sparing solubility in DCM may also be converted in other solvents (TCE, THF, DMF, chlorobenzene, etc.) and at elevated temperature. Subsequently, the solvent is substantially removed under reduced pressure. The residue is extracted by boiling with 100 ml of methanol, and the solids are filtered off with suction, washed three times with 30 ml of methanol and then dried under reduced pressure. This gives the iridium complexes brominated in the para position to the iridium. Complexes having a HOMO (CV) of about −5.1 to −5.0 eV and of smaller magnitude have a tendency to oxidation (Ir(III)→Ir(IV)), the oxidizing agent being bromine released from NBS. This oxidation reaction is apparent by a distinct green hue in the otherwise yellow to red solutions or suspensions of the emitters. In such cases, a further equivalent of NBS is added. For workup, 300-500 ml of methanol and 2 ml of hydrazine hydrate as reducing agent are added, which causes the green solutions or suspensions to turn yellow (reduction of Ir(IV)→Ir(III)). Then the solvent is substantially drawn off under reduced pressure, 300 ml of methanol are added, and the solids are filtered off with suction, washed three times with 100 ml each time of methanol and dried under reduced pressure.

Substoichiometric brominations, for example mono- and dibrominations, of complexes having 3 C—H groups in the para position to iridium usually proceed less selectively than the stoichiometric brominations. The crude products of these brominations can be separated by chromatography (CombiFlash Torrent from A. Semrau).

### Synthesis of Ir(L11-2Br):

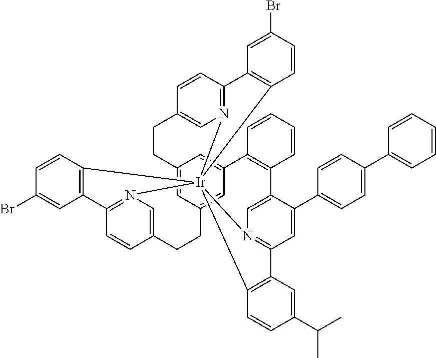

To a suspension, stirred at 0° C., of 10.7 g (10 mmol) of Ir(L11) in 500 ml of DCM are added 3.7 g (21.0 mmol) of N-bromosuccinimide all at once and the mixture is stirred for a further 20 h. After removing about 450 ml of the DCM under reduced pressure, 100 ml of methanol are added to the yellow suspension, and the solids are filtered off with suction, washed three times with about 50 ml of methanol and dried under reduced pressure. Yield: 11.7 g (9.5 mmol), 95%; purity: >99.5% by NMR.

In an analogous manner, it is possible to prepare the following compounds:

| | Reactant | |
|---|---|---|
| Ex. | Bromination product | Yield |
| Ir(L12-2Br) | 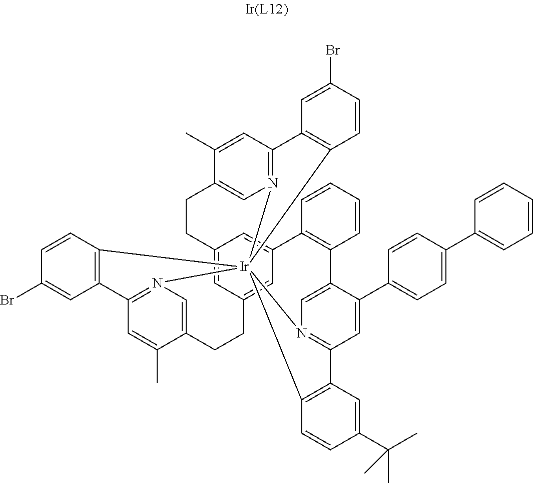 | 94% |

### 3) Cyanation of the Metal Complexes

A mixture of 10 mmol of the brominated complex, 20 mmol of copper(I) cyanide per bromine function and 300 ml of NMP is stirred at 180° C. for 40 h. After cooling, the solvent is removed under reduced pressure, the residue is taken up in 500 ml of dichloromethane, the copper salts are filtered off using Celite, the dichloromethane is concentrated almost to dryness under reduced pressure, 100 ml of ethanol are added, and the precipitated solids are filtered off with suction, washed twice with 50 ml each time of ethanol and dried under reduced pressure. The crude product is purified by chromatography and/or hot extraction. The heat treatment is effected under high vacuum (p about 10⁻⁶ mbar) within the temperature range of about 200-300° C. The sublimation is effected under high vacuum (p about 10⁻⁶ mbar) within the temperature range of about 350-450° C., the sublimation preferably being conducted in the form of a fractional sublimation.

### Synthesis of Ir(L11-2CN):

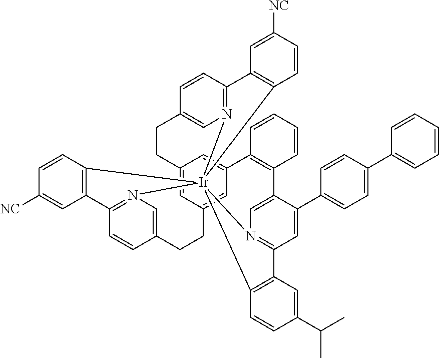

Use of 12.3 g (10 mmol) of Ir(L11-2Br) and 3.6 g (40 mmol) of copper(I) cyanide. Chromatography on silica gel with dichloromethane, hot extraction six times with dichloromethane/acetonitrile (2:1 w), sublimation. Yield: 6.1 g (5.5 mmol), 55%; purity: about 99.9% by HPLC.

In an analogous manner, it is possible to prepare the following compounds:

| | Reactant | |
|---|---|---|
| Ex. | Cyanation product | Yield |
| Ir(L12-2CN) | 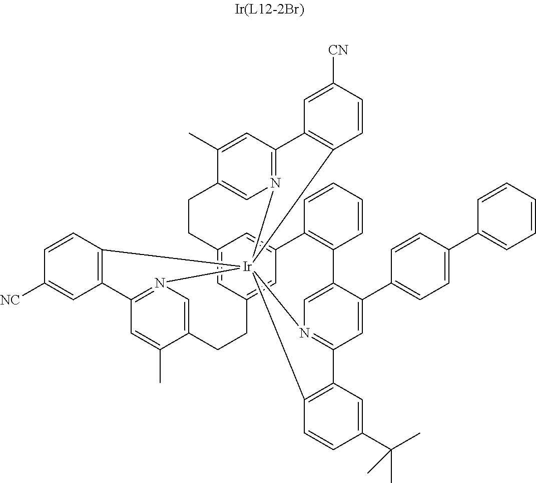 | 57% |

### D: Heteroleptic Complexes of Bidentate Ligands

1) Iridium Complexes of the [Ir(L)₂Cl]₂ Type

### Variant A:

A mixture of 22 mmol of the ligand, 10 mmol of iridium(III) chloride hydrate, 75 ml of 2-ethoxyethanol and 25 ml of water is heated under reflux with good stirring for 16-24 h. If the ligand dissolves incompletely in the solvent mixture, if at all, under reflux, 1,4-dioxane is added until a solution has formed. After cooling, the precipitated solids are filtered off with suction, washed twice with ethanol/water (1:1, w) and then dried under reduced pressure. The chloro dimer of the formula [Ir(L)₂Cl]₂ thus obtained is converted further without purification.

| | Ligand | | |
|---|---|---|---|
| Ex. | L | Ir complex | Yield |
| [Ir(L100)₂Cl]₂ | L100 | 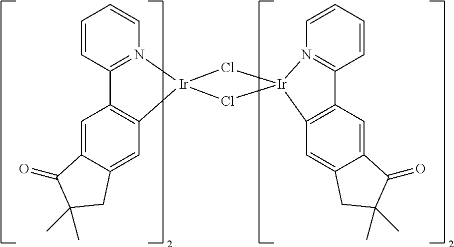 | 66% |
| [Ir(L101)₂Cl]₂ | L101 | 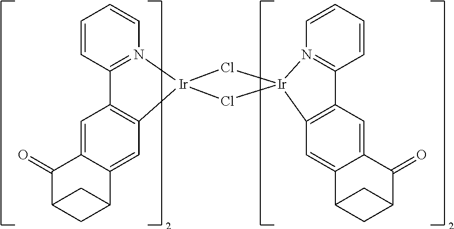 | 59% |

2) Iridium Complexes of the [Ir(L)₂(HOMe)₂]OTf Type

To a suspension of 5 mmol of the chloro dimer [Ir(L)₂Cl]₂ in 150 ml of dichloromethane are added 5 ml of methanol and then 10 mmol of silver(I) trifluoromethanesulfonate [2923-28-6], and the mixture is stirred at room temperature for 18 h. The precipitated silver(I) chloride is filtered off with suction through a Celite bed, the filtrate is concentrated to dryness, the yellow residue is taken up in 30 ml of toluene or cyclohexane, and the solids are filtered off, washed with n-heptane and dried under reduced pressure. The product of the formula [Ir(L)₂(HOMe)₂]OTf thus obtained is converted further without purification.

| Ex. | [Ir(L)₂Cl]₂ | [Ir(L)₂(HOMe)₂]OTf | Yield |
|---|---|---|---|
| [Ir(L100)₂(HOMe)₂]OTf | Ir[(L100)Cl]₂ | 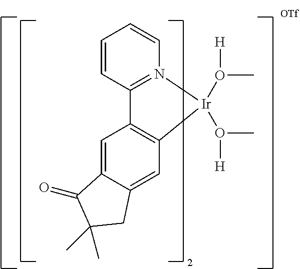 | 80% |
| [Ir(L101)₂(HOMe)₂]OTf | Ir[(L101)Cl]₂ | 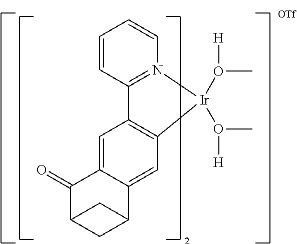 | 77% |

### 3) Heteroleptic Iridium Complexes of the Phenylpyridine Type:

A mixture of 10 mmol of the ligand L_{act}, 10 mmol of the iridium complex of the [Ir(L)₂(HOMe)₂]OTf type, 11 mmol of 2,6-dimethylpyridine and 150 ml of ethanol is heated under reflux for 40 h. After cooling, the precipitated solids are filtered off with suction, washed three times with 30 ml each time of ethanol and dried under reduced pressure. The crude product thus obtained is chromatographed on silica gel (solvents or mixtures thereof, e.g. DCM, THF, toluene, n-heptane, cyclohexane), and fractionally sublimed as described in C: 1) Synthesis of the tripodal metal complexes.

| | [Ir(L)₂(HOMe)₂]OTf | | |
|---|---|---|---|
| Ex. | Ligand L_{act} | Ir complex | Yield |
| Ir100 | 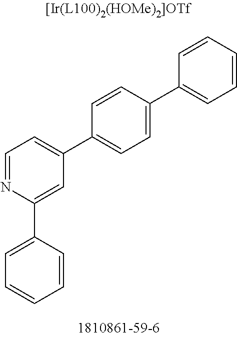 [SMILES: c1ccc(-c2ccc(-c3ccnc(-c4ccccc4)c3)cc2)cc1] | 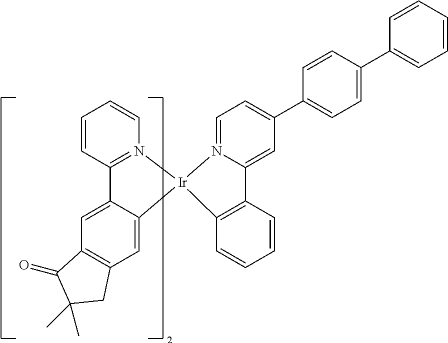 | 45% |
| Ir101 | [Ir(L101)₂(HOMe)₂]OTf 1810861-59-6 | 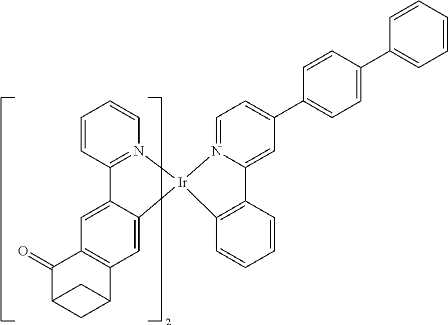 | 43% |

Optical Orientation Anisotropy Θ and Angle α(μ_{act},d)

The optical orientation anisotropy Θ and the angle α(μ_{act},d) of the complexes of which the synthesis has been described above is compiled in Table 1. These parameters have been calculated by the methods described in part 1 and part 2 of the Examples.

TABLE 1
Optical orientation anisotropy Θ and angle α

| Complex | Θ | α(μ_{act}, d) |
|---|---|---|
| Ir(L1) | 0.18 | 24° |
| Ir(L2) | 0.16 | 24° |
| Ir(L3) | 0.16 | 25° |
| Ir(L4) | 0.20 | 24° |
| Ir(L5) | 0.21 | 24° |
| Ir(L6) | 0.17 | 24° |
| Ir(L7) | 0.18 | 24° |
| Ir(L8) | 0.17 | 24° |
| Ir(L9) | 0.17 | 23° |
| Ir(L10) | 0.17 | 24° |
| Ir(L13) | 0.16 | 29° |
| Ir(L14) | 0.14 | 30° |
| Ir(L11-2CN) | 0.19 | 38° |
| Ir(L12-2CN) | 0.19 | 38° |
| Ir100 | 0.16 | 32° |
| Ir101 | 0.17 | 27° |

### Example: Production of the OLEDs

### 1) Vacuum-Processed Devices:

OLEDs of the invention and OLEDs according to the prior art are produced by a general method according to WO 2004/058911, which is adapted to the circumstances described here (variation in layer thickness, materials used). In the examples which follow, the results for various OLEDs are presented. Cleaned glass plaques (cleaning in Miele laboratory glass washer, Merck Extran detergent) coated with structured ITO (indium tin oxide) of thickness 50 nm are pretreated with UV ozone for 25 minutes (PR-100 UV ozone generator from UVP) and, within 30 min, for improved processing, coated with 20 nm of PEDOT:PSS (poly(3,4-ethylenedioxythiophene) poly(styrenesulfonate), purchased as CLEVIOS™ P VP Al 4083 from Heraeus Precious Metals GmbH Deutschland, spun on from aqueous solution) and then baked at 180° C. for 10 min. These coated glass plaques form the substrates to which the OLEDs are applied.

The OLEDs basically have the following layer structure: Substrate/hole injection layer 1 (HIL1) consisting of HTM1 doped with 5% NDP-9 (commercially available from Novaled), 20 nm/hole transport layer 1 (HTL1) consisting of HTM1, 220 nm/hole transport layer 2 consisting of HTM2, 10 nm/emission layer (EML) (see Table 2)/hole blocker layer consisting of HBL1, 10 nm/electron transport layer consisting of ETM1:ETM2 (50%:50%), 30 nm/cathode consisting of aluminium, 100 nm. For this purpose, all the materials are applied by thermal vapour deposition in a vacuum chamber. In this case, the emission layer always consists of at least one matrix material (host material) and an emitting dopant (emitter) which is added to the matrix material(s) in a particular proportion by volume by co-evaporation. Details given in such a form as M1:M2:Ir(L1) (55%:35%:10%) mean here that the material M1 is present in the layer in a proportion by volume of 55%, M2 in a proportion by volume of 35% and Ir(L1) in a proportion by volume of 10%. Analogously, the electron transport layer may also consist of a mixture of two materials. The exact structure of the emitting layer of the OLEDs can be found in Table 2. The materials used for production of the OLEDs are shown in Table 4.

The OLEDs are characterized in a standard manner. For this purpose, the electroluminescence spectra, the current efficiency (measured in cd/A), the power efficiency (measured in lm/W) and the external quantum efficiency (EQE, measured in percent) as a function of luminance, calculated from current-voltage-luminance characteristics (IUL characteristics) assuming Lambertian emission characteristics, and also the lifetime are determined. The electroluminescence spectra are determined at a luminance of 1000 cd/m², and the CIE 1931 x and y colour coordinates are calculated therefrom. The lifetime LT90 is defined as the time after which the luminance in operation has dropped to 90% of the starting luminance with a starting brightness of 10 000 cd/m².

The OLEDs can initially also be operated at different starting luminances. The values for the lifetime can then be converted to a figure for other starting luminances with the aid of conversion formulae known to those skilled in the art.

### Use of Compounds of the Invention as Emitter Materials in Phosphorescent OLEDs

One use of the compounds of the invention is as phosphorescent emitter materials in the emission layer in OLEDs. The results for the OLEDs are collated in Table 3. Examples Ref.-D2A and Ref.-D2B here illustrate, for a non-inventive material with an angle α(μ_{act},d) of 51°, the voltage shift on transition from 5% to 15% by volume of the emitter. This is also shown in the form of a graph in FIG. 9.

TABLE 2
Structure of the OLEDs

| Ex. | EML composition/thickness |
|---|---|
| Ref.-D1 | M1:M2:Ir-Ref.2/ |
| | (42.5%:42.5%:15%)/30 nm |
| Ref.-D2A | M1:M2:Ir-Ref.1/ |
| | (47.5%:47.5%:5%)/30 nm |
| Ref.-D2B | M1:M2:Ir-Ref.1/ |
| | (42.5%:42.5%:15%)/30 nm |
| D1A | M1:M2:Ir(L11-2CN)/ |
| | (47.5%:47.5%:5%)/30 nm |
| D1B | M1:M2:Ir(L11-2CN)/ |
| | (42.5%:42.5%:15%)/30 nm |
| D2A | M1:M2:Ir(L12-2CN)/ |
| | (47.5%:47.5%:5%)/30 nm |
| D2B | M1:M2:Ir(L12-2CN)/ |
| | (42.5%:42.5%:15%)/30 nm |
| D3A | M1:M2:Ir(L14)/ |
| | (47.5%:47.5%:5%)/30 nm |
| D3B | M1:M2:Ir(L14)/ |
| | (42.5%:42.5%:15%)/30 nm |

TABLE 3
Results for the OLEDs

| | | EQE | Voltage | CIE | LT90 | ΔU |
|---|---|---|---|---|---|---|
| | | (%) | (V) | x/y | (h) | (V) |
| | | 1000 | 1000 | 1000 | 10 000 | 10⁻³ |
| Ex. | PLQE* | cd/m² | cd/m² | cd/m² | cd/m² | mA/cm² |
| Ref.-D1 | 0.96 | 17.4 | 3.4 | 0.35/0.62 | 650 | — |
| Ref.-D2A | 0.98 | 26.2 | 3.3 | 0.34/0.63 | — | 0.3 |
| Ref.-D2B | | 25.9 | 3.6 | 0.34/0.63 | 240 | |
| D1A | 0.99 | 29.6 | 2.9 | 0.34/0.63 | — | 0.0 |
| D1B | | 29.1 | 2.9 | 0.34/0.63 | 800 | |
| D2A | 0.99 | 29.5 | 2.9 | 0.34/0.63 | — | 0.0 |
| D2B | | 29.0 | 2.9 | 0.34/0.63 | 750 | |
| D3A | 0.32 | 12.5 | 3.0 | 0.42/0.56 | — | 0.0 |
| D3B | | 12.3 | 3.1 | 0.42/0.56 | not | |
| | | | | | determined | |

*PLQE: Absolute photoluminescence quantum yield in degassed toluenic solution

TABLE 4
Materials used

| | |
|---|---|
| 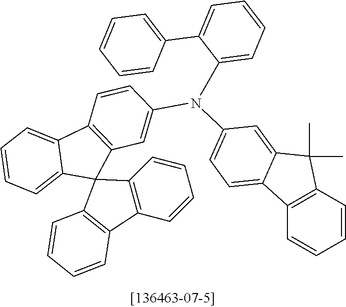 [SMILES: CC1(C)c2ccccc2-c2ccc(N(c3ccc4c(c3)C3(c5ccccc5-c5ccccc53)c3ccccc3-4)c3ccccc3-c3ccccc3)cc21] | HTM 1 |
| 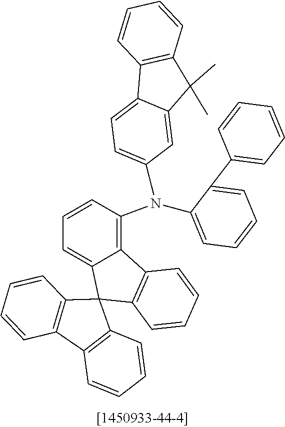 [SMILES: CC1(C)c2ccccc2-c2ccc(N(c3ccccc3-c3ccccc3)c3cccc4c3-c3ccccc3C43c4ccccc4-c4ccccc43)cc21] | HTM2 |
| 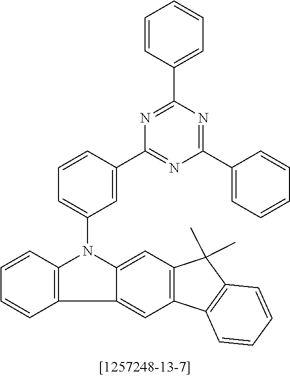 [SMILES: CC1(C)c2ccccc2-c2cc3c4ccccc4n(-c4cccc(-c5nc(-c6ccccc6)nc(-c6ccccc6)n5)c4)c3cc21] | M1 |
| 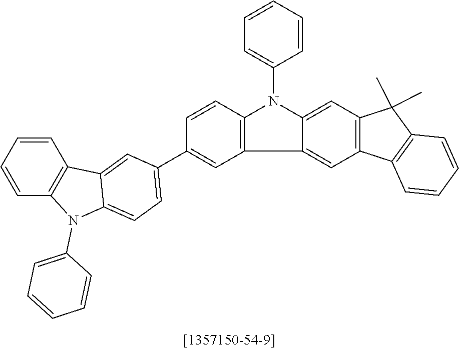 [SMILES: CC1(C)c2ccccc2-c2cc3c4cc(-c5ccc6c(c5)c5ccccc5n6-c5ccccc5)ccc4n(-c4ccccc4)c3cc21] | M2 |
| 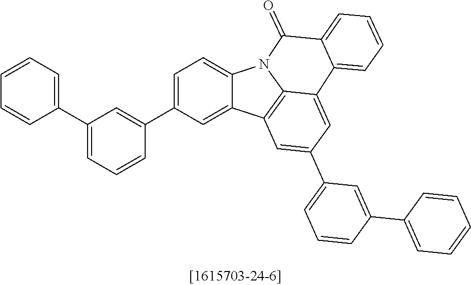 [SMILES: O=c1c2ccccc2c2cc(-c3cccc(-c4ccccc4)c3)cc3c4cc(-c5cccc(-c6ccccc6)c5)ccc4n1c23] | M3 |
| 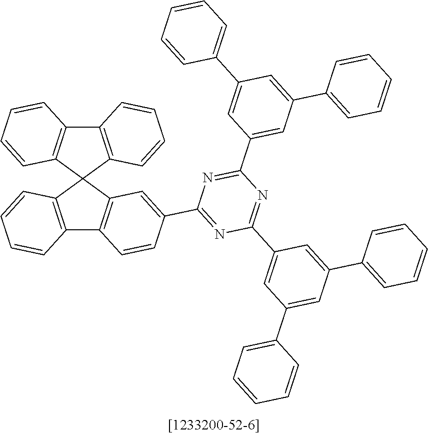 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] | ETM1 = HBL1 |
| 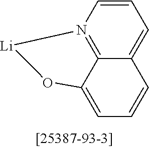 | ETM2 |
| 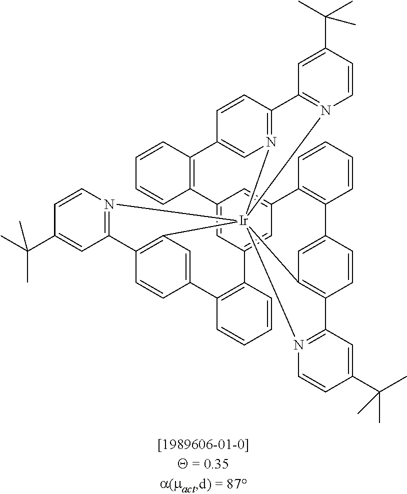 | Ir-Ref.1 |
| 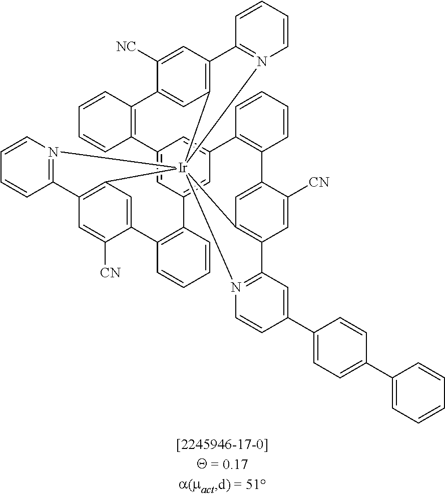 | Ir-Ref.2 |

1.-18. (canceled)

19. A mononuclear iridium complex that exhibits oriented emission with an optical orientation anisotropy Θ≤0.24, containing three ortho-metallated bidentate ligands or three ortho-metallated bidentate sub-ligands, characterized in that the angle α(μ_{act},d) between the transition dipole moment μ_{act} and the electrical dipole moment d is ≤40°;
where the following compounds are excluded from the invention:

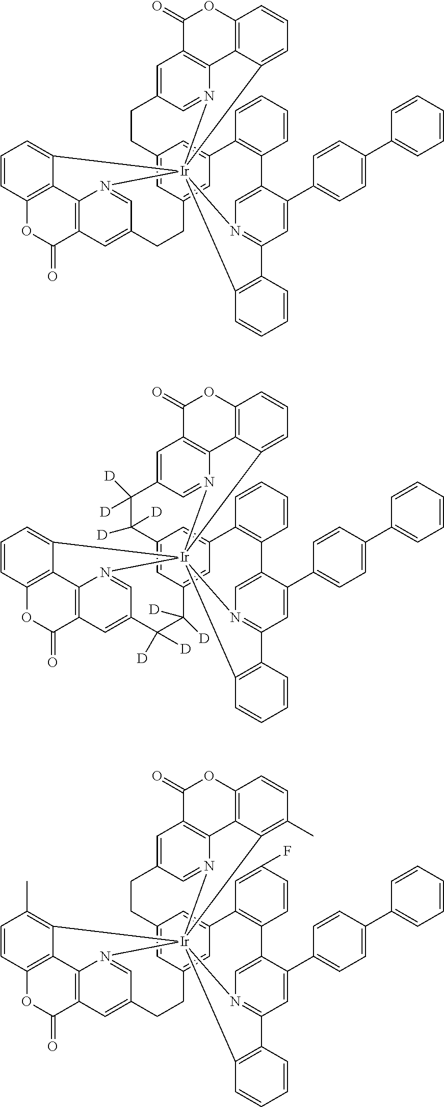

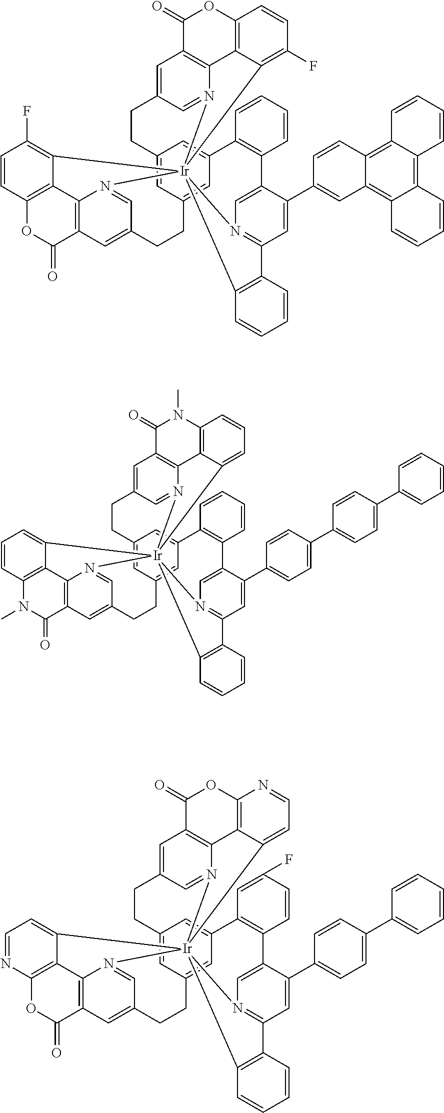

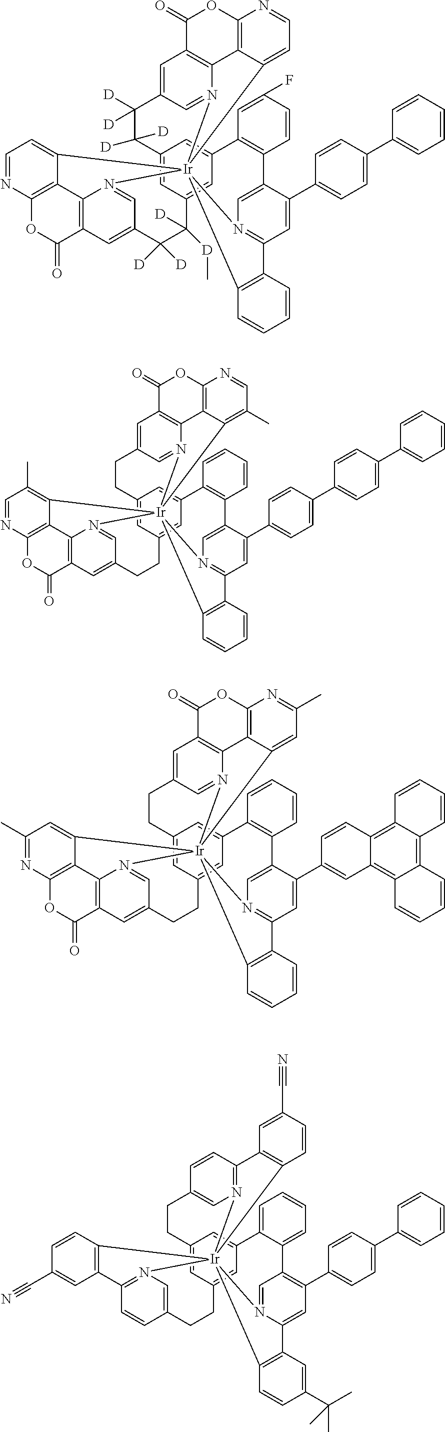

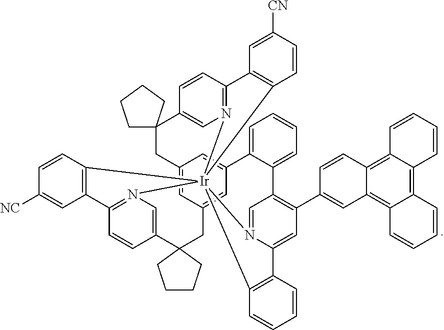

20. The mononuclear iridium complex according to claim 19, wherein the complex is a heteroleptic complex containing at least two different ligands or sub-ligands.

21. The mononuclear iridium complex according to claim 19, wherein the complex has two identical bidentate ligands or sub-ligands and a further bidentate ligand or sub-ligand different from the two other bidentate ligands or sub-ligands.

22. The mononuclear iridium complex according to claim 19, wherein the complex has exactly one optically active ligand or sub-ligand L_{act} which is characterized in that the triplet energy is subject to the following condition: Ir(L_{act})<Ir(L) where L is the optically inactive ligand.

23. The mononuclear iridium complex according to claim 22, wherein the triplet energy of the ligand Ir(L) is at least 0.05 eV greater than that of the ligand Ir(L_{act}).

24. The mononuclear iridium complex according to claim 19, wherein the optically active ligand or sub-ligand is extended in the direction of the transition dipole moment with an aromatic or heteroaromatic ring system.

25. The mononuclear iridium complex according to claim 19, wherein the optical orientation anisotropy Θ is ≤0.22.

26. The mononuclear iridium complex according to claim 19, wherein the angle α(μ_{act},d) between the transition dipole moment μ_{act} and the electrical dipole moment d is ≤35°.

27. The mononuclear iridium complex according to claim 19, wherein the complex has a photoluminescence quantum efficiency of more than 0.85.

28. The mononuclear iridium complex according to claim 19, wherein the complex is one of the formulae (1) and (2) 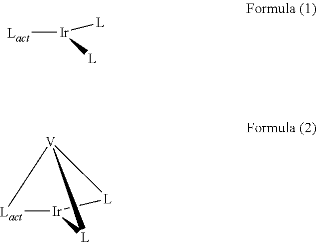
where L_{act} in formula (1) is an optically active ortho-metallated bidentate ligand and in formula (2) is an optically active ortho-metallated bidentate sub-ligand, L is different from L_{act} and is the same or different at each instance and is ortho-metallated bidentate ligands in formula (1) and ortho-metallated bidentate sub-ligands in formula (2), and V in formula (2) is a bridging unit that joins the sub-ligands L_{act} and L covalently to form a tripodal hexadentate ligand.

29. The mononuclear iridium complex according to claim 28, wherein L_{act} and L each coordinate to the iridium via one carbon atom and one nitrogen atom or via two carbon atoms.

30. The mononuclear iridium complex according to claim 28, wherein L_{act} and L each represent a structure of the formulae (L-1) or (L-2), where the two ligands or sub-ligands L may be the same or different, 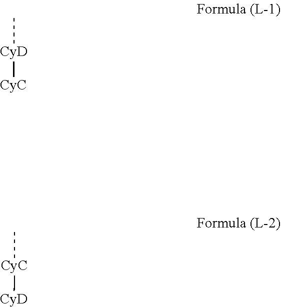
where the dotted bond represents the bond of the sub-ligand in formula (2) to V and is absent for formula (1) and where the other symbols used are as follows:
CyC is the same or different at each instance and is a substituted or unsubstituted aryl or heteroaryl group which has 5 to 14 aromatic ring atoms and coordinates in each case to the metal via a carbon atom and which is bonded to CyD via a covalent bond;
CyD is the same or different at each instance and is a substituted or unsubstituted heteroaryl group which has 5 to 14 aromatic ring atoms and coordinates to the metal via a nitrogen atom or via a carbene carbon atom and which is bonded to CyC via a covalent bond;
at the same time, two or more of the optional substituents together may form a ring system.

31. The mononuclear iridium complex according to claim 28, wherein L_{act} and L are each a structure of one of the formulae (L-1-1), (L-1-2), (L-2-1), (L-2-2), (L-2-3) or (L-2-4) 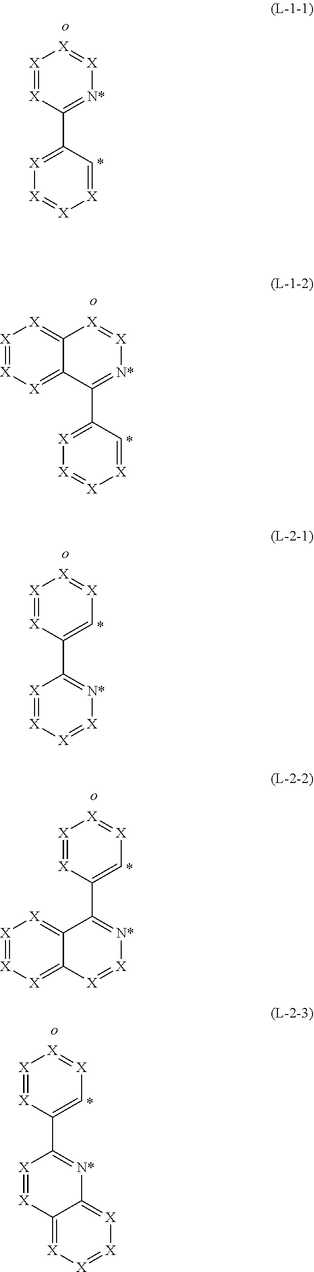 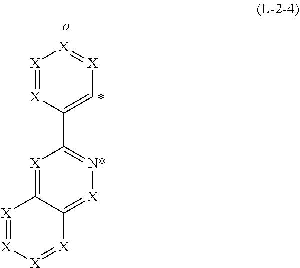
where “o” for compounds of the formula (2) represents the position of the bond to V, in which case the corresponding X is C, and where “o” is undefined for compounds of the formula (1), and in addition:
X is the same or different at each instance and is CR or N, with the proviso that at most two symbols X per ring are N;
R is the same or different at each instance and is H, D, F, Cl, Br, I, N(R¹)₂, OR¹, SR¹, CN, NO₂, COOR¹, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, having 1 to 20 carbon atoms, in which one or more hydrogen atoms may also be replaced by F.

32. The mononuclear iridium complex according to claim 28, wherein L_{act} is a ligand or sub-ligand of the formula (L-39) that coordinates to the iridium via the two D groups and which, when the complex is one of the formula (2), is bonded to V via the dotted bond, in which case the corresponding X is C, 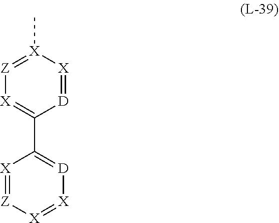
Wherein
X is the same or different at each instance and is CR or N, with the proviso that at most two symbols X per ring are N;
R is the same or different at each instance and is H, D, F, Cl, Br, I, N(R¹)₂, OR¹, SR¹, CN, NO₂, COOR¹, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, having 1 to 20 carbon atoms, in which one or more hydrogen atoms may also be replaced by F;
D is C or N, with the proviso that one D is C and the other D is N;
Z is CR′, CR or N, with the proviso that exactly one Z is CR′ and the other Z is CR or N;
where a maximum of one symbol X or Z per cycle is N;
R′ is a group of the following formula (14) or (15): 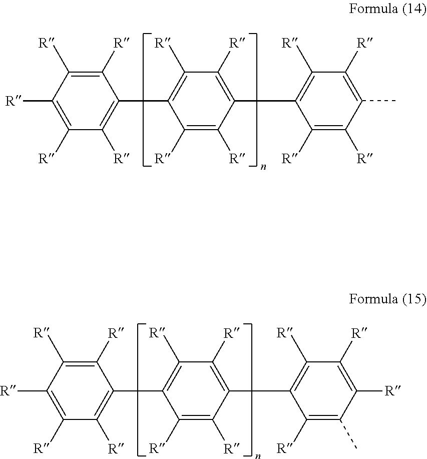
where the dotted bond indicates the attachment of the group;
R″ is the same or different at each instance and is H, D, F, CN, a straight-chain alkyl group having 1 to 10 carbon atoms in which one or more hydrogen atoms may also be replaced by D or F, or a branched or cyclic alkyl group having 3 to 10 carbon atoms in which one or more hydrogen atoms may also be replaced by D or F, or an alkenyl group having 2 to 10 carbon atoms in which one or more hydrogen atoms may also be replaced by D or F; at the same time, two adjacent R″ radicals or two R″ radicals on adjacent phenyl groups together may also form a ring system; or two R″ on adjacent phenyl groups together are a group selected from C(R¹)₂, NR¹, O and S, such that the two phenyl rings together with the bridging group are a carbazole, dibenzofuran or dibenzothiophene, and the further R″ are as defined above;
n is 0, 1, 2, 3, 4 or 5.

33. The mononuclear iridium complex according to claim 28, wherein V represents a group of the formula (16), where the dotted bonds represent the position of the attachment of the sub-ligands L_{act} and L, 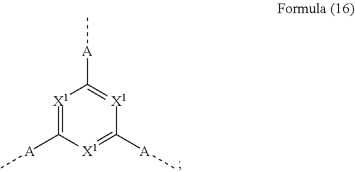
wherein
R is the same or different at each instance and is H, D, F, Cl, Br, I, N(R¹)₂, OR¹, SR¹, CN, NO₂, COOR¹, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals and where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more nonaromatic R¹ radicals; at the same time, two R radicals together may also form a ring system;
R¹ is the same or different at each instance and is H, D, F, Cl, Br, I, N(R²)₂, OR², SR², CN, NO₂, Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals and where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic organic radical, having 1 to 20 carbon atoms, in which one or more hydrogen atoms may also be replaced by F;
X¹ is the same or different at each instance and is CR or N;
A is the same or different at each instance and is CR₂—CR₂, CR₂—O, CR₂—NR, C(═O)—O, C(═O)—NR or a group of the formula (17): 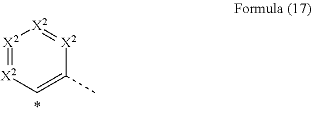
where the dotted bond represents the position of the bond of the bidentate sub-ligands L_{act} and L to this structure, * represents the position of the attachment of the unit of the formula (17) to the central trivalent aryl or heteroaryl group and X² is the same or different at each instance and is CR or N.

34. An electronic device comprising at least one mononuclear iridium complex according to claim 19.

35. Electronic device according to claim 34, the device is an organic electroluminescent device and the mononuclear iridium complex is used as emitting compound in an emitting layer.
